(19) United States
(12) Patent Application Publication
(10) Pub. No.: US 2026/0206419 A1
(43) Pub. Date: Jul. 16, 2026

(54) LIGHT-EMITTING DEVICE AND ELECTRONIC EQUIPMENT

(71) Applicant: Sony Semiconductor Solutions Corporation, Kanagawa (JP)

(72) Inventors: Toshiaki Shiraiwa, Kanagawa (JP); Naoya Kasahara, Kanagawa (JP); Daisuke Hamashita, Kanagawa (JP); Masaya Ogura, Kanagawa (JP); Tadayuki Kimura, Kanagawa (JP); Yosuke Fujii, Kanagawa (JP); Shoji Kobayashi, Kanagawa (JP); Kohei Fukushima, Kanagawa (JP); Katsuhisa Kugimiya, Kanagawa (JP); Tomokaza Ohchi, Kanagawa (JP); Masataka Sugiyasu, Kumamoto (JP)

(21) Appl. No.: 19/127,571

(22) PCT Filed: Nov. 30, 2023
(86) PCT No.: PCT/JP2023/042892

§ 371 Date: May 6, 2025

(30) Foreign Application Priority Data
Nov. 30, 2022 (JP) 2022-192288

(51) Int. Cl. H10K 59/122

(52) U.S. Cl. CPC H10K 59/122

(57) ABSTRACT

Light-emitting devices that prevent delamination between an organic-containing layer and a first electrode are disclosed. In one example, a light-emitting device includes light-emitting elements each including a first electrode, an organic-containing layer including an organic light-emitting layer, and a second electrode. The light-emitting elements are arranged two-dimensionally, a protective layer is provided on each of the light-emitting elements and separated between the light-emitting elements adjacent to each other, and a side surface protective layer covers a side surface of each of the organic-containing layers, a side surface of each of the second electrodes, and a side surface of each of the protective layers. The side surface of the protective layer is located inside the side surface of the second electrode.

### TECHNICAL FIELD

The present disclosure relates to a light-emitting device and electronic equipment.

### BACKGROUND ART

A light-emitting device including a plurality of light-emitting elements each including a first electrode, an organic-containing layer including an organic light-emitting layer, and a second electrode in sequence, the light-emitting elements arranged two-dimensionally, has become widely known in recent years. As a display device of this type, a display device having a structure where an organic-containing layer is divided between the adjacent light-emitting elements has been proposed (see, for example, Patent Document 1).

### CITATION LIST

### Patent Document

Patent Document 1: Japanese Patent Application Laid-Open No. 2004-127637

### SUMMARY OF THE INVENTION

### Problems to be Solved by the Invention

The display device in which the organic-containing layer is divided between the adjacent light-emitting elements, however, may suffer delamination between the organic-containing layer and the second electrode. There is a possibility that such delamination causes an increase in the drive voltage of the light-emitting elements.

It is therefore an object of the present disclosure to provide a light-emitting device and electronic equipment that can prevent the occurrence of delamination between an organic-containing layer and a first electrode.

### Solutions to Problems

In order to solve the above-described problems, a first light-emitting device according to the present disclosure includes:
a plurality of light-emitting elements each including a first electrode, an organic-containing layer including an organic light-emitting layer, and a second electrode, the light-emitting elements being arranged two-dimensionally;
a protective layer provided on each of the light-emitting elements and separated between the light-emitting elements adjacent to each other; and
a side surface protective layer covering a side surface of each of the organic-containing layers, a side surface of each of the second electrodes, and a side surface of each of the protective layers, in which the side surface of the protective layer is located inside the side surface of the second electrode.

A second light-emitting device according to the present disclosure includes:
a plurality of light-emitting elements each including a first electrode, an organic-containing layer including an organic light-emitting layer, and a second electrode, the light-emitting elements being arranged two-dimensionally; and
a side surface protective layer provided on a side surface of each of the light-emitting elements, in which
the organic-containing layer includes a flat portion and an inclined portion on a surface adjacent to the second electrode, the inclined portion being provided adjacent to a side surface of the organic-containing layer, and
the second electrode is provided along the flat portion and the inclined portion, the second electrode located at the inclined portion being thicker than the second electrode located at the flat portion.

Electronic equipment according to the present disclosure includes the first light-emitting device or the second light-emitting device.

### BRIEF DESCRIPTION OF DRAWINGS

FIG. 1 is a plan view of a display device according to a first embodiment.

FIG. 2 is an enlarged plan view of a part of a display region.

FIG. 3 is a cross-sectional view taken along line III-III in FIG. 2.

FIG. 4 is an enlarged cross-sectional view of a part of a light-emitting element.

FIG. 5A is a manufacturing process diagram of the display device according to the first embodiment.

FIG. 5B is a manufacturing process diagram of the display device according to the first embodiment.

FIG. 5C is a manufacturing process diagram of the display device according to the first embodiment.

FIG. 5D is a manufacturing process diagram of the display device according to the first embodiment.

FIG. 5E is a manufacturing process diagram of the display device according to the first embodiment.

FIG. 6 is an enlarged plan view of a part of a display region of a display device according to a second embodiment.

FIG. 7 is a cross-sectional view taken along line VII-VII in FIG. 6.

FIG. 8A is a manufacturing process diagram of the display device according to the second embodiment.

FIG. 8B is a manufacturing process diagram of the display device according to the second embodiment.

FIG. 8C is a manufacturing process diagram of the display device according to the second embodiment.

FIG. 8D is a manufacturing process diagram of the display device according to the second embodiment.

FIG. 8E is a manufacturing process diagram of the display device according to the second embodiment.

FIG. 8F is a manufacturing process diagram of the display device according to the second embodiment.

FIG. 9A is a manufacturing process diagram of the display device according to the second embodiment.

FIG. 9B is a manufacturing process diagram of the display device according to the second embodiment.

FIG. 9C is a manufacturing process diagram of the display device according to the second embodiment.

FIG. 9D is a manufacturing process diagram of the display device according to the second embodiment.

FIG. 10 is a manufacturing process diagram of the display device according to the second embodiment.

FIG. 11 is a cross-sectional view of a display device according to a reference example.

FIG. 12 is an enlarged cross-sectional view of a light-emitting element.

FIG. 13 is an enlarged plan view of a part of a display region of a display device according to a third embodiment.

FIG. 14 is a cross-sectional view taken along line XIV-XIV in FIG. 13.

FIG. 15 is an enlarged cross-sectional view of a light-emitting element.

FIG. 16A is a manufacturing process diagram of the display device according to the third embodiment.

FIG. 16B is a manufacturing process diagram of the display device according to the third embodiment.

FIG. 16C is a manufacturing process diagram of the display device according to the third embodiment.

FIG. 16D is a manufacturing process diagram of the display device according to the third embodiment.

FIG. 16E is a manufacturing process diagram of the display device according to the third embodiment.

FIG. 16F is a manufacturing process diagram of the display device according to the third embodiment.

FIG. 16G is a manufacturing process diagram of the display device according to the third embodiment.

FIG. 16H is a manufacturing process diagram of the display device according to the third embodiment.

FIG. 17 is a cross-sectional view of a display device according to a fourth embodiment.

FIG. 18 is an enlarged cross-sectional view of a light-emitting element.

FIG. 19A is a manufacturing process diagram of the display device according to the fourth embodiment.

FIG. 19B is a manufacturing process diagram of the display device according to the fourth embodiment.

FIG. 19C is a manufacturing process diagram of the display device according to the fourth embodiment.

FIG. 19D is a manufacturing process diagram of the display device according to the fourth embodiment.

FIG. 19E is a manufacturing process diagram of the display device according to the fourth embodiment.

FIG. 20 is a cross-sectional view of a display device according to a fifth embodiment.

FIG. 21 is an enlarged cross-sectional view of a part of a light-emitting element.

FIG. 22A is a manufacturing process diagram of the display device according to the fifth embodiment.

FIG. 22B is a manufacturing process diagram of the display device according to the fifth embodiment.

FIG. 22C is an enlarged manufacturing process diagram illustrating a part of FIG. 22B.

FIG. 22D is a manufacturing process diagram of the display device according to the fifth embodiment.

FIG. 23 is a cross-sectional view of a display device according to a modification of the fifth embodiment.

FIG. 24 is a manufacturing process diagram of the display device according to the modification of the fifth embodiment.

FIG. 25 is a cross-sectional view of the display device according to the modification of the fifth embodiment.

FIG. 26 is a manufacturing process diagram of the display device according to the modification of the fifth embodiment.

FIG. 27 is a cross-sectional view of the display device according to the modification of the fifth embodiment.

FIG. 28 is a manufacturing process diagram of the display device according to the modification of the fifth embodiment.

FIG. 29 is a cross-sectional view of the display device according to the modification of the fifth embodiment.

FIG. 30 is a manufacturing process diagram of the display device according to the modification of the fifth embodiment.

FIG. 31A is a cross-sectional view of the display device according to the modification of the fifth embodiment.

FIG. 31B is an enlarged cross-sectional view of a part of FIG. 31A.

FIG. 32 is a cross-sectional view of a display device according to a sixth embodiment.

FIG. 33 is an enlarged cross-sectional view of a part of a light-emitting element.

FIG. 34A is a manufacturing process diagram of the display device according to the sixth embodiment.

FIG. 34B is a manufacturing process diagram of the display device according to the sixth embodiment.

FIG. 34C is a manufacturing process diagram of the display device according to the sixth embodiment.

FIG. 34D is a manufacturing process diagram of the display device according to the sixth embodiment.

FIG. 34E is a manufacturing process diagram of the display device according to the sixth embodiment.

FIG. 34F is a manufacturing process diagram of the display device according to the sixth embodiment.

FIG. 34G is an enlarged manufacturing process diagram illustrating a part of FIG. 34F.

FIG. 34H is a manufacturing process diagram of the display device according to the sixth embodiment.

FIG. 35 is a cross-sectional view of a display device according to a modification of the sixth embodiment.

FIG. 36A is a manufacturing process diagram of the display device according to the modification of the sixth embodiment.

FIG. 36B is an enlarged manufacturing process diagram illustrating a part of FIG. 36A.

FIG. 36C is a manufacturing process diagram of the display device according to the modification of the sixth embodiment.

FIG. 37 is a cross-sectional view of a display device according to a seventh embodiment.

FIG. 38 is an enlarged cross-sectional view of a region between the adjacent light-emitting elements.

FIG. 39 is an enlarged cross-sectional view of the display device according to the modification of the sixth embodiment.

FIG. 40 is an enlarged cross-sectional view of the display device according to the modification of the sixth embodiment.

FIG. 41 is an enlarged cross-sectional view of the display device according to the modification of the sixth embodiment.

FIG. 42 is an enlarged cross-sectional view of the display device according to the modification of the sixth embodiment.

FIG. 43 is an enlarged cross-sectional view of the display device according to the modification of the sixth embodiment.

FIG. 44 is an enlarged plan view of a part of a display region of a display device according to an eighth embodiment.

FIG. 45 is an enlarged plan view of a part of FIG. 44.

FIG. 46 is a cross-sectional view taken along line B-B in FIG. 44.

FIG. 47 is a cross-sectional view taken along line C-C in FIG. 44.

FIG. 48A is a plan view for describing the manufacturing process of the display device according to the eighth embodiment. FIG. 48B is a cross-sectional view taken along line B-B in FIG. 48A. FIG. 48C is a cross-sectional view taken along line C-C in FIG. 48A.

FIG. 49A is a plan view for describing the manufacturing process of the display device according to the eighth embodiment. FIG. 49B is a cross-sectional view taken along line B-B in FIG. 49A. FIG. 49C is a cross-sectional view taken along line C-C in FIG. 49A.

FIG. 50A is a plan view for describing the manufacturing process of the display device according to the eighth embodiment. FIG. 50B is a cross-sectional view taken along line B-B in FIG. 50A. FIG. 50C is a cross-sectional view taken along line C-C in FIG. 50A.

FIG. 51A is a plan view for describing the manufacturing process of the display device according to the eighth embodiment. FIG. 51B is a cross-sectional view taken along line B-B in FIG. 51A. FIG. 51C is a cross-sectional view taken along line C-C in FIG. 51A.

FIG. 52A is a plan view for describing the manufacturing process of the display device according to the eighth embodiment. FIG. 52B is a cross-sectional view taken along line B-B in FIG. 52A. FIG. 52C is a cross-sectional view taken along line C-C in FIG. 52A.

FIG. 53 is a cross-sectional view of a display device according to a ninth embodiment.

FIG. 54 is a cross-sectional view of a display device according to a modification.

FIG. 55 is an enlarged cross-sectional view of a light-emitting element.

FIGS. 56A, 56B, and 56C are conceptual diagrams illustrating a relationship among a normal line LN passing through a center of a light-emitting unit, a normal line LN′ passing through a center of a lens member, and a normal line LN″ passing through a center of a wavelength selection unit, respectively.

FIG. 57 is a conceptual diagram illustrating a relationship among the normal line LN passing through the center of the light-emitting unit, the normal line LN′ passing through the center of the lens member, and the normal line LN″ passing through the center of the wavelength selection unit.

FIGS. 58A and 58B are conceptual diagrams illustrating a relationship among the normal line LN passing through the center of the light-emitting unit, the normal line LN′ passing through the center of the lens member, and the normal line LN″ passing through the center of the wavelength selection unit, respectively.

FIG. 59 is a conceptual diagram illustrating a relationship among the normal line LN passing through the center of the light-emitting unit, the normal line LN′ passing through the center of the lens member, and the normal line LN″ passing through the center of the wavelength selection unit.

FIG. 60A is a schematic cross-sectional view for describing a first example of a resonator structure.

FIG. 60B is a schematic cross-sectional view for describing a second example of the resonator structure.

FIG. 61A is a schematic cross-sectional view for describing a third example of the resonator structure. FIG. 61B is a schematic cross-sectional view for describing a fourth example of the resonator structure.

FIG. 62A is a schematic cross-sectional view for describing a fifth example of the resonator structure. FIG. 62B is a schematic cross-sectional view for describing a sixth example of the resonator structure.

FIG. 63 is a schematic cross-sectional view for describing a seventh example of the resonator structure.

FIG. 64A is a front view of a digital still camera. FIG. 64B is a rear view of the digital still camera.

FIG. 65 is a perspective view of a head-mounted display.

FIG. 66 is a perspective view of a television device.

FIG. 67 is a perspective view of a see-through head-mounted display.

FIG. 68 is a perspective view of a smartphone.

FIG. 69A is a diagram illustrating an internal state of a vehicle as viewed from a rear side to a front side of the vehicle. FIG. 69B is a diagram illustrating an internal state of the vehicle as viewed from an oblique rear side to an oblique front side of the vehicle.

FIG. 70 is an enlarged plan view of a part of a display region of a display device according to a tenth embodiment.

FIG. 71 is a cross-sectional view taken along line LXXI-LXXI in FIG. 71.

FIG. 72 is an enlarged cross-sectional view of a part of a light-emitting element.

FIG. 73A is a manufacturing process diagram of the display device according to the tenth embodiment.

FIG. 73B is a manufacturing process diagram of the display device according to the tenth embodiment.

FIG. 73C is a manufacturing process diagram of the display device according to the tenth embodiment.

FIG. 73D is a manufacturing process diagram of the display device according to the tenth embodiment.

FIG. 73E is a manufacturing process diagram of the display device according to the tenth embodiment.

FIG. 74A is a manufacturing process diagram of the display device according to the tenth embodiment.

FIG. 74B is a manufacturing process diagram of the display device according to the tenth embodiment.

FIG. 75 is an enlarged cross-sectional view of a display device according to a modification of the tenth embodiment.

FIG. 76 is an enlarged cross-sectional view of the display device according to the modification of the tenth embodiment.

### MODE FOR CARRYING OUT THE INVENTION

Embodiments of the present disclosure will be described in the following order with reference to the drawings. Note that the same or corresponding portions will be denoted by the same reference signs in all the drawings of the following embodiments.
1 First embodiment (Example of display device)
2 Second embodiment (Example of display device)
3 Third embodiment (Example of display device)
4 Fourth embodiment (Example of display device)
5 Fifth embodiment (Example of display device)
6 Sixth embodiment (Example of display device)
7 Seventh embodiment (Example of display device)
8 Eighth embodiment (Example of display device)
9 Ninth embodiment (Example of display device)
10 Tenth embodiment (Example of display device)
11 Modifications
12 Relationship among normal lines passing through the centers of light-emitting unit, lens member, and wavelength selection unit
13 Example of resonator structure
14 Application examples (examples of electronic equipment)

### 1 First Embodiment

### [Configuration of Display Device]

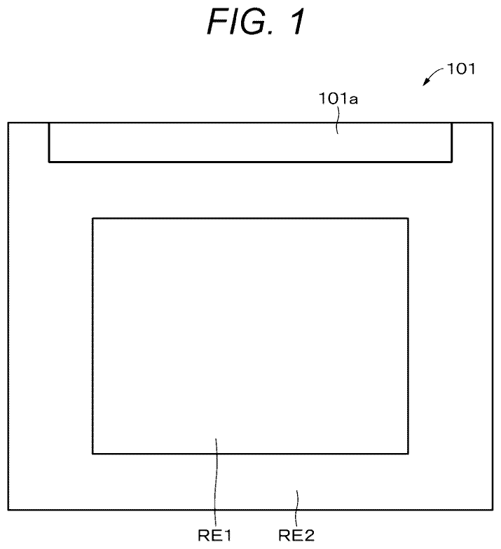

FIG. 1 is a plan view of a display device 101 according to a first embodiment. The display device 101 includes a display region RE1 and a peripheral region RE2 provided around the display region RE1.

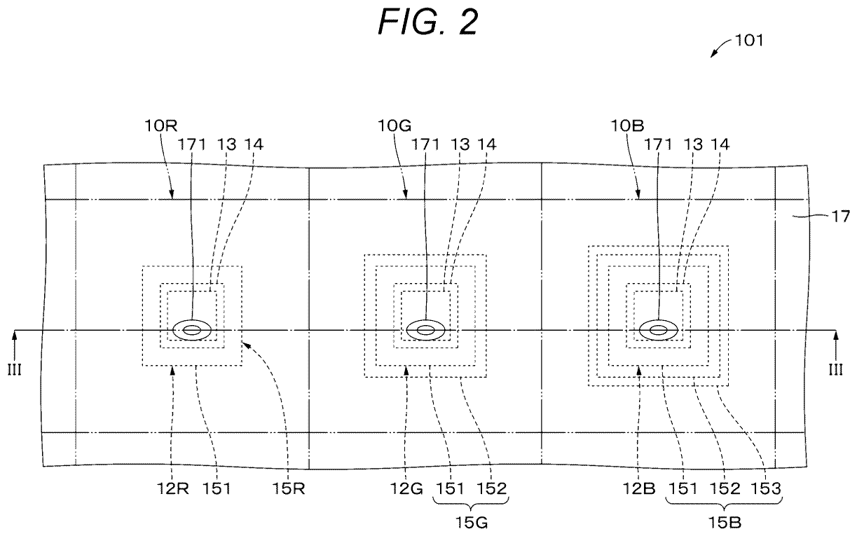

FIG. 2 is an enlarged plan view of a part of the display region RE1. A plurality of subpixels 10R, 10G, and 10B is two-dimensionally arranged in a prescribed arrangement pattern in the display region RE1. The prescribed arrangement pattern may be, for example, a stripe array, a delta array, a square array, a mosaic array, or an array other than these. A pad 101a, a video display driver (not illustrated), and the like are provided in the peripheral region RE2. A flexible printed circuit (FPC) board (not illustrated) may be connected to the pad 101a.

The subpixel 10R can emit red light (first light). The subpixel 10G can emit green light (second light). The subpixel 10B can emit blue light (third light). In the following description, the subpixels 10R, 10G, and 10B may be referred to as subpixel 10 unless otherwise distinguished. Each pixel (one pixel) may include, for example, a plurality of subpixels 10R, 10G, and 10B adjacent in the in-plane direction of a display surface. The configuration of each pixel, however, is not limited to this example.

The shape of the subpixel 10 is not particularly limited, but examples of the shape include, but are not limited to, a quadrilateral shape such as a rectangular shape, a hexagonal shape, and other shapes in plan view. Herein, it is assumed that the rectangular shape includes a square shape. The upper limit of the size of the subpixel 10 is preferably less than or equal to 10 μm, more preferably less than or equal to 8 μm, still more preferably less than or equal to 5 μm, less than or equal to 4 μm, or less than or equal to 3.5 μm. The lower limit of the size of the subpixel 10 is, for example, greater than or equal to 1 μm.

The display device 101 is an example of a light-emitting device. The display device 101 may be a top-emitting OLED display device. The display device 101 may be a microdisplay. The display device 101 may be provided in a virtual reality (VR) device, a mixed reality (MR) device, an augmented reality (AR) device, an electronic view finder (EVF), a small projector, or the like.

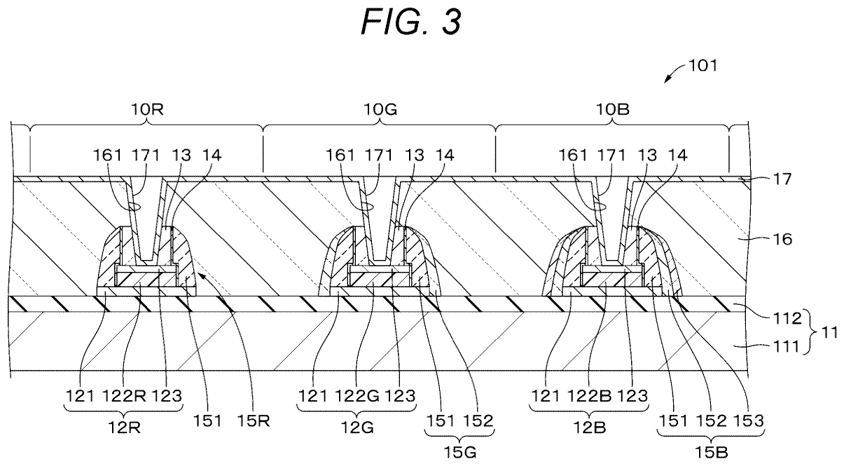

FIG. 3 is a cross-sectional view taken along line III-III in FIG. 2. The display device 101 includes a drive substrate 11, a plurality of light-emitting elements (first light-emitting elements) 12R, a plurality of light-emitting elements (second light-emitting elements) 12G, a plurality of light-emitting elements (third light-emitting elements) 12B, a plurality of protective layers 13, a plurality of side surface protective layers 14, a plurality of sidewalls 15R, a plurality of sidewalls 15G, a plurality of sidewalls 15B, a protective layer 16, and a common electrode 17.

Herein, of both the surfaces of each layer constituting the display device 101, a surface on the top side (display surface side) of the display device 101 may be referred to as first surface, and a surface on a bottom side (opposite side to the display surface) of the display device 101 may be referred to as second surface. Herein, the plan view refers to a plan view when an object is viewed from a direction perpendicular to the first surface. Herein, the cross-sectional view refers to a cross-sectional view when an object is viewed along a cut surface obtained by cutting the display device 101 along a plane passing through the geometric center of the light-emitting element 12 and parallel to the normal to the first surface. Herein, the peripheral edge portion of the first surface refers to a region extending inward from the peripheral edge of the first surface by a predetermined width, and the peripheral edge portion of the second surface refers to a region extending inward from the peripheral edge of the second surface by a predetermined width.

Note that, in the following description, the light-emitting elements 12R, 12G, and 12B may be collectively referred to as light-emitting element 12 unless otherwise distinguished. Furthermore, the sidewalls 15R, 15G, and 15B may be collectively referred to as sidewall 15 unless otherwise distinguished.

### (Drive Substrate 11)

The drive substrate 11 is a so-called backplane and drives the plurality of light-emitting elements 12R, 12G, and 12B. The drive substrate 11 includes, for example, a substrate 111 and an insulating layer 112 in sequence.

A plurality of drive circuits, a plurality of wiring lines (none of which are illustrated), and the like are provided on the first surface of the substrate 111. The substrate 111 may include, for example, a semiconductor that is easy to form, such as a transistor, or may include glass or resin having low moisture and oxygen permeability. Specifically, the substrate 111 may be a semiconductor substrate, a glass substrate, a resin substrate, or the like. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from the group consisting of polymethyl methacrylate, polyvinyl alcohol, polyvinyl phenol, polyethersulfone, polyimide, polycarbonate, polyethylene terephthalate, polyethylene naphthalate, and the like.

The insulating layer 112 is provided on the first surface of the substrate 111 to cover the plurality of drive circuits, the plurality of wiring lines, and the like for planarization of the first surface of the drive substrate 11. The insulating layer 112 may insulate the plurality of drive circuits, the plurality of wiring lines, and the like provided on the first surface of the substrate 111 from the plurality of light-emitting elements 12.

The insulating layer 112 may be an organic insulating layer, an inorganic insulating layer, or a laminate thereof. The organic insulating layer includes, for example, at least one selected from the group consisting of polyimide resin, acrylic resin, novolac resin, and the like. The inorganic insulating layer includes, for example, at least one selected from the group consisting of silicon oxide (SiOₓ), silicon nitride (SiNₓ), silicon oxynitride (SiOₓN_{y}), and the like.

### (Light-Emitting Elements 12R, 12G, and 12B)

The emission colors of the light-emitting element 12R, the light-emitting element 12G, and the light-emitting element 12B are different from each other. The light-emitting element 12R can emit red light under the control of the drive circuit and the like. The light-emitting element 12G can emit green light under the control of the drive circuit and the like. The light-emitting element 12B can emit blue light under the control of the drive circuit and the like. The light-emitting element 12 is an organic light emitting diode (OLED) element.

The light-emitting element 12R belongs to the subpixel 10R. The light-emitting element 12G belongs to the subpixel 10G. The light-emitting element 12B belongs to the subpixel 10B. The plurality of light-emitting elements 12 is two-dimensionally arranged on the first surface of the drive substrate 11 in a prescribed arrangement pattern. The prescribed arrangement pattern is as described for the prescribed arrangement pattern of the plurality of subpixels 10.

The light-emitting element 12R includes a first electrode 121, an OLED layer 122R, and a second electrode 123 in sequence on the first surface of the drive substrate 11. The light-emitting element 12G includes a first electrode 121, an OLED layer 122G, and a second electrode 123 in sequence on the first surface of the drive substrate 11. The light-emitting element 12B includes a first electrode 121, an OLED layer 122B, and a second electrode 123 in sequence on the first surface of the drive substrate 11.

### (OLED Layers 122R, 122G, 122B)

The OLED layer 122R can emit red light. The OLED layer 122G can emit green light. The OLED layer 122B can emit blue light. The OLED layers 122R, 122G, and 122B are examples of the organic-containing layer in the claims.

The OLED layers 122R, 122G, and 122B are each provided between the first electrode 121 and the second electrode 123. The OLED layer 122R includes an organic light-emitting layer that can emit red light (hereinafter, referred to as “red organic light-emitting layer”). The OLED layer 122R includes an organic light-emitting layer that can emit green light (hereinafter, referred to as “green organic light-emitting layer”). The OLED layer 122B includes an organic light-emitting layer that can emit blue light (hereinafter, referred to as “blue organic light-emitting layer”). Furthermore, in the following description, the OLED layers 122R, 122G, and 122B may be collectively referred to as OLED layer 122 unless otherwise distinguished. The red organic light-emitting layer, the green organic light-emitting layer, and the blue organic light-emitting layer may be collectively referred to as organic light-emitting layer unless otherwise distinguished.

The OLED layers 122R, 122G, and 122B may each include a laminate including the corresponding organic light-emitting layer, and in this case, a part of the laminate (for example, an electron injection layer) may be an inorganic layer. In a case where each of the OLED layers 122R, 122G, and 122B is a laminate, the OLED layers 122R, 122G, and 122B may each include an organic-containing layer (for example, an electron transport layer or an electron injection layer) on the surface in contact with the second electrode 123. In this case, the adhesion between the OLED layer 122 and the second electrode 123 tends to decrease significantly, so that it is particularly effective to provide a side surface protective layer 14.

The OLED layer 122R includes, for example, a hole injection layer, a hole transport layer, a red organic light-emitting layer, an electron transport layer, and an electron injection layer in sequence from the first electrode 121 to the second electrode 123. The OLED layer 122G includes, for example, a hole injection layer, a hole transport layer, a green organic light-emitting layer, an electron transport layer, and an electron injection layer in sequence from the first electrode 121 to the second electrode 123. The OLED layer 122G includes, for example, a hole injection layer, a hole transport layer, a blue organic light-emitting layer, an electron transport layer, and an electron injection layer in sequence from the first electrode 121 to the second electrode 123.

The red organic light-emitting layer can emit red light through recombination of holes injected from the first electrode 121 and electrons injected from the second electrode 123. The green organic light-emitting layer can emit green light through a phenomenon similar to the red organic light-emitting layer. The blue organic light-emitting layer can emit blue light through a phenomenon similar to the red organic light-emitting layer.

The hole injection layer can enhance the efficiency of hole injection into each organic light-emitting layer and suppress leakage. The hole transport layer can enhance the efficiency of hole transport to the each organic light-emitting layer. The electron injection layer can enhance the efficiency of electron injection into each organic light-emitting layer. The electron transport layer can enhance the efficiency of electron transport to each organic light-emitting layer.

### (First Electrode 121)

The first electrode 121 is provided on the second surface of the OLED layer 122. The first electrode 121 is provided individually for each of the plurality of light-emitting elements 12 in the display region RE1. That is, the first electrode 121 is divided between the light-emitting elements 12 adjacent in the in-plane direction in the display region RE1. Herein, the in-plane direction refers to the in-plane direction of the first surface of the drive substrate 11 unless otherwise specified. The first electrode 121 is larger in size than the OLED layer 122 and the second electrode 123 in plan view, and the side surface of the first electrode 121 is located outside the side surfaces of both the OLED layer 122 and the second electrode 123. That is, the peripheral edge portion of the first surface of the first electrode 121 is exposed without being covered by the OLED layer 122 and the second electrode 123. The first electrode 121 is an anode. When a voltage is applied between the first electrode 121 and the second electrode 123, holes are injected from the first electrode 121 into the OLED layer 122.

The first electrode 121 may include, for example, a metal layer, or may include a metal layer and a transparent conductive oxide layer. In a case where the first electrode 121 includes a metal layer and a transparent conductive oxide layer, the transparent conductive oxide layer is preferably provided adjacent to the OLED layer 122 from the viewpoint of placing a layer with a high work function adjacent to the OLED layer 122.

The metal layer also functions as a reflective layer that reflects light emitted from the OLED layer 122. The metal layer includes, for example, at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

An underlayer (not illustrated) may be provided adjacent to the second surface of the metal layer. The underlayer is provided to improve the crystal orientation of the metal layer during formation of the metal layer. The underlayer includes, for example, at least one metal element selected from the group consisting of titanium (Ti) and tantalum (Ta). The underlayer may include the at least one metal element described above as a constituent element of an alloy.

The transparent conductive oxide layer includes a transparent conductive oxide. The transparent conductive oxide includes, for example, at least one selected from the group consisting of indium-containing transparent conductive oxide (hereinafter referred to as “indium-based transparent conductive oxide”), tin-containing transparent conductive oxide (hereinafter referred to as “tin-based transparent conductive oxide”), and zinc-containing transparent conductive oxide (hereinafter referred to as “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO), or fluorine-doped indium oxide (IFO). Among these transparent conductive oxides, the indium tin oxide (ITO) is particularly preferable. This is because the indium tin oxide (ITO) has a particularly low barrier for hole injection into the OLED layers 122R, 122G, and 122B in terms of work function, and accordingly, the drive voltage of the display device 101 can be significantly reduced. The tin-based transparent conductive oxide includes, for example, tin oxide, antimony-doped tin oxide (ATO), or fluorine-doped tin oxide (FTO). The zinc-based transparent conductive oxide includes, for example, zinc oxide, aluminum-doped zinc oxide (AZO), boron-doped zinc oxide, or gallium-doped zinc oxide (GZO).

### (Second Electrode 123)

The second electrode 123 is provided on the first surface of the OLED layer 122. The second electrode 123 is provided individually for each of the plurality of light-emitting elements 12 in the display region RE1. That is, the second electrode 123 is divided between the light-emitting elements 12 adjacent in the in-plane direction in the display region RE1. The second electrode 123 is approximately the same in size as the OLED layer 122 in plan view. The side surface of the second electrode 123 and the side surface of the OLED layer 122 are approximately flush with each other.

The second electrode 123 is a cathode. When a voltage is applied between the first electrode 121 and the second electrode 123, electrons are injected from the second electrode 123 into the OLED layer 122. The second electrode 123 is transparent to each light emitted from the OLED layers 122R, 122G, and 122B. The second electrode 123 is preferably a transparent electrode transparent to visible light. Herein, the visible light refers to light in a wavelength range of 360 nm to 830 nm.

The second electrode 123 preferably includes a material having as high transparent as possible and a low work function in order to enhance the luminous efficiency. The second electrode 123 includes, for example, at least one of a metal layer or a transparent conductive oxide layer. More specifically, the second electrode 123 includes a single-layer film of a metal layer or a transparent conductive oxide layer, or a multilayer film of a metal layer and a transparent conductive oxide layer. In a case where the second electrode 123 includes a multilayer film, the metal layer may be provided adjacent to the OLED layer 122, or the transparent conductive oxide layer may be provided adjacent to the OLED layer 122, but, from the viewpoint of placing a layer with a low work function adjacent to the OLED layer 122, the metal layer is preferably provided adjacent to the OLED layer 122.

The second electrode 123 is preferably lower in etching rate than the protective layer 13. In this case, in the process of etching the protective layer 13 and the second electrode 123, the protective layer 13 becomes more prone to side etching. That is, a step 123S is easily formed between the side surface of the protective layer 13 and the side surface of the second electrode 123. The second electrode 123 may include an etch-resistant material.

The metal layer includes, for example, at least one metal element selected from the group consisting of magnesium (Mg), aluminum (Al), silver (Ag), calcium (Ca), and sodium (Na). The metal layer may include the at least one metal element described above as a constituent element of an alloy. Specific examples of the alloy include an MgAg alloy, an MgAl alloy, an AlLi alloy, and the like. The transparent conductive oxide layer includes a transparent conductive oxide. As the transparent conductive oxide, a material similar to the transparent conductive oxide of the first electrode 121 described above can be exemplified.

### (Protective Layer 13)

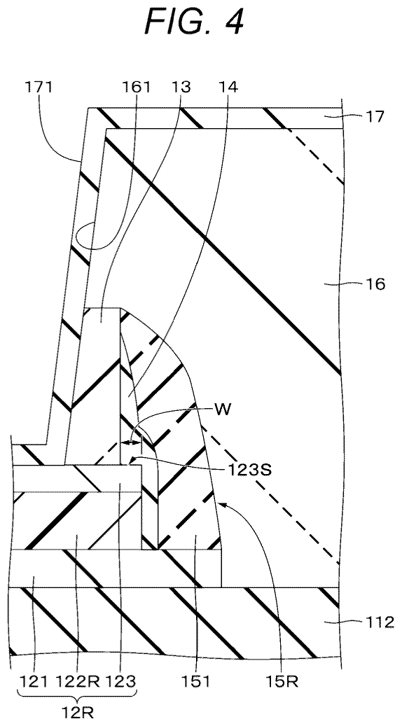

FIG. 4 is an enlarged cross-sectional view of a part of the light-emitting element 12R. The protective layer 13 is provided on the first surface of the second electrode 123. The protective layer 13, along with the second electrode 123, is separated between the adjacent light-emitting elements 12. The side surface of the protective layer 13 is preferably located inside the side surface of the second electrode 123 in the in-plane direction. Here, the side surface of the protective layer 13 being located inside the side surface of the second electrode 123 in the in-plane direction means that the peripheral edge of the second surface of the protective layer 13 is located inside the peripheral edge of the first surface of the second electrode 123 in the in-plane direction.

More specifically, the step 123S is preferably provided between the side surface of the protective layer 13 and the side surface of the second electrode 123. The step 123S includes an exposed portion where the peripheral edge portion of the first surface of the second electrode 123 is exposed without being covered by the protective layer 13. The exposed portion may have a closed loop shape surrounding the entire peripheral edge of the second surface of the protective layer 13, or may have a segmented loop shape partially surrounding the peripheral edge of the second surface of the protective layer 13.

As described above, since the step 123S is provided between the side surface of the protective layer 13 and the side surface of the second electrode 123, residues can be deposited on the step 123S through the process of processing the protective layer 13, the second electrode 123, and the OLED layer 122. Therefore, as compared with a case where the step 123S is not provided between the side surface of the protective layer 13 and the side surface of the second electrode 123, that is, as compared with a case where the side surface of the protective layer 13 and the side surface of the second electrode 123 are flush with each other, it is possible to increase the amount of residues deposited in the vicinity of the step 123S through the process of processing the protective layer 13, the second electrode 123, and the OLED layer 122. That is, it is possible to increase the thickness of the side surface protective layer 14 located in the vicinity of the step 123S. It is thus possible to prevent delamination between the OLED layer 122 and the second electrode 123. Here, it is assumed that the vicinity of the step 123S includes a boundary between the side surface of the second electrode 123 and the side surface of the OLED layer 122.

A width W of the step 123S is preferably greater than or equal to 50 nm, more preferably greater than or equal to 60 nm, still more preferably greater than or equal to 70 nm, 80 nm, 90 nm, or 100 nm from the viewpoint of increasing the amount of residues deposited in the vicinity of the step 123S.

The width W of the step 123S is preferably less than or equal to 200 nm, more preferably less than or equal to 180 nm, still more preferably less than or equal to 160 nm, 140 nm, or 120 nm from the viewpoint of suppressing a reduction in the area of the light-emitting region of the light-emitting element 12.

The width W of the step 123S is determined as follows. First, a cross section of the display device 101 (a cross section parallel to the thickness direction of the display device 101) is cut out by cryo-focused ion beam (FIB) processing or the like to prepare a thin piece. Subsequently, the prepared thin piece is observed under a transmission electron microscope (TEM) to acquire one cross-sectional TEM image. Next, the width W of the step 123S in the acquired cross-sectional TEM image is measured.

The side wall of the protective layer 13 may be perpendicular or at an angle to the first surface of the second electrode 123. In a case where the side wall of the protective layer 13 is at an angle, the side wall of the protective layer 13 may have a tapered shape or a flared shape. Here, the tapered shape refers to a shape in which the first surface (upper surface) of the protective layer 13 is narrower than the second surface (lower surface) of the protective layer 13, and the flared shape refers to a shape in which the first surface (upper surface) of the protective layer 13 of the protective layer 13 is wider than the second surface (lower surface).

The protective layer 13 can protect the first surface of the light-emitting element 12. The protective layer 13 can suppress moisture ingress into the display device 101 from an external environment to suppress deterioration of the plurality of light-emitting elements 12. Furthermore, in a case where the second electrode 123 includes a metal layer, the protective layer 13 may have a function of suppressing oxidation of the metal layer. The protective layer 13 is transparent to each light emitted from the light-emitting elements 12R, 12G, and 12B. The protective layer 13 is preferably transparent to the visible light.

The protective layer 13 includes, for example, a material with low hygroscopicity, such as an inorganic material or polymer resin. The protective layer 13 may have a single layer structure or a multilayer structure. In a case where the thickness of the protective layer 13 is increased, a multilayer structure is preferable. This is to alleviate the internal stress in the protective layer 13. The inorganic material includes, for example, at least one selected from the group consisting of silicon oxide (SiOₓ), silicon nitride (SiNₓ), silicon oxynitride (SiOₓN_{y}), titanium oxide (TiOₓ), aluminum oxide (AlOₓ), and the like. The polymer resin includes, for example, at least one resin selected from the group consisting of thermosetting resin, ultraviolet curable resin, and the like. Specifically, the polymer resin includes, for example, at least one selected from the group consisting of acrylic resin, polyimide resin, novolac resin, epoxy resin, norbornene resin, parylene resin, and the like.

### (Side Surface Protective Layer 14)

The side surface protective layer 14 covers at least the boundary between the side surface of the OLED layer 122 and the side surface of the second electrode 123. This configuration can reduce the impact of film stress of the protective layer 13 on the interface between the OLED layer 122 and the second electrode 123. The side surface protective layer 14 may cover a range from the side surface of the OLED layer 122 to the side surface of the protective layer 13. More specifically, the side surface protective layer 14 may cover the side surface of the OLED layer 122, the side surface of the second electrode 123, the step 123S (the peripheral edge portion of the second surface of the second electrode 123), and the side surface of the protective layer 13. The side surface protective layer 14 may cover the entire side surface of the protective layer 13, or may cover a prescribed height range on the side surface of the protective layer 13, starting from the peripheral edge of the second surface of the protective layer 13. The side surface protective layer 14 may have a closed loop shape or a segmented loop shape in plan view.

The side surface protective layer 14 can protect the side surface of the light-emitting element 12. For example, the side surface protective layer 14 may be capable of suppressing moisture ingress into the light-emitting element 12 from an external environment to suppress deterioration of the light-emitting element 12. The side surface protective layer 14 is transparent to each light emitted from the light-emitting elements 12R, 12G, and 12B. The side surface protective layer 14 is preferably transparent to the visible light. The side surface protective layer 14 preferably has insulating properties.

The side surface protective layer 14 may include residues deposited as a result of etching of the protective layer 13, the second electrode 123, and the OLED layer 122, or may include residues deposited as a result of etching of the protective layer 13, the second electrode 123, the OLED layer 122, and the first electrode 121. The side surface protective layer 14 may include the constituent materials of the protective layer 13, the constituent materials of the second electrode 123, and the constituent materials of the OLED layer 122, or may include the constituent materials of the protective layer 13, the constituent materials of the second electrode 123, the constituent materials of the OLED layer 122, and the constituent materials of the first electrode 121.

The constituent materials of the protective layer 13 included in the side surface protective layer 14 may include some or all of the constituent materials of the protective layer 13. The constituent materials of the second electrode 123 included in the side surface protective layer 14 may include some or all of the constituent materials of the second electrode 123. The constituent materials of the OLED layer 122 included in the side surface protective layer 14 may include some or all of the constituent materials of the OLED layer 122.

The constituent materials of the first electrode 121 included in the side surface protective layer 14 may include some or all of the constituent materials of the first electrode 121.

### (Sidewalls 15R, 15G, 15B)

The sidewall 15R covers the side surfaces of both the light-emitting element 12R and the protective layer 13, where the side surface protective layer 14 is provided. The sidewall 15R preferably has insulating properties. The sidewall 15R may include a first sidewall 151. The first sidewall 151 is provided on the peripheral edge portion of the first surface of the first electrode 121 and covers the side surface protective layer 14.

The sidewall 15G covers the side surfaces of both the light-emitting element 12G and the protective layer 13, where the side surface protective layer 14 is provided. The sidewall 15G preferably has insulating properties. The sidewall 15G may include a first sidewall 151 and a second sidewall 152. The second sidewall 152 is provided on the first surface of the drive substrate 11 and covers the side surface of the first electrode 121 and the side surface of the first sidewall 151.

The sidewall 15B covers the side surfaces of both the light-emitting element 12B and the protective layer 13, where the side surface protective layer 14 is provided. The sidewall 15B preferably has insulating properties. The sidewall 15G may include a first sidewall 151, a second sidewall 152, and a third sidewall 153. The third sidewall 153 is provided on the first surface of the drive substrate 11 and covers the side surface of the second sidewall 152.

The first sidewall 151, the second sidewall 152, and the third sidewall 153 may be transparent to each light emitted from the light-emitting elements 12R, 12G, and 12B. The first sidewall 151, the second sidewall 152, and the third sidewall 153 are preferably transparent to the visible light.

The first sidewall 151, the second sidewall 152, and the third sidewall 153 include, for example, an inorganic material with low hygroscopicity. As the inorganic material, an inorganic material similar to that of the protective layer 13 can be exemplified. The materials of the first sidewall 151, the second sidewall 152, and the third sidewall 153 may be the same or different.

### (Protective Layer 16)

The protective layer 16 is provided on the first surface of the drive substrate 11 to cover the plurality of light-emitting elements 12, each provided with the sidewall 15. The protective layer 16 can protect the plurality of light-emitting elements 12 and the like. For example, the protective layer 16 can suppress moisture ingress into the light-emitting device 101 from an external environment to suppress deterioration of the plurality of light-emitting elements 12 and the like. The protective layer 16 is transparent to each light emitted from the light-emitting elements 12R, 12G, and 12B. The protective layer 16 is preferably transparent to the visible light.

The protective layer 16 includes a plurality of contact holes 161. Each contact hole 161 extends from the first surface of the protective layer 16 to the second surface of the light-emitting element 12. The contact hole 161 may be provided in the light-emitting region of the light-emitting element 12 in plan view, or may be provided outside the light-emitting region of the light-emitting element 12 in plan view. FIGS. 2 and 3 illustrate an example where the contact hole 161 is provided in the light-emitting region of the light-emitting element 12 in plan view.

The protective layer 16 includes, for example, a material with low hygroscopicity, such as an inorganic material or polymer resin. The protective layer 16 may have a single layer structure or a multilayer structure. In a case where the thickness of the protective layer 16 is increased, a multilayer structure is preferable. This is to alleviate the internal stress in the protective layer 16. As the inorganic material, an inorganic material similar to that of the protective layer 13 can be exemplified. As the polymer resin, a polymer resin similar to that of the protective layer 13 can be exemplified.

### (Common Electrode 17)

The common electrode 17 is provided on the first surface of the protective layer 16. The common electrode 17 is connected between the light-emitting elements 12 adjacent in the in-plane direction in the display region RE1, and serves as a common electrode for the plurality of light-emitting elements 12 provided in the display region RE1. The common electrode 17 is transparent to each light emitted from the light-emitting elements 12R, 12G, and 12B. The common electrode 17 is preferably transparent to the visible light. The common electrode 17 extends from the display region RE1 to the peripheral region RE2. The common electrode 17 has its peripheral edge portion connected to a contact electrode (not illustrated). The contact electrode is provided on the peripheral edge portion of the first surface of the drive substrate 11. The contact electrode is an auxiliary electrode that connects the common electrode 17 and the corresponding wiring line of the drive substrate 11.

The common electrode 17 is connected to each second electrode 123 separated for each subpixel 10. Specifically, the common electrode 17 includes a plurality of contact portions 171, and each of the plurality of contact portions 171 is provided in the contact hole 161 of the protective layer 16. With this configuration, the ends of the plurality of contact portions 171 are each connected to the first surface of the corresponding second electrode 123 separated for each subpixel 10. However, the connection form between the contact portion 171 and the second electrode 123 is not limited to this example, and for example, the contact portion 171 may be connected to the side surface of the second electrode 123. Although FIGS. 2 and 3 illustrate an example where one contact portion 171 is provided for each subpixel 10, two or more contact portions 171 may be provided for each subpixel 10.

### [Method for Manufacturing Display Device]

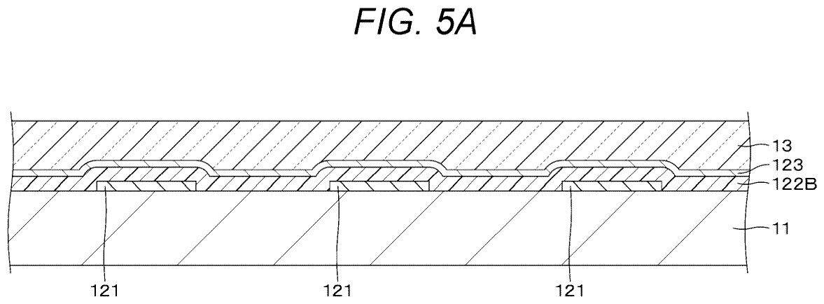

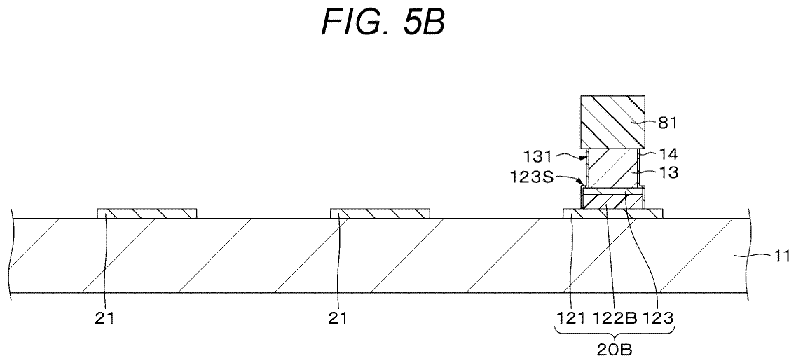

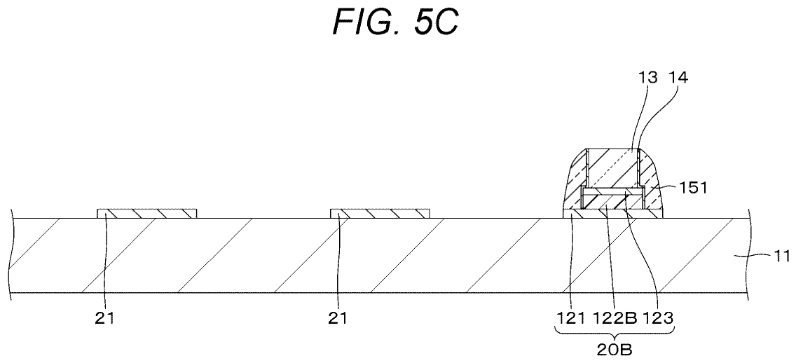

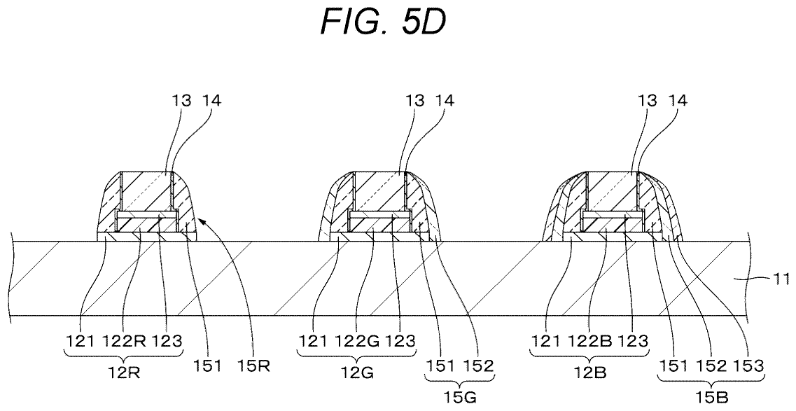

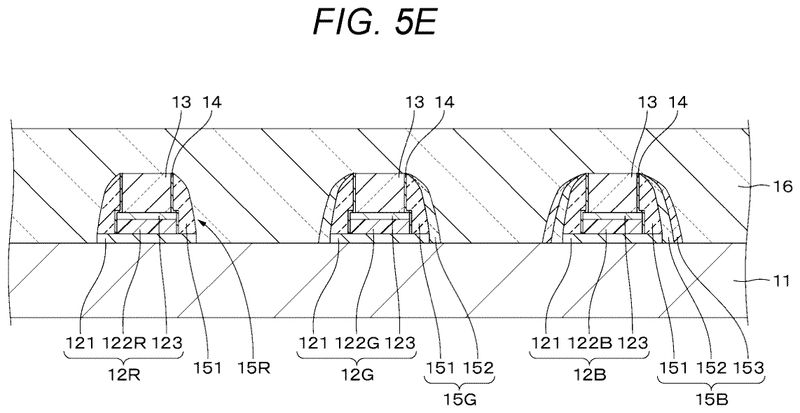

Hereinafter, an example of a method for manufacturing the display device 101 according to the first embodiment will be described with reference to FIGS. 5A to 5E.

First, a metal layer (for example, an aluminum layer having a thickness of about 200 nm) is formed on the first surface of the drive substrate 11 using, for example, a sputtering method, and then the metal layer is patterned using, for example, photolithography and dry etching. As a result, the plurality of first electrodes 121 is formed on the first surface of the drive substrate 11.

Next, a hole injection layer, a hole transport layer, a blue organic light-emitting layer, an electron transport layer, and an electron injection layer are stacked in this order on the first surfaces of the plurality of first electrodes 121 and the first surface of the drive substrate 11 using, for example, a vapor deposition method to form the OLED layer 122B. Next, the second electrode 123 (for example, an IZO layer having a thickness of about 60 nm) is formed on the first surface of the OLED layer 122B using, for example, a vapor deposition or sputtering method.

Next, as illustrated in FIG. 5A, the protective layer (for example, a silicon nitride layer having a thickness of about 1 μm) 13 is formed on the first surface of the second electrode 123 using, for example, a chemical vapor deposition (CVD) method. Next, as illustrated in FIG. 5B, the protective layer 13, the second electrode 123, and the OLED layer 122B that are not coincident with the plurality of subpixels 10B are removed using, for example, photolithography and dry etching to form the plurality of light-emitting elements 12B the first surface of the drive substrate 11. In the dry etching, the side surface protective layer 14 is formed over the side surface of the OLED layer 122B and the side surface of the protective layer 13.

Specifically, the plurality of light-emitting elements 12B and the side surface protective layer 14 are formed as follows. A resist is applied onto the first surface of the protective layer 13 and cured to form a resist layer 81, and then the resist layer 81 is exposed and developed. As a result, an island-shaped resist layer 81 remains at a position corresponding to each of the plurality of subpixels 10B.

Dry etching the protective layer 13, the second electrode 123, and the OLED layer 122B sequentially using the resist layer 81 as a mask removes the protective layer 13, the second electrode 123, and the OLED layer 122B that are not coincident with the plurality of subpixels 10B. In the dry etching of the protective layer 13, the protective layer 13 is side-etched to remove the protective layer 13 located below the peripheral edge portion of the resist layer 81, thereby forming a side-etched portion 131. This allows the side surface of the protective layer 13 to be located inside the side surface of the second electrode 123 in the in-plane direction. That is, the step 123S can be formed between the side surface of the protective layer 13 and the side surface of the second electrode 123.

When the protective layer 13, the second electrode 123, and the OLED layer 122B are etched, the constituent materials of the protective layer 13, the second electrode 123, and the OLED layer 122B are sputtered by ions and deposited not only on the side-etched portion 131, but also on the side surface of the second electrode 123 and the side surface of the OLED 122B to form the side surface protective layer 14. Since the resist layer 81 overhangs the step 123S, the incidence of ions on the residues deposited on the side-etched portion 131 is reduced. This can increase the amount of both the residues deposited on the step 123S and the residues deposited in the vicinity of the step 123S. Here, it is assumed that the vicinity of the step 123S includes a boundary between the side surface of the second electrode 123 and the side surface of the OLED layer 122B.

Next, an insulating layer (for example, a silicon nitride layer having a thickness of about 100 nm) is formed using, for example, a CVD method, and then the insulating layer is etched back using, for example, dry etching to form a plurality of sidewalls 15B as illustrated in FIG. 5C.

Next, as illustrated in FIG. 5D, the plurality of light-emitting elements 12R, the plurality of light-emitting elements 12G, the plurality of sidewalls 15R, and the plurality of sidewalls 15G are formed on the first surface of the drive substrate 11 through a procedure similar to the formation of the light-emitting elements 12B and the sidewalls 15B.

Next, as illustrated in FIG. 5E, the protective layer (for example, a silicon nitride layer) 16 is formed to cover the plurality of light-emitting elements 12R, 12G, and 12B using, for example, a CVD method. Next, the first surface of the protective layer 16 may be polished for planarization by, for example, chemical mechanical polishing (CMP), as necessary. Next, the protective layer 16 and the protective layer 13 are processed using, for example, photolithography and dry etching to form the contact hole 161 on each of the plurality of light-emitting elements 12R, 12G, and 12B. Next, the common electrode 17 (for example, an IZO layer) is formed on the first surface of the protective layer 16 and in the contact hole 161 using, for example, a vapor deposition or sputtering method. Through the above-described processes, the display device 101 is obtained.

### Effects

In the display device 101 according to the first embodiment, the side surface protective layer 14 covers at least the boundary between the side surface of the OLED layer 122 and the side surface of the second electrode 123. This configuration can reduce the impact of film stress of the protective layer 13 on the interface between the OLED layer 122 and the second electrode 123. It is therefore possible to prevent delamination between the OLED layer 122 and the second electrode 123. It is thus possible to prevent an increase in the drive voltage of the light-emitting element 12.

In a case where the side surface protective layer 14 covers the side surface of the OLED layer 122, the side surface of the second electrode 123, and the side surface of the protective layer 13, the side surface of the protective layer 13 is preferably located inside the side surface of the second electrode 123 in the in-plane direction, and the step 123S is preferably formed between the side surface of the protective layer 13 and the side surface of the second electrode 123. With this configuration, when the protective layer 13, the second electrode 123, and the OLED layer 122 are etched, residues can be deposited on the step 123S. Therefore, as compared with a case where step 123S does not exist, the amount of residues deposited in the vicinity of the step 123S can be increased, which helps to increase the thickness of the side surface protective layer 14 in the vicinity of the step 123S. It is therefore possible to prevent delamination between the OLED layer 122 and the second electrode 123. It is thus possible to further prevent an increase in the drive voltage of the display device 101.

### 2 Second Embodiment

### [Configuration of Display Device]

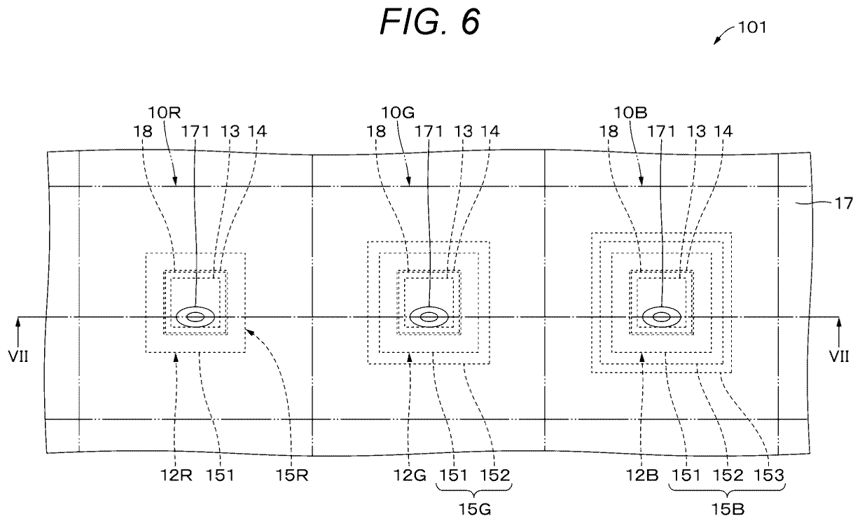

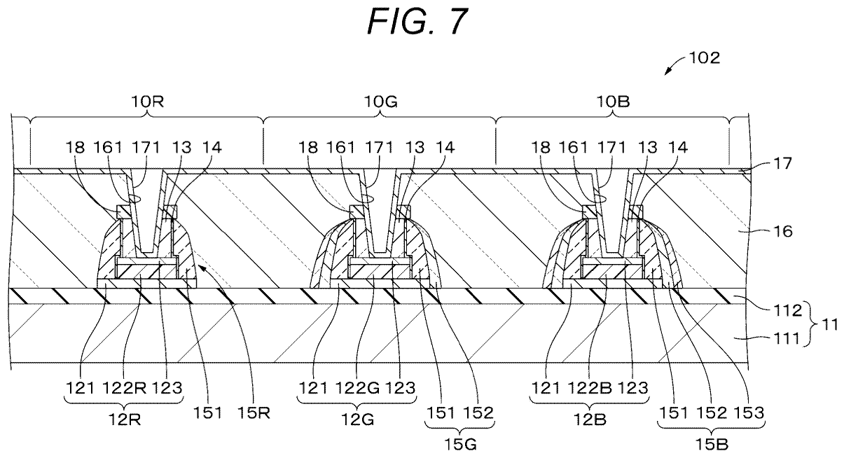

FIG. 6 is an enlarged plan view of a part of a display region RE1 of a display device 102 according to a second embodiment. FIG. 7 is a cross-sectional view taken along line VII-VII in FIG. 6. The display device 102 is different from the display device 101 according to the first embodiment in that the display device 102 further includes a protective layer 18.

The protective layer 18 is provided on the first surface of the protective layer 13. A protective layer having a multilayer structure includes the protective layer 13 and the protective layer 18. In the second embodiment, the protective layer 13 is an example of the first protective layer in the claims, and the protective layer 18 is an example of the second protective layer in the claims.

The side surface of the protective layer 18 may be located outside the side surface of the protective layer 13 in the in-plane direction. That is, the peripheral edge portion of the protective layer 18 may protrude in a flange shape relative to the side surface of the protective layer 13. The flange-shaped protruding portion may have a closed loop shape in plan view.

The protective layer 18, along with the protective layer 13, can protect the first surface of the light-emitting element 12. The protective layer 18 can suppress moisture ingress into the plurality of light-emitting elements 12 from an external environment. The protective layer 18 is transparent to each light emitted from the light-emitting elements 12R, 12G, and 12B. The protective layer 18 is preferably transparent to the visible light. The protective layer 18 may be usable as a hard mask for the manufacturing process of the display device 102.

The protective layer 18 preferably includes a monolayer. The protective layer 18 may include a monolayer deposit. More specifically, the protective layer 18 may be an atomic layer deposition (ALD) layer. When the protective layer 18 includes a monolayer, it is possible to enhance the moisture ingress suppression effect of the protective layer 18.

The protective layer 18 is preferably lower in etching rate than the protective layer 13. In this case, in the process of etching the protective layer 13 using the protective layer 18 as a hard mask, the protective layer 13 becomes more prone to side etching. The protective layer 18 may include an etch-resistant material.

The protective layer 18 includes, for example, an inorganic material with low hygroscopicity. The inorganic material includes, for example, metal oxide. More specifically, the inorganic material includes, for example, aluminum oxide (AlOₓ) or titanium oxide (TiOₓ).

### [Method for Manufacturing Display Device]

### First Example

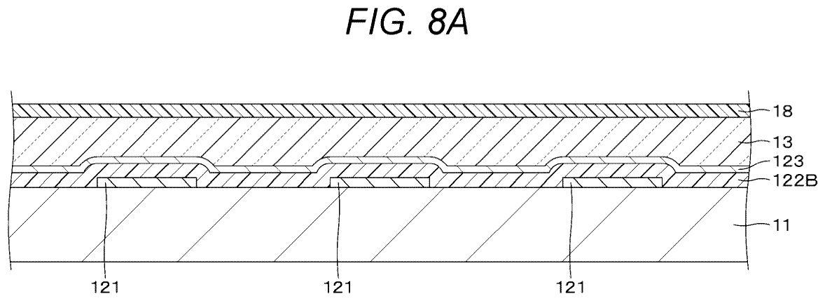

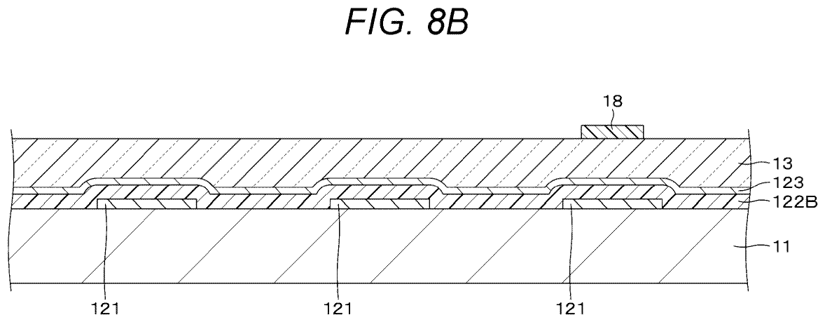

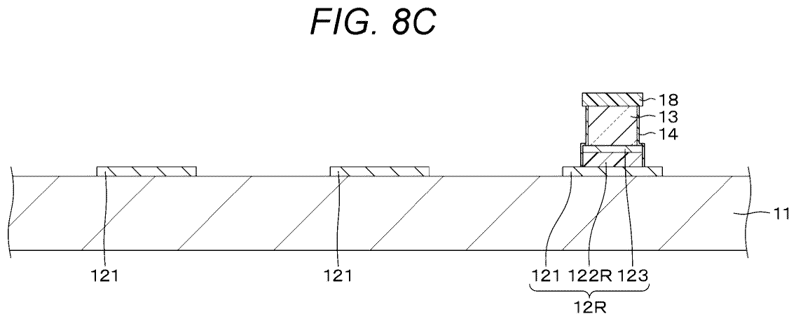

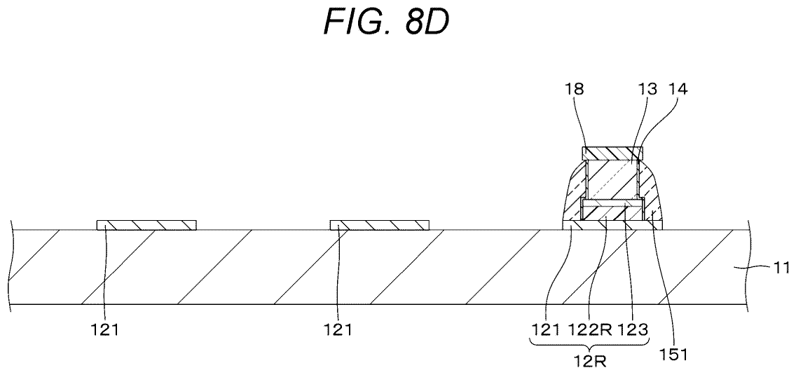

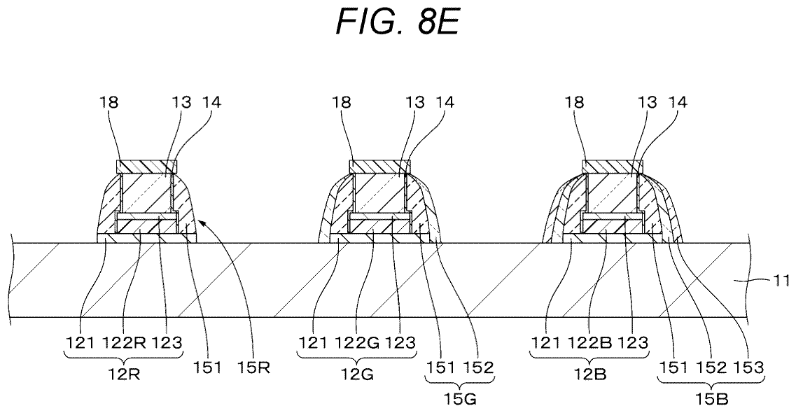

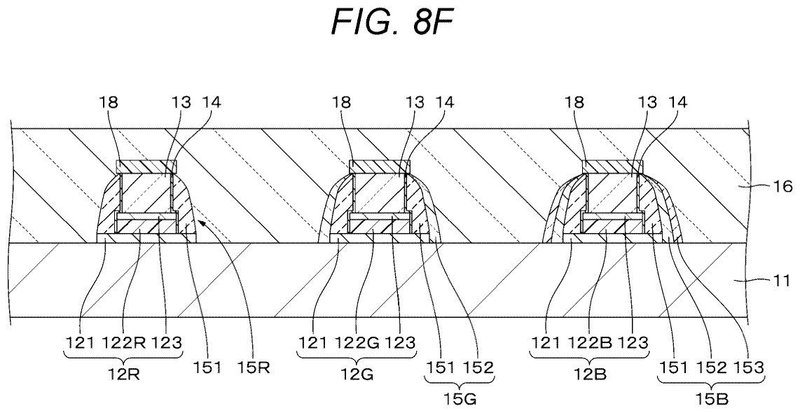

Hereinafter, a first example of the method for manufacturing the display device 102 according to the second embodiment will be described with reference to FIGS. 5A and FIGS. 8A to 8F.

First, the process from the formation of the first electrode 121 to the formation of the protective layer 13 is performed in a similar manner as the method for manufacturing the display device 101 according to the first embodiment (see FIG. 5A). In the second embodiment, the protective layer 13 may be, for example, a SiN layer having a thickness of about 200 nm. Next, as illustrated in FIG. 8A, the protective layer (an aluminum oxide layer having a thickness of about 60 nm) 18 is formed on the first surface of the protective layer 13 using, for example, a CVD method.

Next, the protective layer 18 is processed using, for example, photolithography and dry etching. As a result, as illustrated in FIG. 8B, a plurality of island-shaped protective layers 18 remains at positions corresponding to the plurality of subpixels 10B. Next, a resist layer (not illustrated) on the first surfaces of the plurality of protective layers 18 is removed by, for example, ashing.

Next, using the plurality of protective layers 18 as hard masks, the protective layer 13, the OLED layer 122B, and the second electrode 123 that are not coincident with the plurality of subpixels 10B are removed by dry etching. As a result, as illustrated in FIG. 8C, the plurality of light-emitting elements 12B is formed on the first surface of the drive substrate 11. In the dry etching, the side surface protective layer 14 is formed over the side surface of the OLED layer 122B and the side surface of the protective layer 13.

When the protective layer 13, the second electrode 123, and the OLED layer 122B are etched, the constituent materials of the protective layer 13, the second electrode 123, and the OLED layer 122B are sputtered by ions and deposited not only on the side-etched portion 131, but also on the side surface of the second electrode 123 and the side surface of the OLED layer 122B to form the side surface protective layer 14. Since the protective layer (hard mask) 18 overhangs the step 123S, the incidence of ions on the residues deposited on the side-etched portion 131 is reduced. This can increase the amount of both the residues deposited on the step 123S and the residues deposited in the vicinity of the step 123S.

Next, a protective layer (for example, a silicon nitride layer having a thickness of about 100 nm) is formed using, for example, a CVD method, and then the protective layer is etched back using, for example, dry etching to form the plurality of first sidewalls 151 as illustrated in FIG. 8D.

Next, as illustrated in FIG. 8E, the plurality of light-emitting elements 12R, the plurality of light-emitting elements 12G, the plurality of sidewalls 15R, and the plurality of sidewalls 15G are formed on the first surface of the drive substrate 11 through a procedure similar to the formation of the light-emitting elements 12B and the sidewalls 15B.

Next, as illustrated in FIG. 8F, the protective layer (for example, a silicon nitride layer) 16 is formed to cover the plurality of light-emitting elements 12R, 12G, and 12B using, for example, a CVD method. Next, the first surface of the protective layer 16 may be polished for planarization by, for example, chemical mechanical polishing (CMP), as necessary. Next, the protective layer 16, the protective layer 18, and the protective layer 13 are processed using, for example, photolithography and dry etching to form the contact hole 161 on each of the plurality of light-emitting elements 12R, 12G, and 12B. Next, the common electrode 17 (for example, an IZO layer) is formed on the first surface of the protective layer 16 and in the contact hole 161 using, for example, a vapor deposition or sputtering method. Through the above-described processes, the display device 102 is obtained.

### Second Example

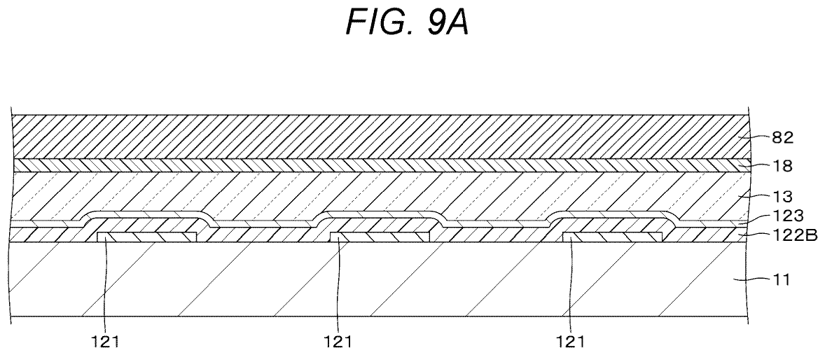

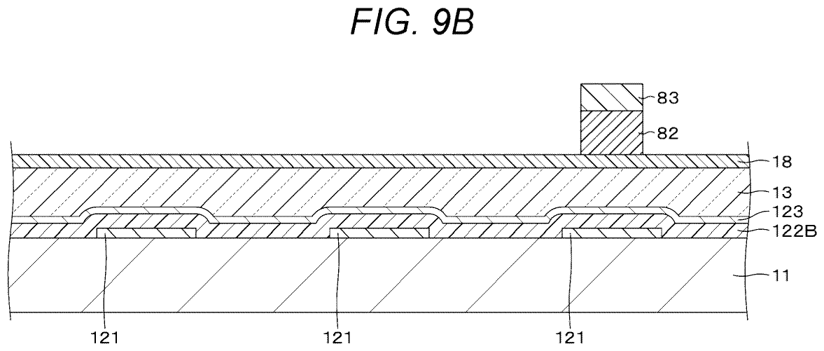

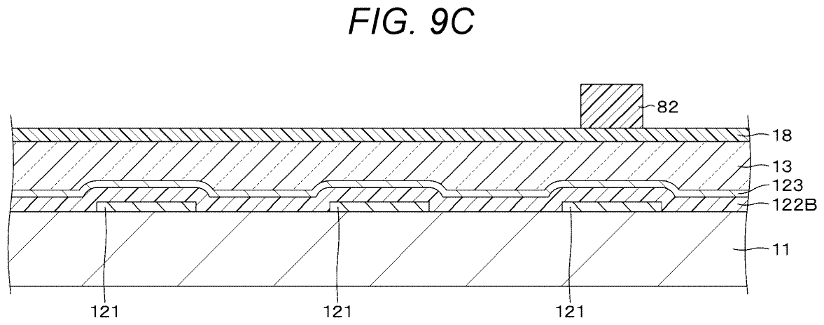

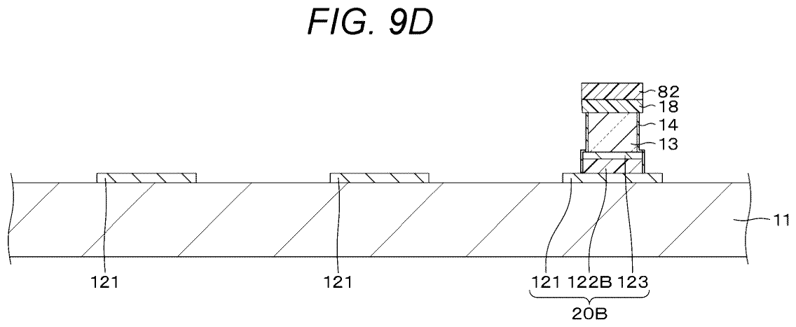

Hereinafter, a second example of the method for manufacturing the display device 102 according to the second embodiment will be described with reference to FIGS. 8A and FIGS. 9A to 9D.

First, the process from the formation of the first electrode 121 to the formation of the protective layer 18 is performed in a similar manner as the first example (see FIG. 8A). Next, as illustrated in FIG. 9A, a hard mask (for example, a silicon nitride layer having a thickness of about 800 nm) 72 is formed on the first surface of the protective layer 18 using, for example, a CVD method.

Next, after a resist layer 83 is formed on the first surface of the hard mask 82 using, for example, photolithography, the hard mask 82 is processed through the resist layer 83 using, for example, dry etching. As a result, as illustrated in FIG. 9B, a plurality of island-shaped hard masks 82 remains at positions corresponding to the plurality of subpixels 10B. Next, as illustrated in FIG. 9C, the resist layer 83 on the plurality of hard masks 82 is removed by, for example, ashing.

Next, for example, the protective layer 18, the protective layer 13, the second electrode 123, and the OLED layer 122B are processed through the plurality of hard masks 82 using, for example, dry etching. As a result, as illustrated in FIG. 9D, the protective layer 18, the protective layer 13, the second electrode 123, and the OLED layer 122B that are not coincident with the plurality of subpixels 10B are removed, and the plurality of light-emitting elements 12B is formed on the first surface of the drive substrate 11. In the dry etching, the side surface protective layer 14 is formed over the side surface of the OLED layer 122B and the side surface of the protective layer 13. The mechanism by which the side surface protective layer 14 is formed by residues during the etching of the protective layer 13, the second electrode 123, and the OLED layer 122B is as described in the first example.

Next, the sidewall 15B is formed in a similar manner as the first example. Next, the plurality of light-emitting elements 12R, the plurality of light-emitting elements 12G, the plurality of sidewalls 15R, and the plurality of sidewalls 15G are formed on the first surface of the drive substrate 11 through a procedure similar to the formation of the light-emitting elements 12B and the sidewalls 15B. Next, the process from the formation of the protective layer 16 to the formation of the common electrode 17 is performed in a similar manner as the first example. Through the above-described processes, the display device 102 is obtained.

### Third Example

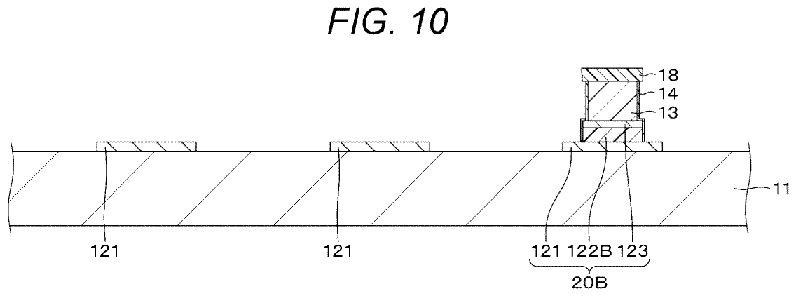

Hereinafter, a third example of the method for manufacturing the display device 102 according to the second embodiment will be described with reference to FIGS. 9A to 9C and FIG. 10.

First, the process from the formation of the first electrode 121 to the formation of the resist layer 83 is performed in a similar manner as the second example (see FIGS. 9A to 9C). Next, the protective layer 18 is processed through the hard mask 82 using, for example, dry etching, and then the protective layer 13, the second electrode, and the OLED layer 122B are processed using a laminate including the hard mask 82 and the processed protective layer 18 as a hard mask. During this process, as illustrated in FIG. 10, the hard mask 82 is removed to expose the first surface of the protective layer 18.

Next, the sidewall 15B is formed in a similar manner as the first example. Next, the plurality of light-emitting elements 12R, the plurality of light-emitting elements 12G, the plurality of sidewalls 15R, and the plurality of sidewalls 15G are formed on the first surface of the drive substrate 11 through a procedure similar to the formation of the light-emitting elements 12B and the sidewalls 15B. Next, the process from the formation of the protective layer 16 to the formation of the common electrode 17 is performed in a similar manner as the first example. Through the above-described processes, the display device 102 is obtained.

### Effects

The display device 102 according to the second embodiment can achieve similar effects as those of the display device 101 according to the first embodiment.

### 3 Third Embodiment

### [Overview]

When an OLED layer is connected between the adjacent light-emitting elements and serves as a common layer for a plurality of light-emitting elements, there is a concern about carrier leakage between the light-emitting elements through the OLED layer. Such carrier leakage between the light-emitting elements is particularly concerning in a high-definition OLD display device with miniaturized light-emitting elements. As a countermeasure against leakage between light-emitting elements, a technique to separate the OLED layer for each light-emitting element is being considered.

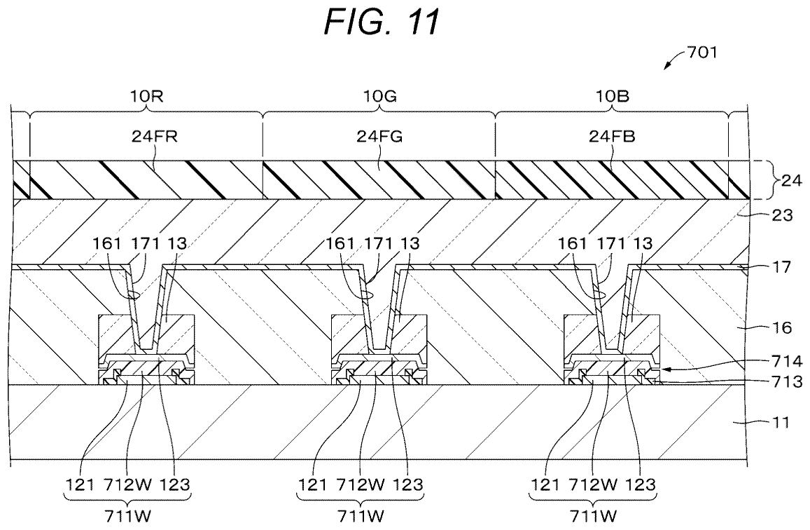

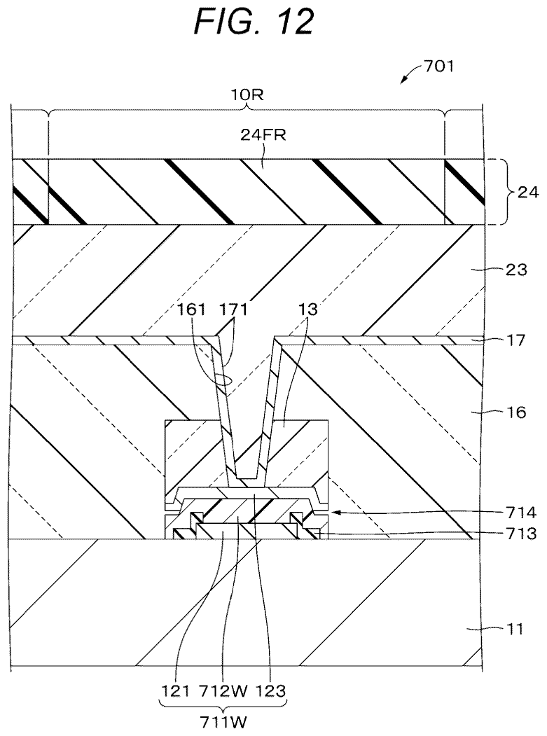

FIG. 11 is a cross-sectional view of a display device 701 of a reference example where an OLED layer 712W is separated for each light-emitting element 711W. FIG. 12 is an enlarged cross-sectional view of the light-emitting element 711W. The light-emitting element 711W includes a first electrode 121, the OLED layer 712W, and a second electrode 123 in sequence on the first surface of a drive substrate 11. The first electrode 121, the OLED layer 712W, and the second electrode 123 are each provided individually for each of the plurality of light-emitting elements 711W. That is, the first electrode 121, the OLED layer 712W, and the second electrode 123 are each divided between the light-emitting elements 711W adjacent in the in-plane direction. The peripheral edge portion of the first surface of the first electrode 121 and the side surface of the first electrode 121 are covered by an insulating layer 713. The insulating layer 713 is provided to improve the reliability of the light-emitting element 71W.

In the display device 701 configured as described above, delamination 714 may occur between the peripheral edge portion of the second electrode 123 and the peripheral edge portion of the OLED layer 712W. Such delamination 714 causes an increase in the drive voltage of the light-emitting element 71W.

The delamination 714 occurs, for example, in the manufacturing process of the display device 701 as follows. That is, after the formation of the protective layer 16, it is removed from a device for forming the protective layer 16 and conveyed to a device for the next process. There is a temperature difference ΔT (=T2−T1) between a film formation temperature T1 of the protective layer 16 during the formation of the protective layer 16 and an ambient temperature (for example, room temperature) T2 when the drive substrate 11 is removed from the film formation device after the formation the protective layer 16. Adhesion between the second electrode 123 such as an IZO layer and the OLED layer 122 is poor, so that when film stress is generated in the protective layer 16 due to the temperature difference ΔT, the delamination 714 occurs between the peripheral edge portion of the second electrode 123 and the peripheral edge portion of the OLED layer 122. Therefore, a technique to prevent the occurrence of the delamination 714 between the peripheral edge portion of the second electrode 123 and the peripheral edge portion of the OLED layer 122 is desired.

In the third embodiment, a display device capable of preventing the occurrence of such delamination between the peripheral edge portion of the second electrode 123 and the peripheral edge portion of the OLED layer 712W will be described. Note that, in both the display device 101 according to the first embodiment and the display device 102 according to the second embodiment, the occurrence of the above-described delamination can be prevented.

### [Configuration of Display Device]

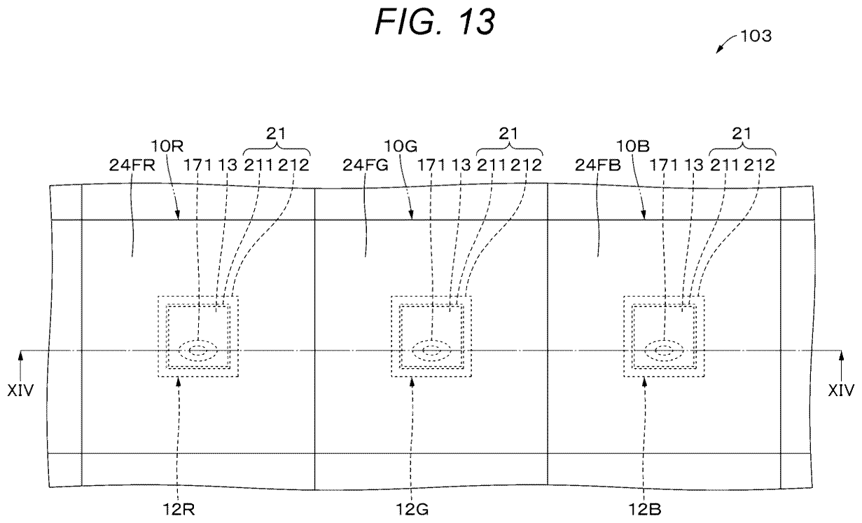

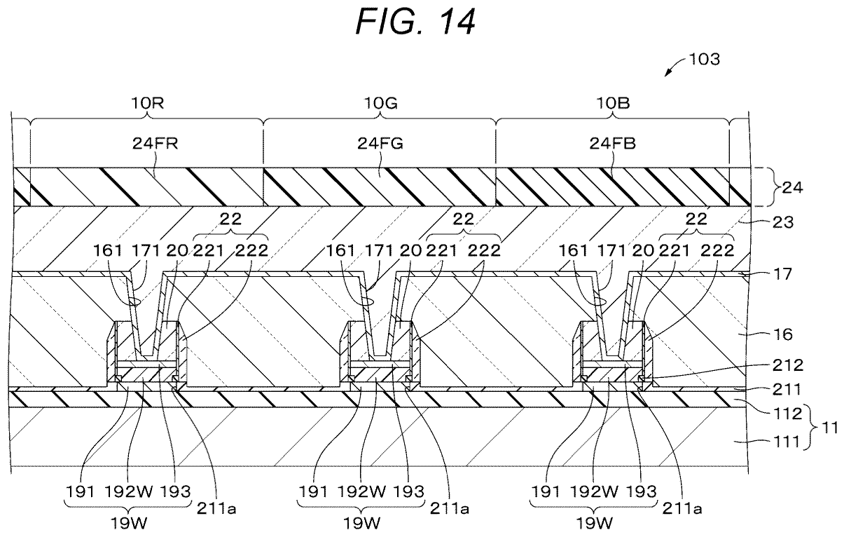

FIG. 13 is an enlarged plan view of a part of a display region RE1 of a display device 103 according to the third embodiment. FIG. 14 is a cross-sectional view taken along line XIV-XIV in FIG. 13. The display device 103 includes a drive substrate 11, a plurality of light-emitting elements 19W, a first insulating layer 211, a second insulating layer 212, a protective layer 20, a side surface protective layer 22, a protective layer 16, a common electrode 17, a protective layer 23, and a color filter 24. Note that, in the third embodiment, the same reference signs are given to parts similar to those of the first embodiment, and the description thereof will be omitted.

In the third embodiment, an example where the display device 103 includes the first insulating layer 211 and the second insulating layer 212 will be described, but the display device 103 may include only at least one of the first insulating layer 211 or the second insulating layer 212.

### (Light-Emitting Element 19W)

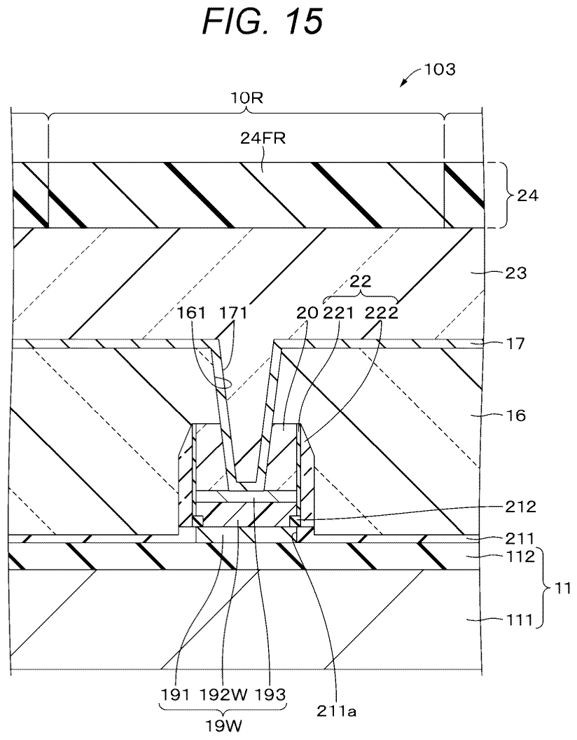

FIG. 15 is an enlarged cross-sectional view of the light-emitting element 19W. The light-emitting element 19W can emit white light. The light-emitting element 19W is a white OLED element, and can emit white light under the control of the drive circuit and the like. The light-emitting element 19W includes a first electrode 191, an OLED layer 192W, and a second electrode 193 in sequence on the first surface of the drive substrate 11. The side surface of the OLED layer 192W, the side surface of the second electrode 193, and the side surface of the protective layer 20 are approximately flush with each other.

### (OLED Layer 192W)

The OLED Layer 192W is provided individually for each of the plurality of light-emitting elements 19W in the display region RE1. That is, the OLED Layer 192W is divided between the light-emitting elements 19W adjacent in the in-plane direction in the display region RE1. The OLED layer 192W may have approximately the same size as the first electrode 121 in plan view, or may be smaller or larger in size than the first electrode 121.

The OLED layer 192W can emit white light. The OLED layer 192W may be an OLED layer including a single-layer light-emitting unit, an OLED layer including a two-layer light-emitting unit (tandem structure), or an OLED layer having a structure other than these structures. The OLED layer including a single-layer light-emitting unit has a configuration where a hole injection layer, a hole transport layer, a red organic light-emitting layer, a light-emitting separation layer, a blue organic light-emitting layer, a green organic light-emitting layer, an electron transport layer, and an electron injection layer are stacked in this order from the first electrode 121 toward the second electrode 193, for example. The OLED layer including a two-layer light-emitting unit may have a configuration where a hole injection layer, a hole transport layer, a blue organic light-emitting layer, an electron transport layer, a charge generation layer, a hole transport layer, a yellow organic light-emitting layer, an electron transport layer, and an electron injection layer are stacked in this order from the first electrode 121 toward the second electrode 193, for example.

The light-emitting separation layer is a layer for regulating injection of carriers into each light-emitting layer, and light emitting balance of each color is adjusted by injecting electrons or holes into each light-emitting layer via the light-emitting separation layer. The charge generation layer can supply electrons to one of the two light-emitting layers between which the charge generation layer is sandwiched and holes to the other light-emitting layer. When an electric field is applied to the yellow organic light-emitting layer, recombination of holes injected from the charge generation layer and electrons injected from the second electrode 193 or the charge generation layer occurs, enabling the yellow organic light-emitting layer to emit yellow light. The layers other than the light-emitting separation layer, the charge generation layer, and the yellow organic light-emitting layer are as described in the first embodiment.

### (First Electrode 191)

The first electrode 191 is similar to the first electrode 21 in the first embodiment.

### (Second Electrode 193)

The second electrode 193 is approximately the same in size as the first electrode 191 in plan view. The second electrode 193 may be similar to the second electrode 123 in the first embodiment in all respects other than the above.

### (Protective Layer 20)

The protective layer 20 is approximately the same in size as the second electrode 193 in plan view, and the side surface of the protective layer 20 and the side surface of the second electrode 193 are approximately flush with each other. The protective layer 20 may be similar to the protective layer 13 in the first embodiment in all respects other than the above.

### (First Insulating Layer 211)

The first insulating layer 211 is provided on the first surface of the drive substrate 11 between the separated first electrodes 191. The first insulating layer 211 insulates between the adjacent first electrodes 191. The first insulating layer 211 has a plurality of openings 211a. Each of the plurality of openings 211a is provided for a corresponding one of the light-emitting elements 19W. Each of the plurality of first electrodes 191 is provided in a corresponding one of the openings 211a. More specifically, each of the plurality of openings 211a is provided on the first surface (the surface adjacent to the OLED layer 192W) of a corresponding one of the first electrodes 191. In this case, the first electrode 191 and the OLED layer 192W are in contact with each other via the opening 211a.

The first insulating layer 211 preferably has high moisture resistance. The first insulating layer 211 includes, for example, metal oxide. The metal oxide includes, for example, at least one selected from the group consisting of zirconium oxide (ZrOₓ), tantalum oxide (TaOₓ), aluminum oxide (AlOₓ), and the like.

### (Second Insulating Layer 212)

The second insulating layer 212 is provided on the peripheral edge portion of the first surface of the first electrode 191. The second insulating layer 212 may be provided on both the peripheral edge portion of the first surface of the first electrode 191 and the opening peripheral edge portion of the first surface of the first insulating layer 211. Herein, the opening peripheral edge of the first surface refers to a region on the first surface extending outward from the peripheral edge of the opening 211a by a predetermined width.

The second insulating layer 212 preferably has high moisture resistance. The second insulating layer 212 includes, for example, metal oxide and metal nitride. The metal oxide includes, for example, at least one selected from the group including silicon oxide (SiOₓ), silicon oxynitride (SiOₓN_{y}), and the like. The metal nitride includes, for example, silicon nitride (SiNₓ).

### (Side Surface Protective Layer 22)

The side surface protective layer 22 is a sidewall insulating layer. The side surface protective layer 22 may cover a range from the side surface of the OLED layer 192W to the side surface of the protective layer 20. More specifically, the side surface protective layer 22 covers the side surface of the OLED layer 192W, the side surface of the second electrode 193, and the side surface of the protective layer 20. This configuration can reduce the impact of film stress of the protective layer 20 on the interface between the OLED layer 192W and the second electrode 193. The side surface protective layer 22 may cover the entire side surface of the protective layer 20, or may cover a prescribed height range on the side surface of the protective layer 20, starting from the peripheral edge of the second surface of the protective layer 20. The side surface protective layer 22 may have a closed loop shape or a segmented loop shape in plan view.

The side surface protective layer 22 can protect the side surface of the light-emitting element 19W. For example, the side surface protective layer 22 may be capable of suppressing moisture ingress into the plurality of light-emitting elements 19W from an external environment to suppress deterioration of the light-emitting elements 19W. The side surface protective layer 22 is transparent to white light emitted from the light-emitting element 19W. The side surface protective layer 22 is preferably transparent to the visible light.

The side surface protective layer 22 has a multilayer structure. The side surface protective layer 22 includes a first side surface protective layer 221 and a second side surface protective layer 222.

The first side surface protective layer 221 is provided on the side surface of the light-emitting element 19W. The first side surface protective layer 221 may include residues deposited as a result of dry etching of the second insulating layer 212. The first side surface protective layer 221 may include the same material as that of the second insulating layer 212. More specifically, the first side surface protective layer 221 may include some or all of the constituent materials of the second insulating layer 212.

The first side surface protective layer 221 is preferably lower in refractive index than the protective layer 20. Since the first side surface protective layer 221 is lower in refractive index than the protective layer 20, light emitted obliquely from the light-emitting element 19W can be reflected off the interface between the protective layer 20 and the first side surface protective layer 221. It is therefore possible to prevent color mixing between the adjacent subpixels 10. Furthermore, it is possible to increase the front luminance of the display device 103. Herein, the refractive index refers to a refractive index for light having a wavelength of 589.3 nm (sodium D line).

The second side surface protective layer 222 is provided on the first side surface protective layer 221. The second side surface protective layer 222 may include residues deposited as a result of dry etching of the first insulating layer 211. The second side surface protective layer 222 may include the same material as that of the first insulating layer 211. More specifically, the second side surface protective layer 222 may include some or all of the constituent materials of the first insulating layer 211.

### (Protective Layer 23)

The protective layer 23 is provided on the first surface of the common electrode 17. The protective layer 23 can fill irregularities on the first surface of the common electrode 17 to form a flat first surface above the common electrode 17. The protective layer 23 can protect the common electrode 17, the plurality of light-emitting elements 19W, and the like. For example, the protective layer 23 may be capable of suppressing moisture ingress into the display device 103 from an external environment to suppress deterioration of the common electrode 17, the plurality of light-emitting elements 19W, and the like. The protective layer 23 is transparent to white light emitted from the light-emitting element 19W. The protective layer 23 is preferably transparent to the visible light. As the material of the protective layer 23, an inorganic material similar to that of the protective layer 13 in the first embodiment can be exemplified.

### (Color Filter 24)

The color filter 24 is provided above the plurality of light-emitting elements 19W. More specifically, the color filter 24 is provided on the first surface of the protective layer 23. The color filter 24 includes, for example, a plurality of red filter portions 24FR, a plurality of green filter portions 24FG, and a plurality of blue filter portions 24FB. Note that, in the following description, the red filter portions 24FR, the green filter portions 24FG, and the blue filter portions 24FB may be collectively referred to as filter portion 24F unless otherwise distinguished.

The plurality of filter portions 24F is two-dimensionally arranged in the in-plane direction. Each filter portion 24F is provided above a corresponding one of the light-emitting elements 19W. The red filter portion 24FR and the light-emitting element 19W constitute the subpixel 10R, the green filter portion 24FG and the light-emitting element 19W constitute the subpixel 10G, and the blue filter portion 24FB and the light-emitting element 19W constitute the subpixel 10B.

The red filter portion 24FR transmits red light out of the white light emitted from the light-emitting element 19W but absorbs light other than the red light. The green filter portion 24FG transmits green light out of the white light emitted from the light-emitting element 19W but absorbs light other than the green light. The blue filter portion 24FB transmits blue light out of the white light emitted from the light-emitting element 19W but absorbs light other than the blue light.

The red filter portion 24FR includes, for example, a red color resist. The green filter portion 24FG includes, for example, a green color resist. The blue filter portion 24FB includes, for example, a blue color resist.

### [Method for Manufacturing Display Device]

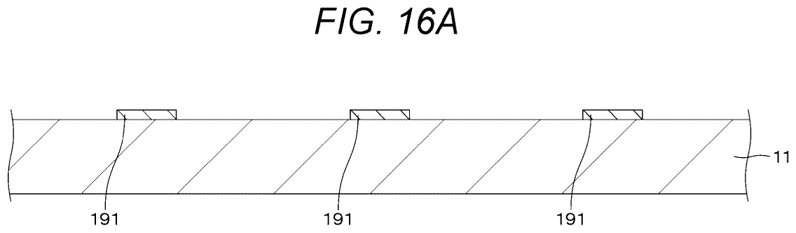

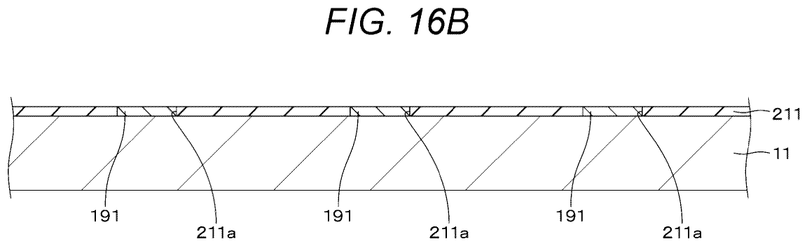

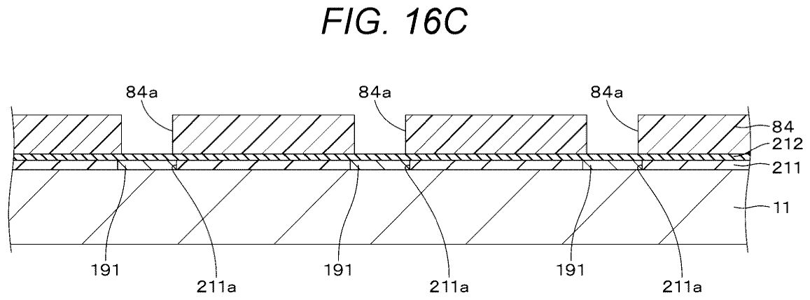

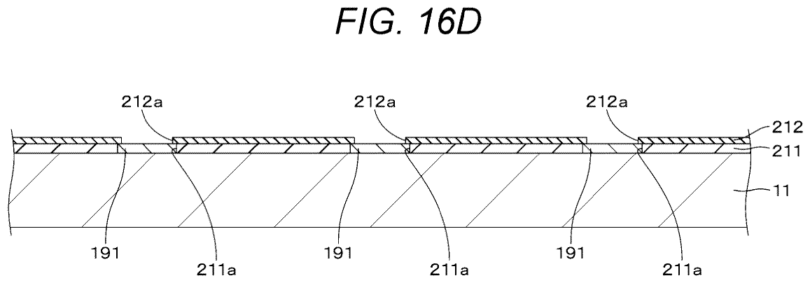

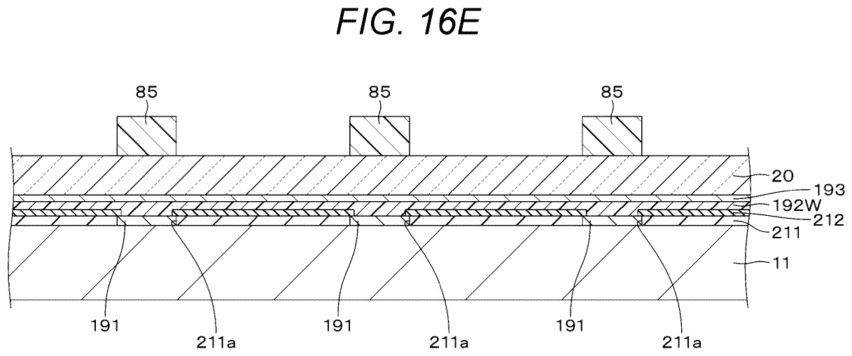

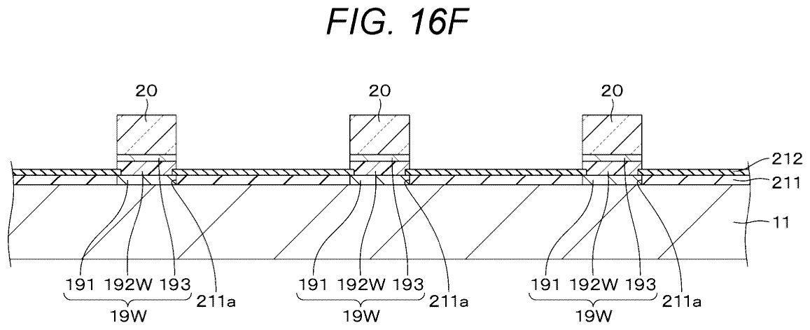

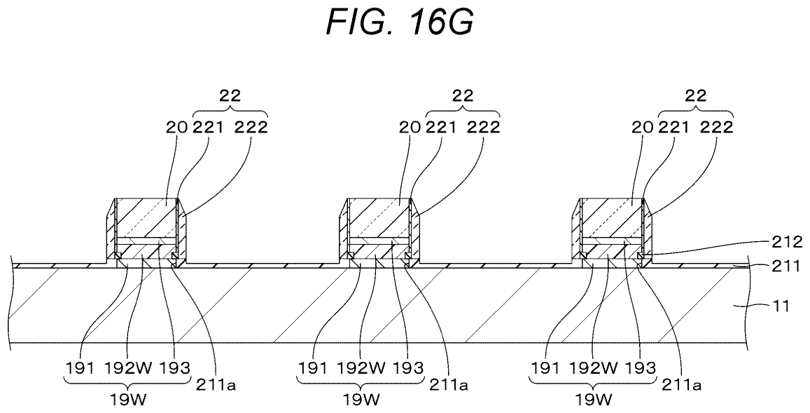

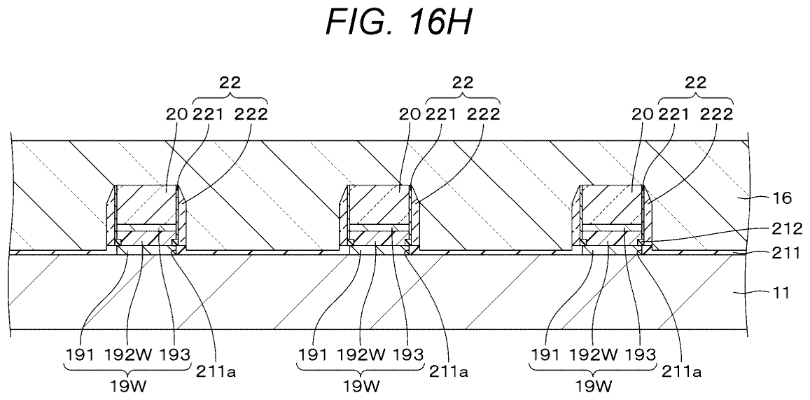

Hereinafter, an example of the method for manufacturing the display device 103 according to the third embodiment will be described with reference to FIGS. 16A to 16H.

First, a metal layer is formed on the first surface of the drive substrate 11 using, for example, a sputtering method, and then the metal layer is patterned using, for example, photolithography and dry etching. As a result, as illustrated in FIG. 16A, the plurality of first electrodes 191 is formed on the first surface of the drive substrate 11.

Next, the first insulating layer (for example, a zirconium oxide layer having a thickness of about 300 nm) 211 is formed on the first surface of the drive substrate 11 using, for example, a CVD method to cover the plurality of first electrodes 191. Next, the first insulating layer 211 is polished using, for example, CMP to expose the first surface of each first electrode 191. As a result, as illustrated in FIG. 16B, the first insulating layer 211 remains on the first surface of the drive substrate 11 between the separated first electrodes 191.

Next, the second insulating layer 212 (for example, a silicon oxynitride layer having a thickness of about 30 nm) is formed on the first surfaces of the plurality of first electrodes 191 and the first surface of the first insulating layer using, for example, a CVD method. Next, as illustrated in FIG. 16C, a resist layer 84 having a plurality of openings 74a is formed on the first surface of the second insulating layer 212 using, for example, photolithography. At this time, each of the plurality of openings 74a is formed above a corresponding one of the first electrodes 191.

Next, the second insulating layer 212 is processed through the resist layer 84 using, for example, dry etching with a CF₄ gas or the like. As a result, a plurality of openings 212a is formed in the second insulating layer 212. Next, as illustrated in FIG. 16D, the resist layer 84 on the first surface of the second insulating layer 212 is removed by, for example, ashing. Next, the OLED layer 192W is formed on the first surfaces of the plurality of first electrodes 191 and the first surface of the second insulating layer 212 using, for example, a vapor deposition method, and then the second electrode (for example, an IZO layer having a thickness of about 100 nm) 193 is formed on the first surface of the OLED layer 192W by, for example, a sputtering method. Next, the protective layer (for example, a silicon nitride layer having a thickness of about 500 nm) 20 is formed on the first surface of the second electrode 193 using, for example, a plasma CVD (PCVD) method.

Next, as illustrated in FIG. 16E, an island-shaped resist layer 85 is formed at a position corresponding to each subpixel 10B using, for example, photolithography. Next, the protective layer 20, the second electrode 193, and the OLED layer 192W are sequentially processed through the resist layer 85 using, for example, dry etching. As a result, as illustrated in FIG. 16F, the plurality of light-emitting elements 19W is formed on the first surface of the drive substrate 11.

Next, the first insulating layer 211 and the second insulating layer 212 are sequentially sputter-etched using, for example, Ar plasma. As a result, as illustrated in FIG. 16G, the second side surface protective layer 222 and the first side surface protective layer 221 are sequentially deposited on the side surface of the OLED layer 192W, the side surface of the second electrode 193, and the side surface of the protective layer 13. The sputter etching may be performed until the first surface of the drive substrate 11 is exposed, or may be terminated before the first surface of the drive substrate 11 is exposed.

It is preferable that the processing of the protective layer 20, the second electrode 193, and the OLED layer 192W and the processing of the first insulating layer 211 and the second insulating layer 212 be performed without interruption using the same etching device. With this configuration, the first side surface protective layer 221 and the second side surface protective layer 222 can be sequentially formed on the side surface of the protective layer 20, the side surface of the second electrode 193, and the side surface of the OLED layer 192W without atmospheric exposure. It is therefore possible to suppress deterioration of the OLED layer 192W and the like due to atmospheric exposure. It is thus possible to increase the reliability of the display device 103.

Next, as illustrated in FIG. 16H, the protective layer 16 is formed using, for example, a PCVD method to cover the plurality of light-emitting elements 19W each provided with the side surface protective layer 22.

Next, the protective layer 16 and the protective layer 20 are processed using, for example, photolithography and dry etching to form the contact hole 161 on each light-emitting element 19W. Next, the common electrode 17 is formed on the first surface of the protective layer 16 and in the contact hole 161 using, for example, a vapor deposition or sputtering method. Next, the protective layer 23 is formed on the first surface of the common electrode 17 using, for example, a PCVD method.

Next, a coloring composition for forming green filter portions is applied onto the first surface of the protective layer 23, and, after pattern exposure by irradiation with ultraviolet rays via a photomask, development is performed to form the plurality of green filter portions 24FG. Next, a coloring composition for forming red filter portions is applied onto the first surface of the protective layer 23, and, after pattern exposure by irradiation with ultraviolet rays via a photomask, development is performed to form the plurality of red filter portions 24FR. Next, a coloring composition for forming blue filter portions is applied onto the first surface of the protective layer 23, and, after pattern exposure by irradiation with ultraviolet rays via a photomask, development is performed to form the plurality of blue filter portions 24FB. As a result, the color filter 24 is formed on the first surface of the protective layer 23.

Through the above-described processes, the display device 103 is obtained.

### Effects

In the display device 103 according to the third embodiment, the side surface protective layer 22 covers the side surface of the OLED layer 192W and the side surfaces of the second electrode 193 and the protective layer 20 to fix these side surfaces. With this configuration, even in a case where there is a temperature difference ΔT (=T2−T1) between a film formation temperature T1 of the protective layer 16 during the formation of the protective layer 16 and an ambient temperature (for example, room temperature) T2 when the drive substrate 11 is removed from the film formation device after the formation the protective layer 16, it is possible to prevent the occurrence of delamination between the peripheral edge portion of the OLED layer 192W and the peripheral edge portion of the second electrode 193. It is therefore possible to prevent an increase in the drive voltage of the light-emitting element 19W.

### 4 Fourth Embodiment

### [Configuration of Display Device]

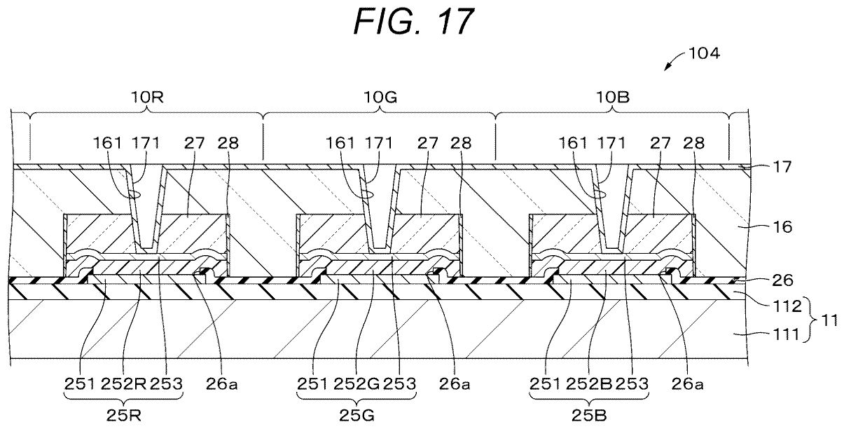

FIG. 17 is a cross-sectional view of a display device 104 according to a fourth embodiment. The display device 104 includes a drive substrate 11, a plurality of light-emitting elements 25R, a plurality of light-emitting elements 25G, a plurality of light-emitting elements 25B, an insulating layer 26, a plurality of protective layers 27, a plurality of side surface protective layers 28, a protective layer 16, and a common electrode 17. Note that, in the fourth embodiment, the same reference signs are given to parts similar to those of the first embodiment, and the description thereof will be omitted.

### (Light-Emitting Elements 25R, 25G, and 25B)

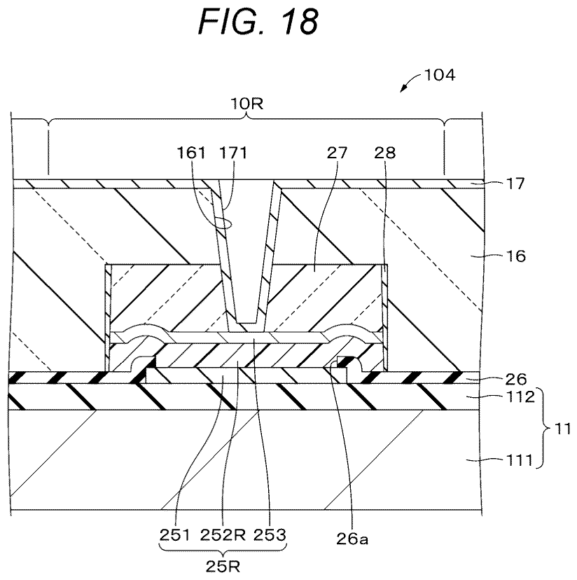

FIG. 18 is an enlarged cross-sectional view of the light-emitting element 25R. The light-emitting element 25R includes a first electrode 251, an OLED layer 252R, and a second electrode 253 in sequence on the first surface of the drive substrate 11. The light-emitting element 25G includes a first electrode 251, an OLED layer 252G, and a second electrode 253 in sequence on the first surface of the drive substrate 11. The light-emitting element 25B includes a first electrode 251, an OLED layer 252B, and a second electrode 253 in sequence on the first surface of the drive substrate 11. Note that, in the following description, the light-emitting elements 25R, 25G, and 25B may be collectively referred to as light-emitting element 25 unless otherwise distinguished. Furthermore, the OLED layers 252R, 252G, and 252B may be collectively referred to as OLED layer 252 unless otherwise distinguished.

The OLED layer 252 and the second electrode 253 are larger in size than the first electrode 251 in plan view and cover the first electrode 251. The first electrode 251, the OLED layer 252, and the second electrode 253 are similar to the first electrode 121, the OLED layer 122, and the second electrode 123 in the first embodiment in all respects other than the above.

### (Insulating Layer 26)

The insulating layer 26 is provided on the first surface of the drive substrate 11 between the separated first electrodes 251. The insulating layer 26 insulates between the adjacent first electrodes 251. The insulating layer 26 has a plurality of openings 26a. Each of the plurality of openings 26a is provided for a corresponding one of the light-emitting elements 12W. More specifically, each of the plurality of openings 26a is provided on the first surface (the surface adjacent to the OLED layer 252) of the first electrode 251. The first electrode 251 and the OLED layer 252 are in contact with each other via the opening 26a.

The insulating layer 26 may be an organic insulating layer, an inorganic insulating layer, or a laminate of the organic insulating layer and the inorganic insulating layer. The organic insulating layer includes, for example, at least one selected from the group consisting of polyimide resin, acrylic resin, novolac resin, and the like. The inorganic insulating layer includes, for example, at least one selected from the group consisting of silicon oxide (SiOₓ), silicon nitride (SiNₓ), silicon oxynitride (SiOₓN_{y}), and the like.

### (Protective Layer 27)

The protective layer 27 is approximately the same in size as the OLED layer 252 and the second electrode 253 in plan view, and the side surface of the OLED layer 252, the side surface of the second electrode 253, and the side surface of the protective layer 27 are approximately flush with each other. The protective layer 27 may be similar to the protective layer 13 in the first embodiment in all respects other than the above.

### (Side Surface Protective Layer 28)

The side surface protective layer 28 covers at least the boundary between the side surface of the OLED layer 252 and the side surface of the second electrode 253. This configuration can reduce the impact of film stress of the protective layer 27 on the interface between the OLED layer 252 and the second electrode 253. The side surface protective layer 28 may cover a range from the side surface of the OLED layer 252 to the side surface of the protective layer 27. More specifically, the side surface protective layer 28 covers the side surface of the OLED layer 252, the side surface of the second electrode 253, and the side surface of the protective layer 27. The side surface protective layer 28 may cover the entire side surface of the protective layer 27, or may cover a prescribed height range on the side surface of the protective layer 27, starting from the peripheral edge of the second surface of the protective layer 27. The side surface protective layer 28 may have a closed loop shape or a segmented loop shape in plan view.

The side surface protective layer 28 preferably includes a monolayer. When the side surface protective layer 28 includes a monolayer, the barrier property of the side surface protective layer 28 can be enhanced. Due to its high adhesion, the monolayer effectively reduces the impact of film stress of the protective layer 27 on the interface between the OLED layer 252 and the second electrode 253. Therefore, the monolayer effectively prevents delamination between the OLED layer 252 and the second electrode 253. Thus, the monolayer effectively prevents an increase in the drive voltage of the light-emitting element 25. The side surface protective layer 28 may include a monolayer deposit. The side surface protective layer 28 may be an atomic layer deposition (ALD) layer.

The side surface protective layer 28 includes, for example, metal oxide. The metal oxide includes, for example, aluminum oxide (AlOₓ) or titanium oxide (TiOₓ).

### [Method for Manufacturing Display Device]

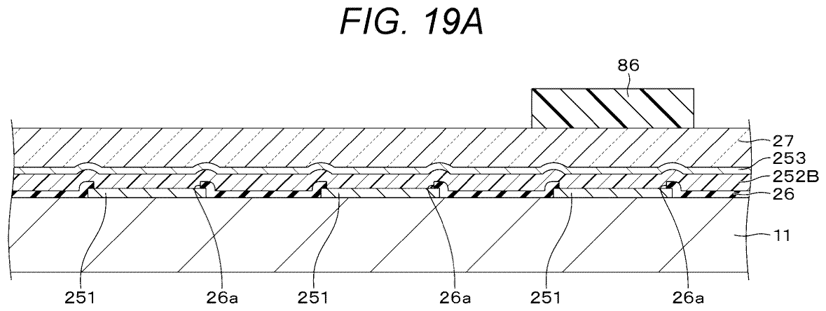

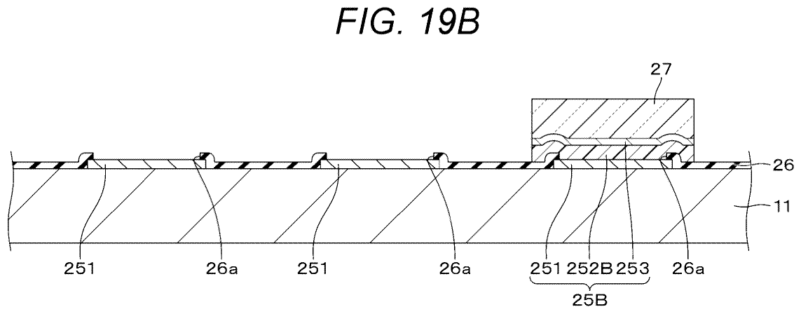

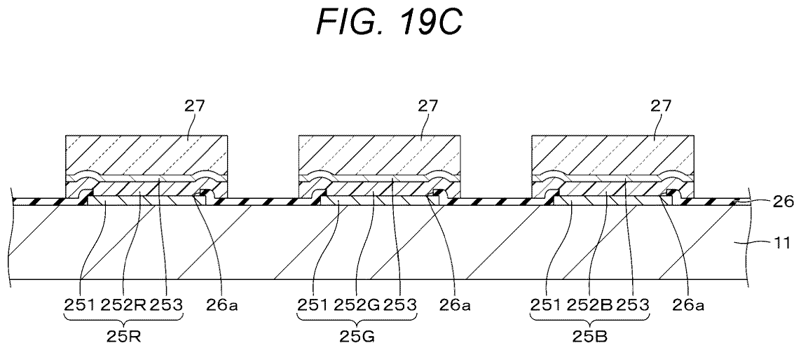

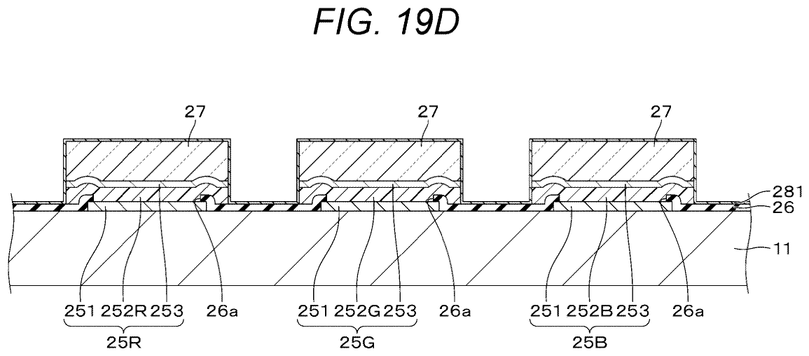

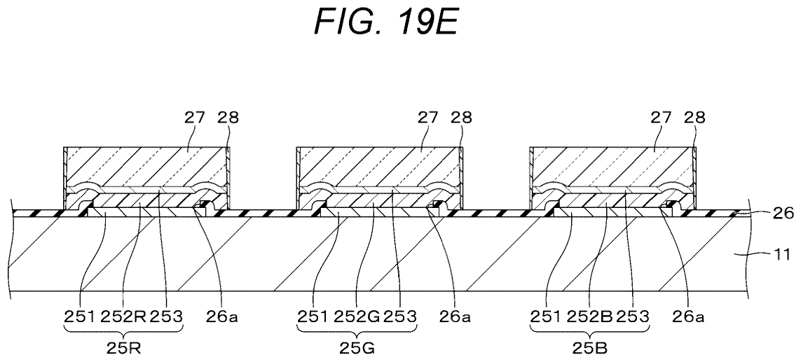

Hereinafter, an example of the method for manufacturing the display device 103 according to the third embodiment will be described with reference to FIGS. 19A to 19E.

First, a metal layer is formed on the first surface of the drive substrate 11 using, for example, a sputtering method, and then the metal layer is patterned using, for example, photolithography and dry etching. As a result, the plurality of first electrodes 251 is formed on the first surface of the drive substrate 11.

Next, the insulating layer 26 is formed on the first surface of the drive substrate 11 using, for example, a CVD method to cover the plurality of first electrodes 251. Next, the plurality of openings 26a is formed in the insulating layer 26 using, for example, photolithography and dry etching. As a result, the first surface of each first electrode 251 is exposed through the opening 26a.

Next, a hole injection layer, a hole transport layer, a blue organic light-emitting layer, an electron transport layer, and an electron injection layer are sequentially stacked on the first surfaces of the plurality of first electrodes 251 and the first surface of the insulating layer 26 using, for example, a vapor deposition method to form the OLED layer 252B. Next, the second electrode 253 is formed on the first surface of the OLED layer 252B using, for example, a vapor deposition or sputtering method. Next, the protective layer 27 is formed on the first surface of the second electrode 253 using, for example, a CVD method.

Next, as illustrated in FIG. 19A, an island-shaped resist layer 86 is formed at a position corresponding to each subpixel 10B using, for example, photolithography. Next, the protective layer 27, the second electrode 253, and the OLED layer 252B are sequentially processed through the resist layer 86 using, for example, dry etching. As a result, as illustrated in FIG. 19B, the plurality of light-emitting elements 25B is formed on the first surface of the drive substrate 11.

Next, as illustrated in FIG. 19C, the plurality of light-emitting elements 25R and the plurality of light-emitting elements 25G are formed on the first surface of the drive substrate 11 through a procedure similar to the formation of the light-emitting elements 25B.

Next, as illustrated in FIG. 19D, a protective layer 281 is formed on the first surface of the drive substrate 11 to cover the plurality of light-emitting elements 25R, the plurality of light-emitting elements 25G, and the plurality of light-emitting elements 25B using, for example, ALD. Next, as illustrated in FIG. 19E, the protective layer 281 on the first surface of the protective layer 27 and the first surface of the drive substrate 11 is removed using, for example, etch back (dry etching), but the protective layer 281 on the side surface of the OLED layer 252, the side surface of the second electrode 253, and the side surface of the protective layer 27 is left. As a result, the side surface protective layer 28 is formed on each of the side surfaces of the plurality of light-emitting elements 25R, the plurality of light-emitting elements 25G, and the plurality of light-emitting elements 25B.

Next, the process from the formation of the protective layer 16 to the formation of the common electrode 17 is performed in a similar manner as the method for manufacturing the display device 101 according to the first embodiment. Through the above-described processes, the display device 104 is obtained.

### Effects

In the display device 104 according to the fourth embodiment, the side surface protective layer 28 covers at least the boundary between the side surface of the OLED layer 252 and the side surface of the second electrode 253. Therefore, effects similar to those of the display device 101 according to the first embodiment can be achieved.

### 5 Fifth Embodiment

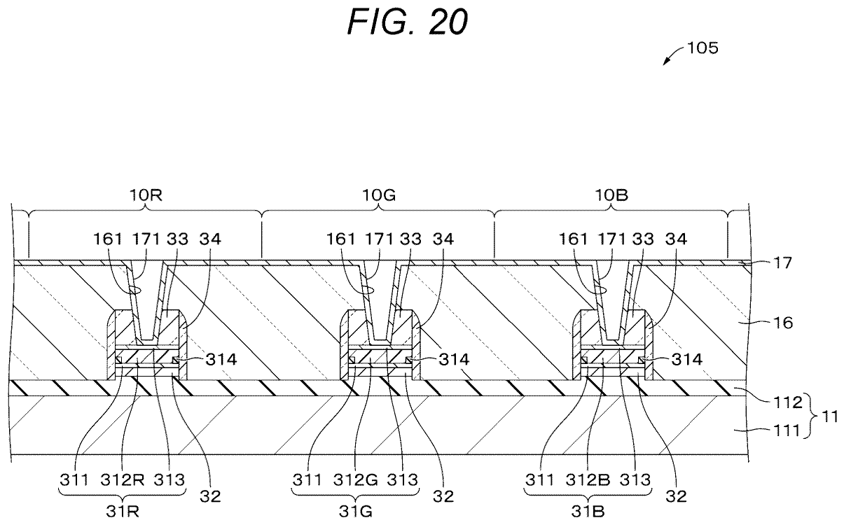

FIG. 20 is a cross-sectional view of a display device 105 according to a fifth embodiment. The display device 105 includes a drive substrate 11, a plurality of light-emitting elements 31R, a plurality of light-emitting elements 31G, a plurality of light-emitting elements 31B, a plurality of metal layers 32, a plurality of protective layers 33, a plurality of side surface protective layers 34, a protective layer 16, and a common electrode 17. Note that, in the fifth embodiment, the same reference signs are given to parts similar to those of the first embodiment, and the description thereof will be omitted.

### (Light-Emitting Elements 31R, 31G, and 31B)

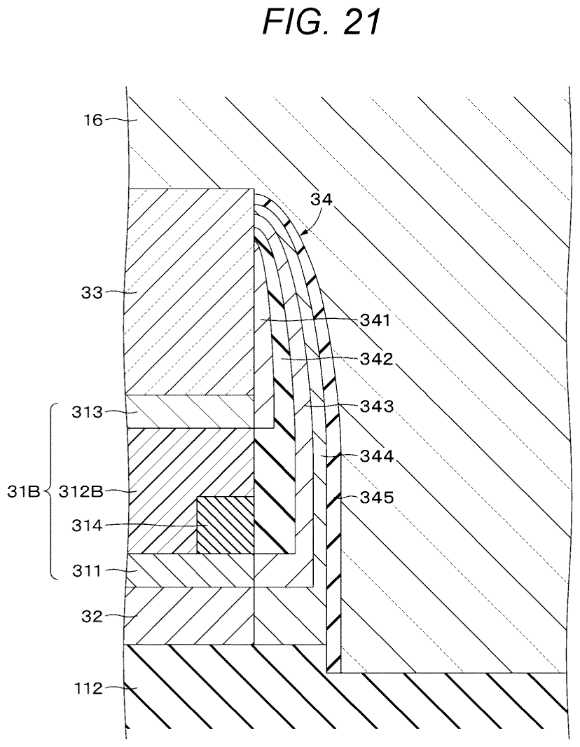

FIG. 21 is an enlarged cross-sectional view of a part of the light-emitting element 31B. The light-emitting element 31R includes a first electrode 311, an OLED layer 312R, a second electrode 313, and an insulating layer 314. The light-emitting element 31G includes a first electrode 311, an OLED layer 312G, a second electrode 313, and an insulating layer 314. The light-emitting element 31B includes a first electrode 311, an OLED layer 312B, a second electrode 313, and an insulating layer 314. In the following description, the light-emitting elements 31R, 31G, and 31B may be collectively referred to as light-emitting element 31 unless otherwise distinguished. Furthermore, the OLED layers 312R, 312G, and 312B may be collectively referred to as OLED layer 312 unless otherwise distinguished.

The first electrode 311, the OLED layer 312, and the second electrode 313 may be approximately the same in size in plan view, and the side surfaces of the first electrode 311, the OLED layer 312, and the second electrode 313 may be approximately flush with each other. The first electrode 311, the OLED layer 312, and the second electrode 313 are similar to the first electrode 121, the OLED layer 122, and the second electrode 123 in the first embodiment in all respects other than the above.

The insulating layer 314 is provided on the peripheral edge portion of the first surface of the first electrode 311. The first surface and inner side surface of the insulating layer 314 are covered by the OLED layer 312. The insulating layer 314 preferably has a closed loop shape in plan view.

The insulating layer 314 includes, for example, metal oxide and metal nitride. The metal oxide includes, for example, at least one selected from the group including silicon oxide (SiOₓ), silicon oxynitride (SiOₓN_{y}), and the like. The metal nitride includes, for example, silicon nitride (SiNₓ).

### (Metal Layer 32)

The metal layer 32 is provided between the first surface of the insulating layer 112 and the second surface of the light-emitting element 31. The metal layer 32 is approximately the same in size as the first electrode 311 in plan view, and the side surface of the metal layer 32 and the side surface of the first electrode 311 may be approximately flush with each other.

The metal layer may function as a reflective layer that reflects light emitted from the OLED layer 312. The metal layer includes, for example, at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

### (Side Surface Protective Layer 34)

The side surface protective layer 34 covers the side surface of the metal layer 32, the side surface of the light-emitting element 31, and the side surface of the protective layer 33. More specifically, the side surface protective layer 34 covers the side surface of the metal layer 32, the side surface of the first electrode 311, the side surface of the OLED layer 312, the side surface of the second electrode 313, and the side surface of the protective layer 33.

In the fifth embodiment, an example where the side surface protective layer 34 covers the side surface of the metal layer 32, the side surface of the first electrode 311, the side surface of the OLED layer 312, the side surface of the second electrode 313, and the side surface of the protective layer 33 will be described, but the side surface protective layer 34 may cover the first electrode 311, the side surface of the OLED layer 312, the side surface of the second electrode 313, and the side surface of the protective layer 33, or may cover the side surface of the OLED layer 312, the side surface of the second electrode 313, and the side surface of the protective layer 33.

The side surface protective layer 34 can protect the side surface of the light-emitting element 31. For example, the side surface protective layer 34 can reduce the impact of film stress of the protective layer 33 on the interface between the OLED layer 312 and the second electrode 313. The side surface protective layer 34 may be capable of suppressing moisture ingress into the light-emitting element 31 from an external environment to suppress deterioration of the light-emitting element 31. The side surface protective layer 34 can reflect light emitted from the light-emitting element 31. The side surface protective layer 34 preferably includes at least one reflective layer that can reflect light emitted from the light-emitting element 31.

The side surface protective layer 34 may include residues deposited as a result of sequential dry etching of the protective layer 33, the second electrode 313, the OLED layer 312, the insulating layer 314, the first electrode 311, and the metal layer 32. The side surface protective layer 34 may include some or all of the constituent materials of the protective layer 33, some or all of the constituent materials of the second electrode 313, some or all of the constituent materials of the insulating layer 314, some or all of the constituent materials of the first electrode 311, and some or all of the constituent materials of the metal layer 32.

The side surface protective layer 34 may include a first side surface protective layer 341, a second side surface protective layer 342, a third side surface protective layer 343, a fourth side surface protective layer 344, and a fifth side surface protective layer 345 in sequence.

### (First Side Surface Protective Layer 341)

The first side surface protective layer 341 may cover the side surface of the second electrode 313 and the side surface of the protective layer 33. The first side surface protective layer 341 may have its bottom portion connected to the side surface of the second electrode 313. The first side surface protective layer 341 may have conductivity. The first side surface protective layer 341 may be a reflective layer capable of reflecting light emitted from the light-emitting element 31 or a light-transmitting layer capable of transmitting light emitted from the light-emitting element 31. The first side surface protective layer 341 may include residues deposited as a result of processing, such as dry etching, of the second electrode 313. The first side surface protective layer 341 may include some or all of the constituent materials of the second electrode 313.

### (Second Side Surface Protective Layer 342)

The second side surface protective layer 342 may cover the side surface of the insulating layer 314, the side surface of the OLED layer 312, and the main surface of the first side surface protective layer 341. The second side surface protective layer 342 may have its bottom portion connected to the side surface of the insulating layer 314. The second side surface protective layer 342 may have insulating properties. The second side surface protective layer 342 may be capable of insulating between the first side surface protective layer 341 and the third side surface protective layer 343. The second side surface protective layer 342 may be capable of transmitting light emitted from the light-emitting element 31. The second side surface protective layer 342 may include residues deposited as a result of processing, such as dry etching, of the insulating layer 314. The second side surface protective layer 342 may include some or all of the constituent materials of the insulating layer 314. The second side surface protective layer 342 may further include some of the constituent materials of the OLED layer 312.

### (Third Side Surface Protective Layer 343)

The third side surface protective layer 343 may cover the side surface of the first electrode 311 and the main surface of the second side surface protective layer 342. The third side surface protective layer 343 may have its bottom portion connected to the side surface of the first electrode 311. The third side surface protective layer 343 may have conductivity. From the viewpoint of improving the light extraction efficiency of the display device 105, the third side surface protective layer 343 is preferably a reflective layer capable of reflecting light emitted obliquely from the light-emitting element 31. The third side surface protective layer 343 may include residues deposited as a result of processing, such as dry etching, of the first electrode 311. The third side surface protective layer 343 may include some or all of the constituent materials of the first electrode 311.

### (Fourth Side Surface Protective Layer 344)

The fourth side surface protective layer 344 may cover the side surface of the metal layer 32 and the main surface of the third side surface protective layer 343. The fourth side surface protective layer 344 may have its bottom portion connected to the side surface of the metal layer 32. The fourth side surface protective layer 344 may have conductivity. From the viewpoint of improving the light extraction efficiency of the display device 105, the fourth side surface protective layer 344 is preferably a reflective layer capable of reflecting light emitted obliquely from the light-emitting element 31. From the viewpoint of improving the light extraction efficiency of the display device 105, both the third side surface protective layer 343 and the fourth side surface protective layer 344 are preferably reflective layers capable of reflecting light emitted obliquely from the light-emitting element 31. The fourth side surface protective layer 344 may include residues deposited as a result of processing, such as dry etching, of the metal layer 32. The fourth side surface protective layer 344 may include some or all of the constituent materials of the metal layer 32.

### (Fifth Side Surface Protective Layer 345)

The fifth side surface protective layer 345 may cover the main surface of the fourth side surface protective layer 344. The fifth side surface protective layer 345 may have insulating properties. The fifth side surface protective layer 345 may include residues deposited as a result of processing, such as dry etching, of the insulating layer 112. The fifth side surface protective layer 345 may include some or all of the constituent materials of the insulating layer 112.

### (Protective Layer 33)

The protective layer 33 is approximately the same in size as the second electrode 313 in plan view, and the side surface of the protective layer 33 and the side surface of the second electrode 313 are approximately flush with each other. The protective layer 33 may be similar to the protective layer 13 in the first embodiment in all respects other than the above.

### [Method for Manufacturing Display Device]

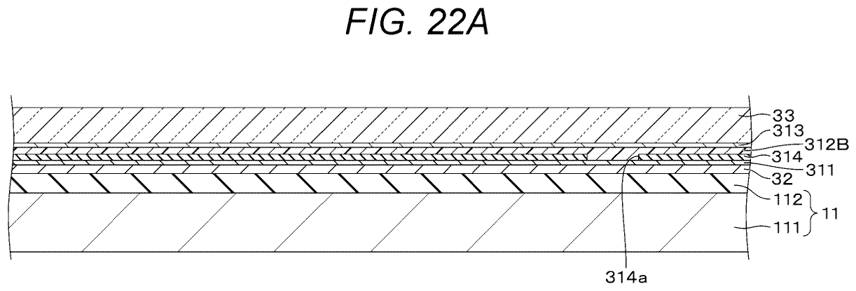

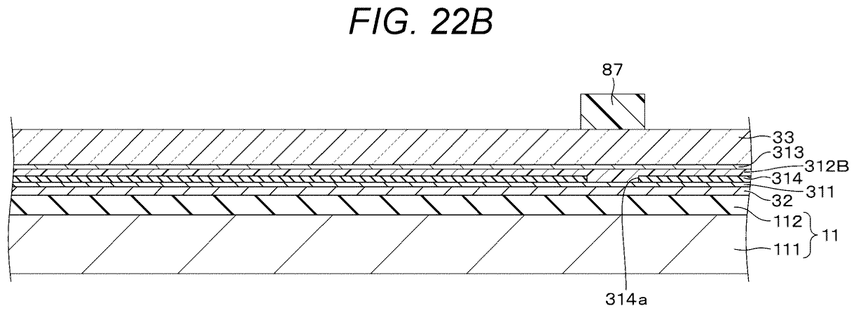

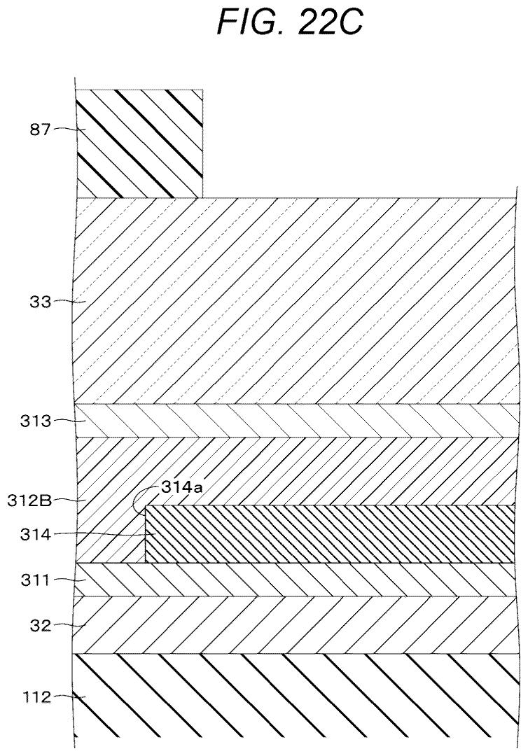

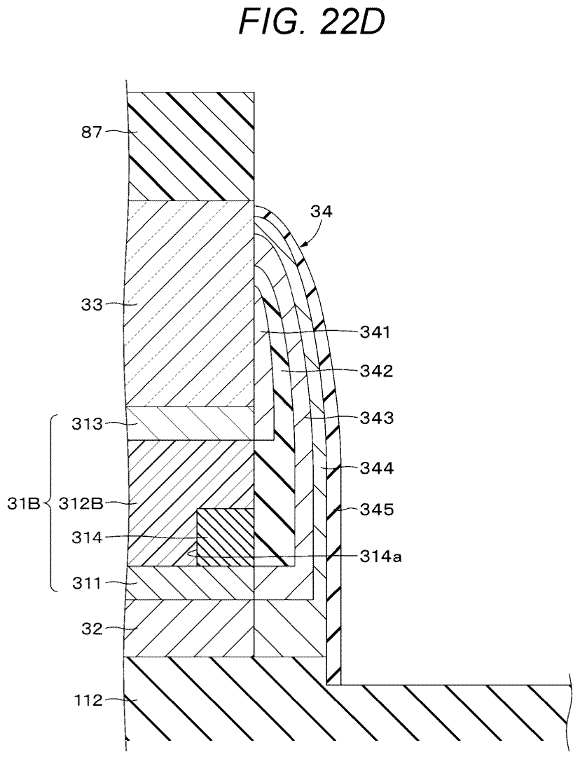

Hereinafter, an example of the method for manufacturing the display device 105 according to the fifth embodiment will be described with reference to FIGS. 22A to 22D.

First, as illustrated in FIG. 22A, the metal layer 32, the first electrode 311, the insulating layer 314, the OLED layer 312B, the second electrode 313, and the protective layer 33 are sequentially stacked on the first surface of the drive substrate 11 using, for example, a sputtering method, a vapor deposition method, a CVD method, and the like. However, when the insulating layer 314 is patterned using, for example, photolithography and dry etching between the formation of the insulating layer 314 and the formation of the OLED layer 312B, a plurality of openings 314a is formed at positions corresponding to the plurality of subpixels 10B. In the method for manufacturing the display device 105 according to the fifth embodiment, the insulating layer 112, the metal layer 32, the first electrode 311, the insulating layer 314, and the second electrode 313 function as a deposition layer for generating residues on the side surface of the light-emitting element 31.

Next, as illustrated in FIGS. 22B and 22C, an island-shaped resist layer 87 is formed at a position corresponding to each subpixel 10B using, for example, photolithography. Next, the protective layer 33, the second electrode 313, the OLED layer 312B, the insulating layer 314, the first electrode 311, the metal layer 32, and the insulating layer 112 are sequentially processed through the resist layer 85 using, for example, dry etching to deposit residues on the side surface of the protective layer 33, the side surface of the light-emitting element 31B, and the side surface of the metal layer 32. As a result, as illustrated in FIG. 22D, the plurality of light-emitting elements 31B is formed on the first surface of the drive substrate 11 with the metal layer 32 interposed therebetween. Furthermore, the first side surface protective layer 341, the second side surface protective layer 342, the third side surface protective layer 343, the fourth side surface protective layer 344, and the fifth side surface protective layer 345 are sequentially formed on the side surface of the metal layer 32, the side surface of the light-emitting element 31B, and the side surface of the protective layer 33.

Next, the plurality of light-emitting elements 31R and the plurality of light-emitting elements 31G are formed on the first surface of the drive substrate 11 with the metal layer 32 interposed therebetween, through a procedure similar to the formation of the light-emitting elements 31B.

Next, the process from the formation of the protective layer 16 to the formation of the common electrode 17 is performed in a similar manner as the method for manufacturing the display device 101 according to the first embodiment. Through the above-described processes, the display device 105 is obtained.

### Effects

In the display device 105 according to the fifth embodiment, the side surface protective layer 34 covers the side surface of the light-emitting element 31 and the side surface of the protective layer 33, and is capable of reflecting light emitted obliquely from the light-emitting element 31. It is therefore possible to prevent delamination between the OLED layer 312 and the second electrode 123 and improve the light extraction efficiency of the display device 105.

Since the second side surface protective layer 342 having insulating properties is provided between the first side surface protective layer 341 and the third side surface protective layer 343, carrier leakage between the first electrode 311 and the second electrode 313 due to contact between the first side surface protective layer 341 and the third side surface protective layer 343 can be suppressed.

### Modifications

### Modification 1

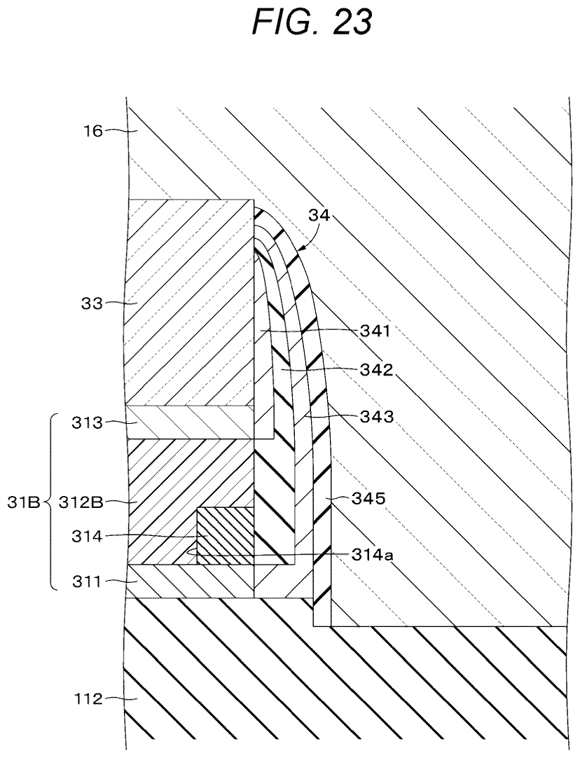

In the fifth embodiment, the example where the display device 105 includes the metal layer 32 between the insulating layer 112 and the light-emitting element 31, and includes the fourth side surface protective layer 344 between the third side surface protective layer 343 and the fifth side surface protective layer 345 has been described (see FIG. 21). However, the configuration of the display device 105 is not limited to such an example, and the display device 105 need not include the metal layer 32 and the fourth side surface protective layer 344 as illustrated in FIG. 23.

The display device 105 configured as described above is manufactured in a similar manner as the method for manufacturing the display device 105 according to the fifth embodiment except that the first electrode 311, the insulating layer 314, the OLED layer 312, the second electrode 313, and the protective layer 33 are sequentially stacked on the first surface of the drive substrate 11 as illustrated in FIG. 24.

### Modification 2

In the fifth embodiment, the example where the display device 105 includes the metal layer 32 between the insulating layer 112 and the light-emitting element 31 has been described (see FIG. 21). However, the configuration of the display device 105 is not limited to such an example, and the display device 105 need not include the metal layer 32 as illustrated in FIG. 25.

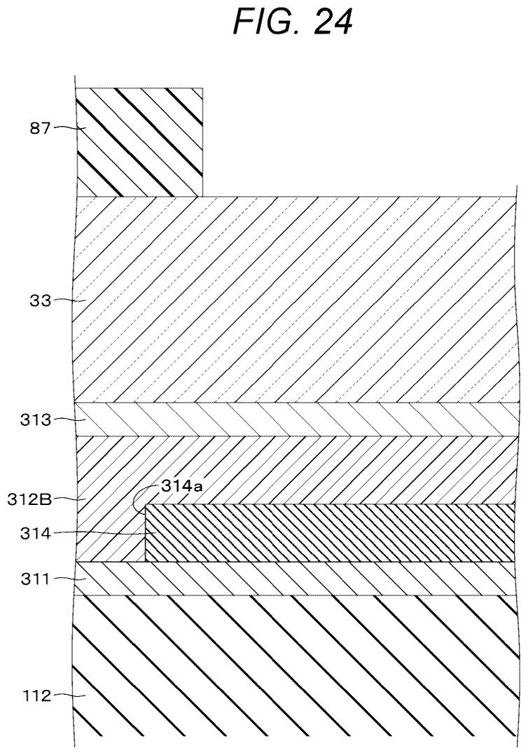

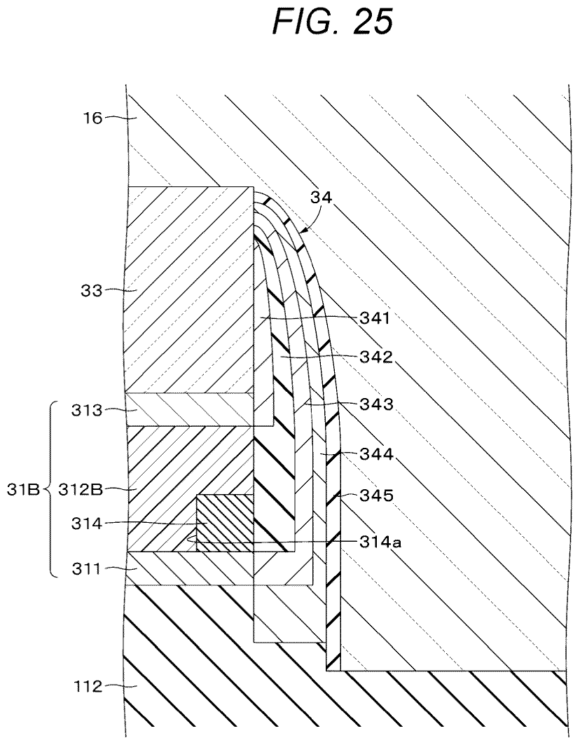

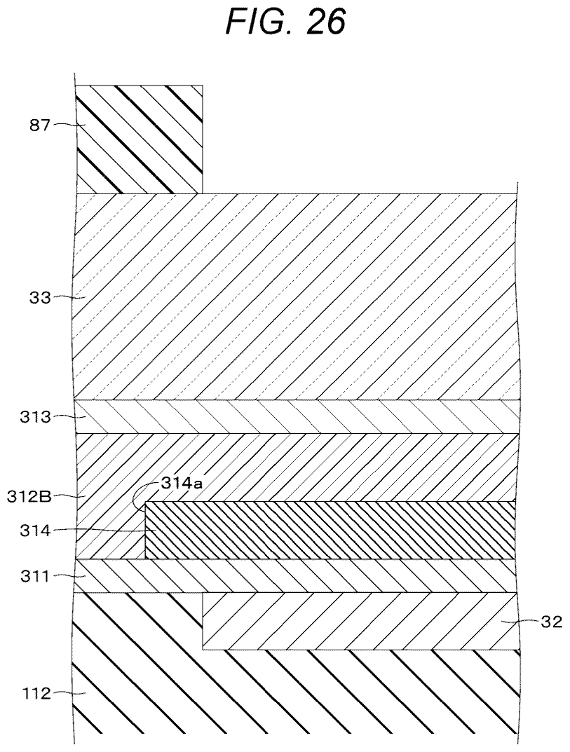

The display device 105 configured as described above is manufactured in a similar manner as the method for manufacturing the display device 105 according to the fifth embodiment except that a plurality of openings 32a is formed in the metal layer 32 using, for example, photolithography and dry etching between the formation of the metal layer 32 and the formation of the first electrode 311 as illustrated in FIG. 26. Each opening 32a is formed at a position of the corresponding light-emitting element 31 in the metal layer 32.

### Modification 3

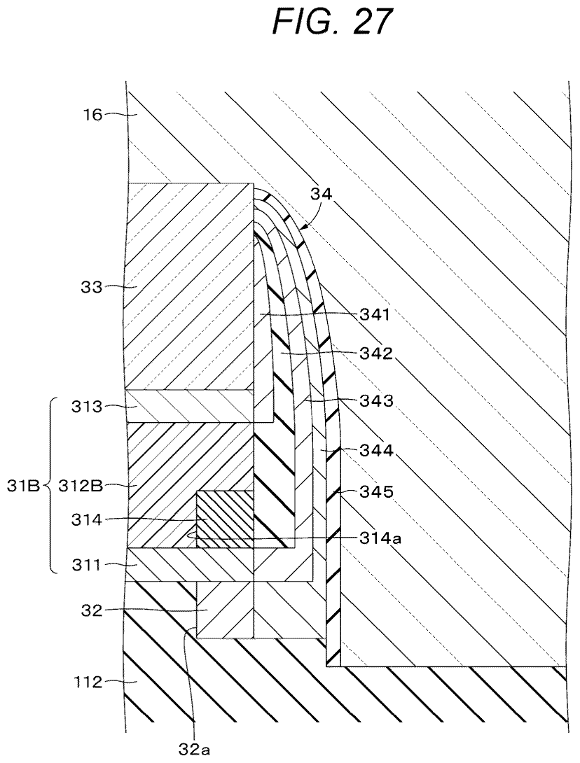

In the fifth embodiment, the example where the metal layer 32 is provided under the entire light-emitting element 31 has been described (see FIG. 21), but as illustrated in FIG. 27, the metal layer 32 may have an opening 32a under the light-emitting element 31.

The display device 105 including the metal layer 32 is manufactured in a similar manner as the method for manufacturing the display device 105 according to Modification 3 except that the peripheral edge of the opening 32a of the metal layer 32 is located inside the peripheral edge of the region where the light-emitting element 31 is formed as illustrated in FIG. 28.

### Modification 4

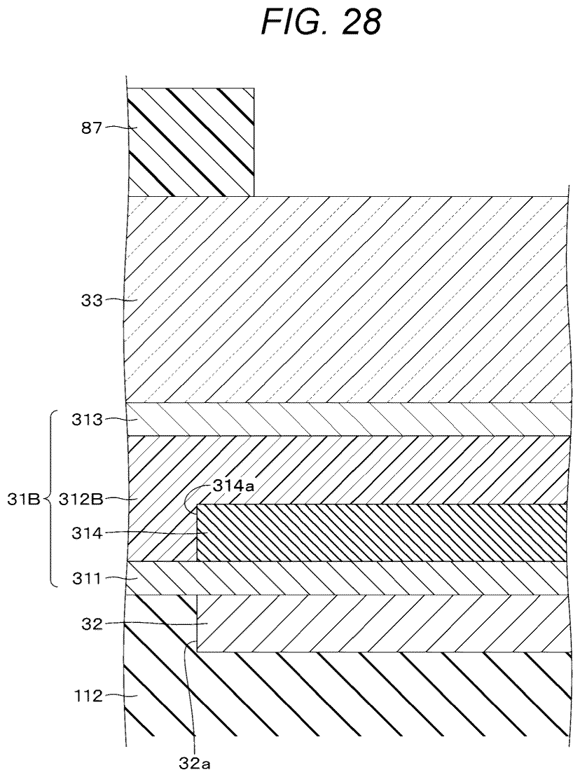

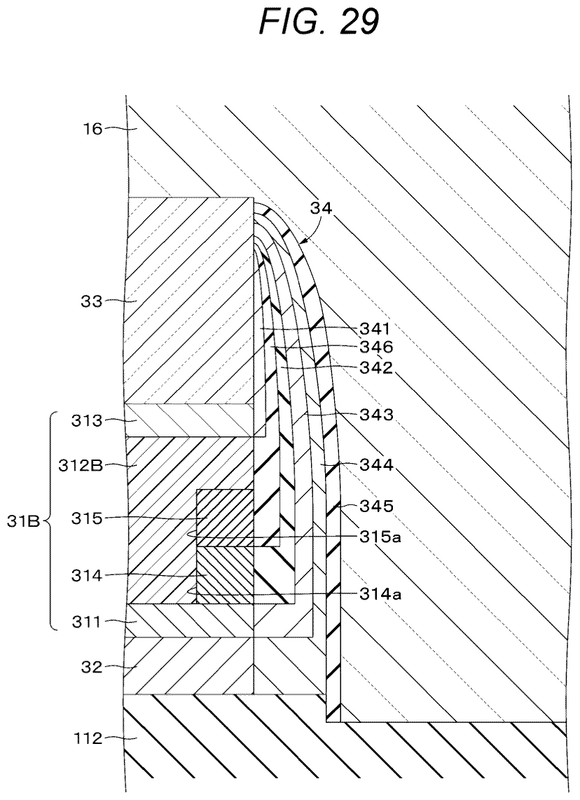

In the fifth embodiment, the example where the light-emitting element 31 includes one insulating layer 314 has been described (see FIG. 21), but the configuration of the light-emitting element 31 is not limited to such an example. For example, as illustrated in FIG. 29, the light-emitting element 31 may include two insulating layers 314 and 315. In this case, the side surface protective layer 34 may further include a sixth side surface protective layer 346.

The insulating layer 315 is provided on the insulating layer 314, and the insulating layer 314 and the insulating layer 315 constitute a laminate. The laminate may be provided on the peripheral edge portion of the first surface of the first electrode 311. The first surface and inner side surface of the laminate may be covered by the OLED layer 312. The laminate preferably has a closed loop shape in plan view.

As the material of the insulating layer 315, a material similar to that of the insulating layer 314 can be exemplified. The materials of the insulating layer 314 and the insulating layer 315 may be different or the same. Here, the difference in the materials of the insulating layer 314 and the insulating layer 315 may refer to either the components of the materials constituting the insulating layer 314 and the insulating layer 315 being different, or the components of the materials constituting the insulating layer 314 and the insulating layer 315 being the same but with varying content ratios.

The sixth side surface protective layer 346 is provided between the first side surface protective layer 341 and the second side surface protective layer 342. The sixth side surface protective layer 346 may have its bottom portion connected to the side surface of the insulating layer 315. The sixth side surface protective layer 346 may have insulating properties. The sixth side surface protective layer 346 may be capable of transmitting light emitted from the light-emitting element 31. The sixth side surface protective layer 346 may include residues deposited as a result of processing, such as dry etching, of the insulating layer 315. The sixth side surface protective layer 346 may include some or all of the constituent materials of the insulating layer 315. The sixth side surface protective layer 346 may further include some of the constituent materials of the OLED layer 312.

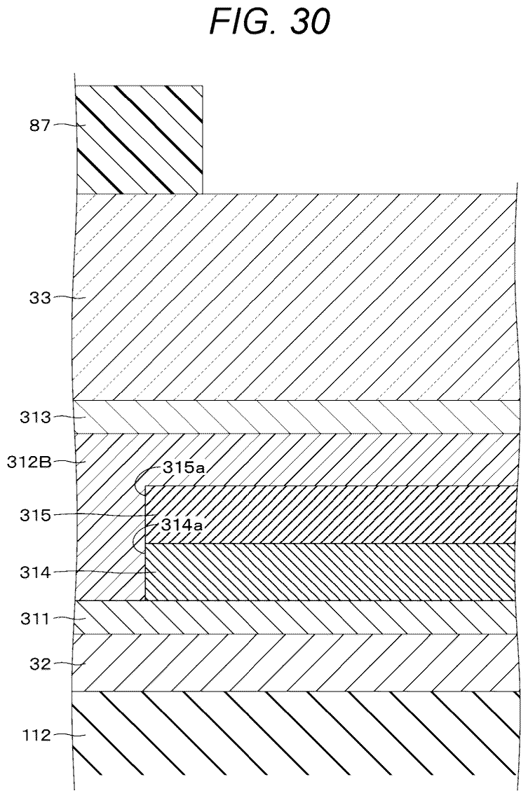

The display device 105 configured as described above is manufactured in a similar manner as the method for manufacturing the display device 105 according to the fifth embodiment except that the metal layer 32, the first electrode 311, the insulating layer 314, the insulating layer 315, the OLED layer 312, the second electrode 313, and the protective layer 33 are sequentially stacked on the first surface of the drive substrate 11 using, for example, a sputtering method, a vapor deposition method, a CVD method, and the like as illustrated in FIG. 30. However, when the insulating layer 314 and the insulating layer 315 are patterned using, for example, photolithography and dry etching between the formation of the insulating layer 315 and the formation of the OLED layer 312, a plurality of openings 314a and 315a is formed at positions corresponding to the plurality of subpixels 10.

In Modification 4, the example where the light-emitting element 31 includes a laminate of the two insulating layers 314 and 315 has been described, but the light-emitting element 31 may include a laminate of three or more insulating layers.

### Modification 5

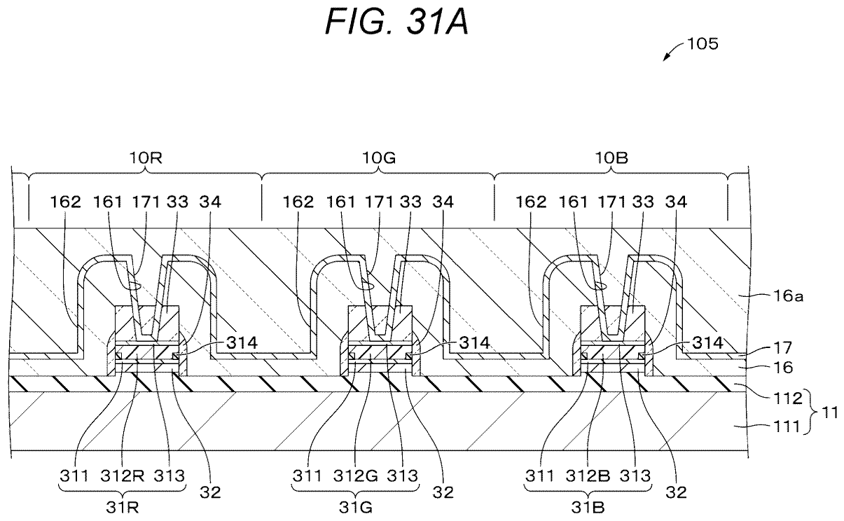

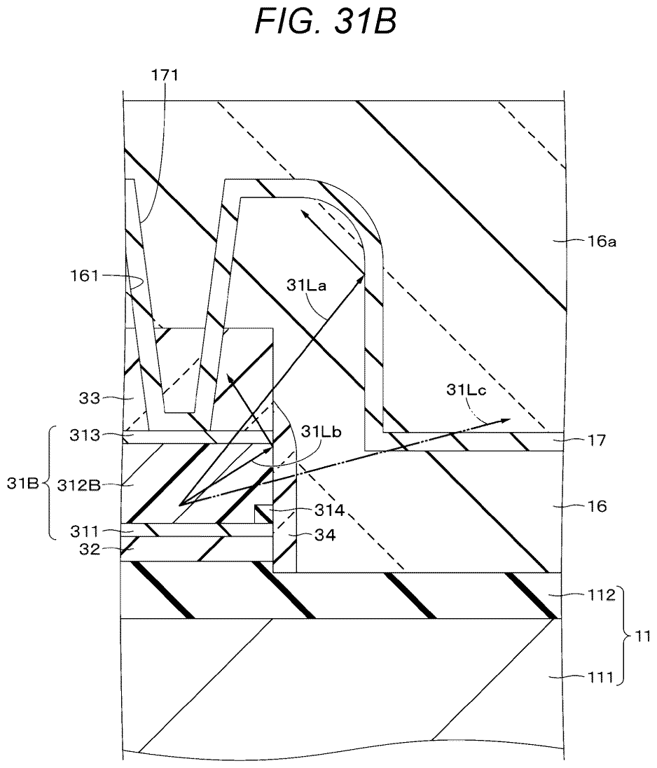

In the fifth embodiment, the example where the protective layer 16 has a flat surface between the adjacent light-emitting elements 31 has been described (see FIG. 21), but the configuration of the protective layer 16 is not limited to such an example. For example, as illustrated in FIG. 31A, the protective layer 16 may have a recess 162 between the adjacent light-emitting elements 31. In this case, the common electrode 17 may be provided along the recess 162. A protective layer 16a may be provided on the first surface of the common electrode 17 to fill the recess 162.

In the display device 105 configured as described above, as illustrated in FIG. 31B, light 31La emitted from the light-emitting element 31 in a wide angle (oblique direction) can be reflected off the interface between the protective layer 16 and the common electrode 17. Furthermore, light 31Lb emitted from the light-emitting element 31 in a wider angle can be reflected off the side surface protective layer 34. It is therefore possible to improve the light extraction efficiency of the display device 105.

### Modification 6

In Modification 5, the example where the common electrode 17 is provided between the protective layer 16 and the protective layer 16a has been described, but the common electrode 17 need not be provided between the protective layer 16 and the protective layer 16a. In this case, a common electrode different in configuration from the common electrode 17 may be provided in the display device 105.

The protective layer 16a is lower in refractive index than the protective layer 16. The refractive index of the protective layer 16 is, for example, greater than 1.4 and less than or equal to 1.8. The refractive index of the protective layer 16a is, for example, less than or equal to 1.4.

In the display device 105 configured as described above, since the protective layer 16a is lower in refractive index than the protective layer 16, the light 31La emitted from the light-emitting element 31 in a wide angle (oblique direction) can be reflected off the interface between the protective layer 16 and the protective layer 16a. Furthermore, the light 31Lb emitted from the light-emitting element 31 in a wider angle can be reflected off the side surface protective layer 34. It is therefore possible to improve the light extraction efficiency of the display device 105.

Note that, in a case where the side surface protective layer 34 is not provided, there is a possibility that light 31Lc (see FIG. 31B) emitted from the light-emitting element 31 in a wider angle is not reflected off the interface between the protective layer 16 and the protective layer 16a and enters an adjacent subpixel 10 or the like.

### 6 Sixth Embodiment

### [Configuration of Display Device]

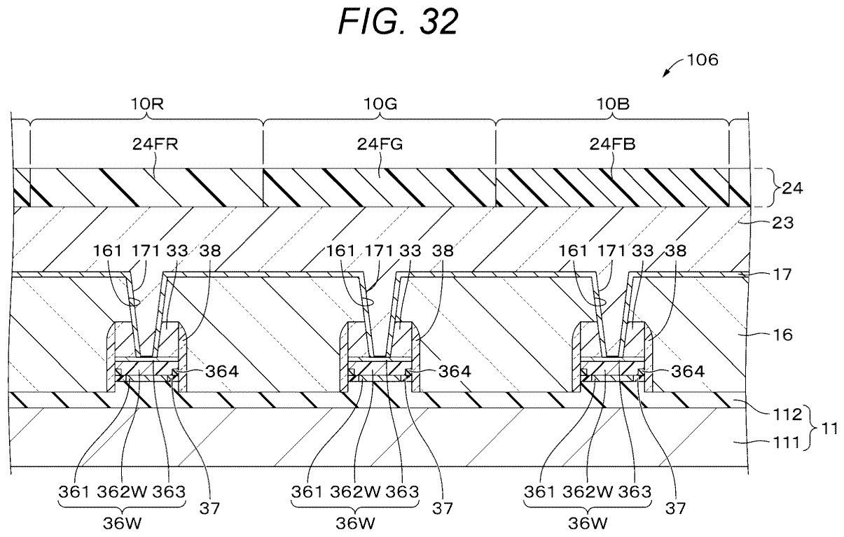

FIG. 32 is a cross-sectional view of a display device 106 according to a sixth embodiment. The display device 106 includes a drive substrate 11, a plurality of light-emitting elements 36W, a plurality of insulating layers 37, a plurality of protective layers 33, a plurality of side surface protective layers 38, a protective layer 16, a common electrode 17, a protective layer 23, and a color filter 24. Note that, in the sixth embodiment, the same reference signs are given to parts similar to those of the first embodiment or the third embodiment, and the description thereof will be omitted.

### (Light-Emitting Element 36W)

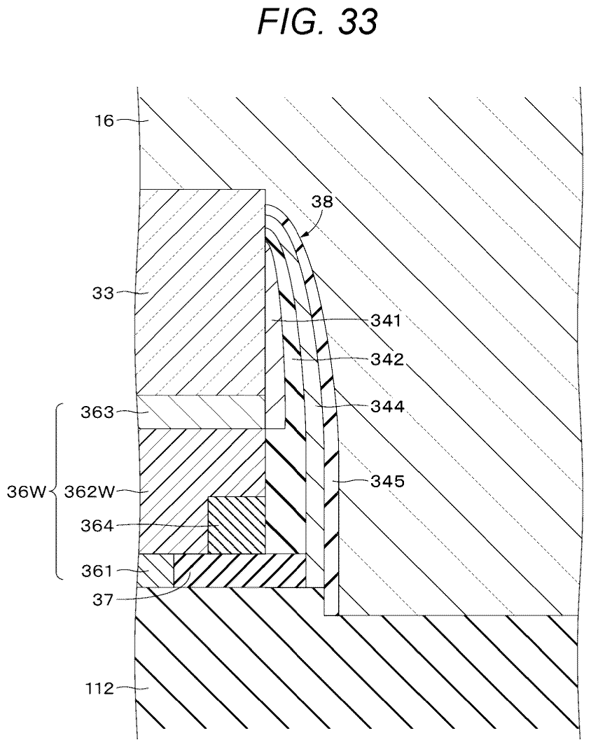

FIG. 33 is an enlarged cross-sectional view of the light-emitting element 36W. The light-emitting element 36W can emit white light. The light-emitting element 36W is a white OLED element, and can emit white light under the control of the drive circuit and the like. The light-emitting element 36W includes a first electrode 361, an OLED layer 362W, a second electrode 363, and an insulating layer 364.

In the fifth embodiment, the example where the light-emitting element 31 is provided on the first surface of the metal layer 32 has been described, but in the sixth embodiment, the light-emitting element 36W is provided on the first surface of the drive substrate.

The first electrode 361 is smaller in size than the OLED layer 362W and the second electrode 363 in plan view. The side surface of the first electrode 361 is located inside the side surface of the OLED layer 362W and the side surface of the second electrode 363 in the in-plane direction. The first electrode 361, the OLED layer 362W, and the second electrode 363 are similar to the first electrode 191, the OLED layer 192W, and the second electrode 193 in the third embodiment in all respects other than the above.

The insulating layer 364 is provided on the first surface of the insulating layer 37. The insulating layer 364 may have a closed loop shape in plan view. The insulating layer 364 is covered by the OLED layer 362 W such that the outer side surface of the insulating layer 364 is exposed from the side surface of the OLED layer 362W. As the material of the insulating layer 364, an inorganic material similar to that of the insulating layer 26 in the fourth embodiment can be exemplified.

### (Insulating Layer 37)

Each insulating layer 37 is provided on the first surface of the drive substrate 11 between the side surface of the first electrode 361 and the inner side surface of the side surface protective layer 38. The insulating layer 37 insulates between the first electrode 361 and the side surface protective layer 38. The insulating layer 37 may have a closed loop shape in plan view. As the material of the insulating layer 37, an inorganic material similar to that of the insulating layer 26 in the fourth embodiment can be exemplified.

### (Side Surface Protective Layer 38)

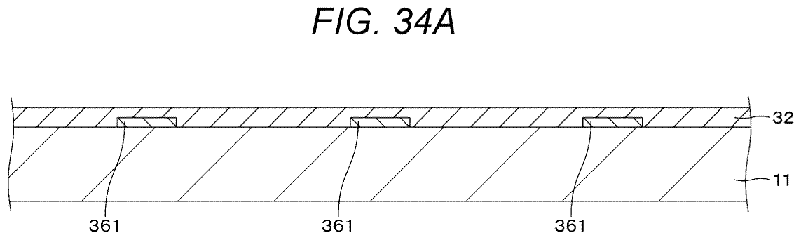

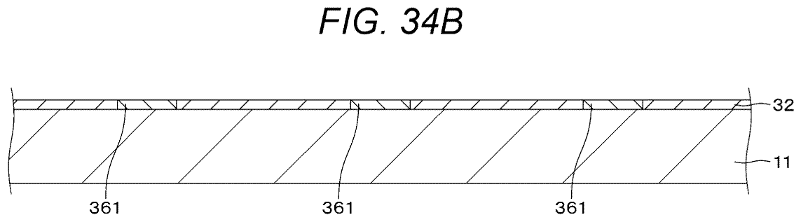

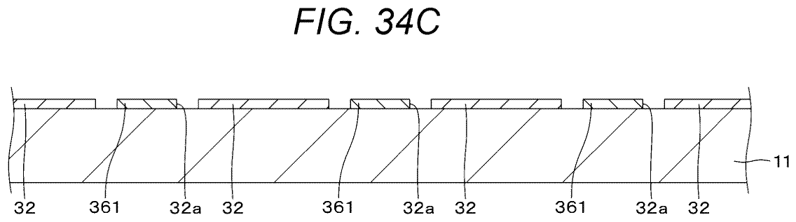

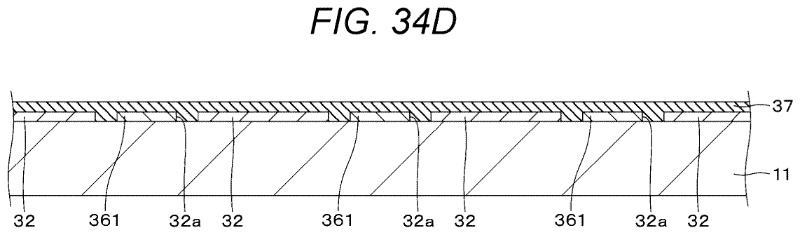

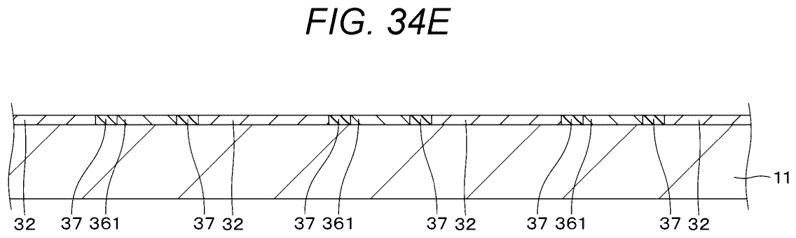

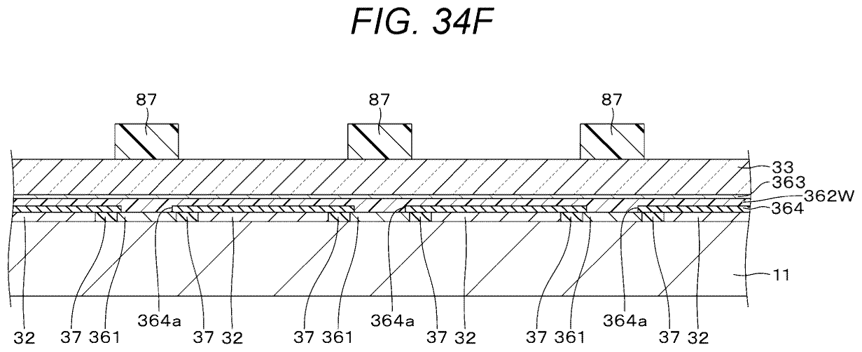

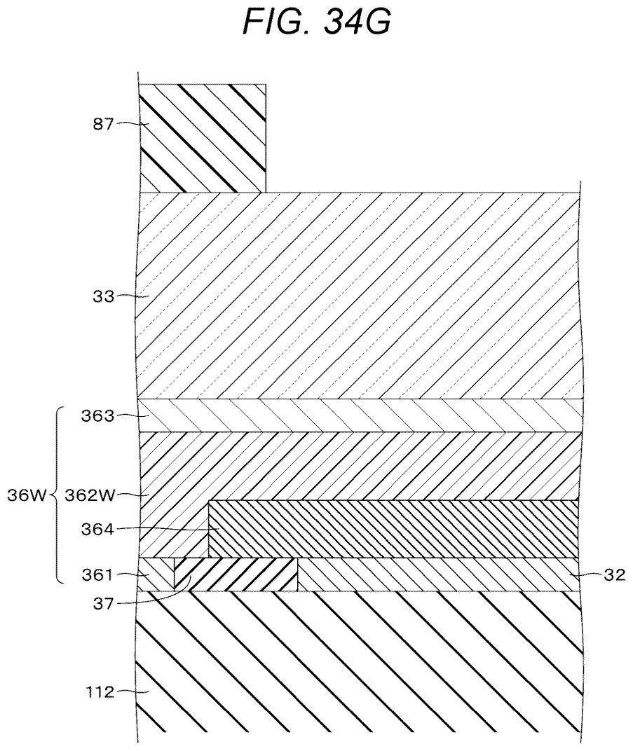

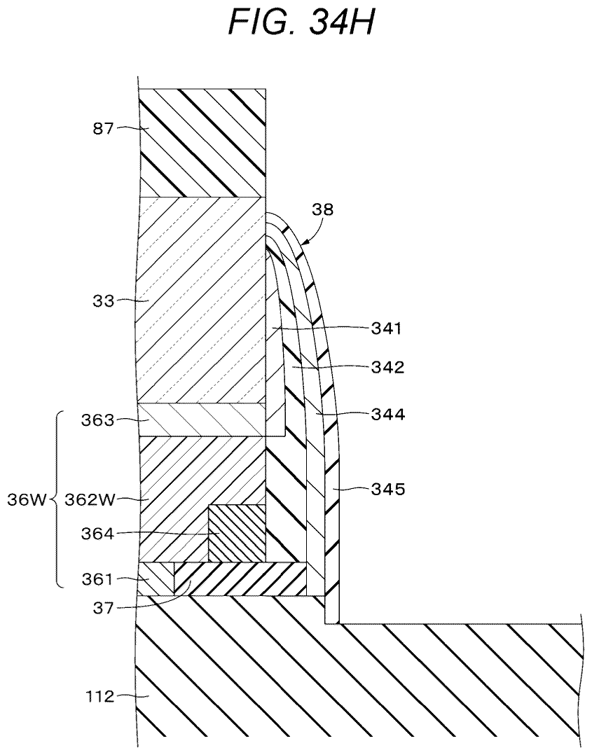

The side surface protective layer 38 may include a first side surface protective layer 341, a second side surface protective layer 342, a fourth side surface protective layer 344, and a fifth side surface protective layer 345 in sequence. The fourth side surface protective layer 344 may have its bottom portion connected to the side surface of the insulating layer 37. The fourth side surface protective layer 344 may include residues deposited as a result of dry etching of the metal layer 32 (see FIGS. 34G and 34H) provided between the first electrodes 361 adjacent in the in-plane direction in the manufacturing process of the display device 106. The side surface protective layer 38 may be similar to the side surface protective layer 34 in the fifth embodiment in all respects other than the above.

### [Method for Manufacturing Display Device]

Hereinafter, an example of the method for manufacturing the display device 106 according to the sixth embodiment will be described with reference to FIGS. 34A to 34H.

First, a metal layer is formed on the first surface of the drive substrate 11 using, for example, a sputtering method, and is then patterned using, for example, photolithography and dry etching. As a result, the plurality of first electrodes 311 is formed on the first surface of the drive substrate 11.

Next, as illustrated in FIG. 34A, the metal layer 32 is formed on the first surface of the drive substrate 11 using, for example, a sputtering method to cover the plurality of first electrodes 311. Next, as illustrated in FIG. 34B, the first surfaces of the plurality of first electrodes 311 are exposed by etching back the metal layer 32 using, for example, dry etching or by polishing the first surface of the metal layer 32 using, for example, CMP.

Next, as illustrated in FIG. 34C, a closed-loop opening 32a surrounding each first electrode 361 in plan view is formed by patterning the metal layer 32 using, for example, photolithography and dry etching. Next, as illustrated in FIG. 34D, the insulating layer 37 is formed on the first surfaces of the plurality of first electrodes 361 and the first surface of the metal layer 32 using, for example, a CVD method to fill the openings 32a. Next, as illustrated in FIG. 34E, the first surfaces of the plurality of first electrodes 311 and the metal layer 32 are exposed by etching back the insulating layer 37 using, for example, dry etching or by polishing the first surface of the insulating layer 37 using, for example, CMP.

Next, as illustrated in FIG. 34F, the insulating layer 364 is formed on the first surfaces of the plurality of first electrodes 361, the first surface of the metal layer 32, and the first surfaces of the plurality of insulating layers 37 using, for example, a sputtering method, and then a plurality of openings 364a is formed at positions corresponding to the plurality of subpixels 10 by patterning the insulating layer 364 using, for example, photolithography and dry etching. Next, as illustrated in FIG. 34F, the OLED layer 362W is formed on the first surface of the insulating layer 37 and the first surface of the first electrode 311 using, for example, a vapor deposition method to fill the plurality of openings 364a. Next, as illustrated in FIG. 34F, the second electrode 363 is formed on the first surface of the OLED layer 362W using, for example, a vapor deposition or sputtering method. Next, as illustrated in FIG. 34F, the protective layer 33 is formed on the first surface of the second electrode 363 using, for example, a vapor deposition or CVD method.

Next, as illustrated in FIGS. 34F and 34G, an island-shaped resist layer 87 is formed at a position corresponding to each subpixel 10 using, for example, photolithography. Next, the protective layer 33, the second electrode 363, the OLED layer 362W, the insulating layer 364, the metal layer 32, and the insulating layer 112 are sequentially processed through the resist layer 85 using, for example, dry etching to deposit residues on the side surface of the protective layer 33, the side surface of the second electrode 363, the side surface of the OLED layer 362W, the side surface of the insulating layer 364, and the side surface of the insulating layer 37. As a result, as illustrated in FIG. 34H, the plurality of light-emitting elements 36W is formed on the first surface of the drive substrate 11. Furthermore, the first side surface protective layer 341, the second side surface protective layer 342, the fourth side surface protective layer 344, and the fifth side surface protective layer 345 are sequentially formed on the side surface of the light-emitting element 36W.

Next, the process from the formation of the protective layer 16 to the formation of the color filter 24 is performed in a similar manner as the method for manufacturing the display device 103 according to the third embodiment. Through the above-described processes, the display device 106 is obtained.

### Effects

In the display device 106 according to the sixth embodiment, the side surface protective layer 38 covers the side surface of the light-emitting element 36W and the side surface of the protective layer 33, and is capable of reflecting light emitted obliquely from the light-emitting element 36W. The display device 106 according to the sixth embodiment can achieve similar effects as those of the display device 105 according to the fifth embodiment.

### Modifications

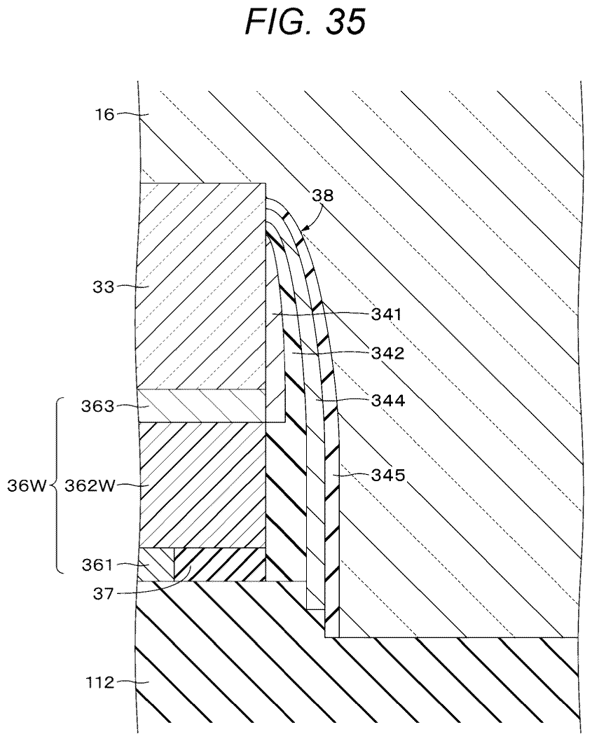

In the sixth embodiment, the example where the light-emitting element 36W includes the insulating layer 364 has been described (see FIG. 33), but as illustrated in FIG. 35, the light-emitting element 36W need not include the insulating layer 364. In this case, the second side surface protective layer 342 may have its bottom portion connected to the side surface of the insulating layer 37.

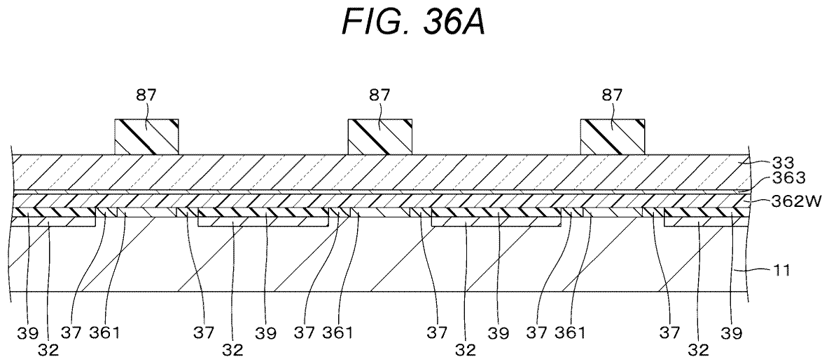

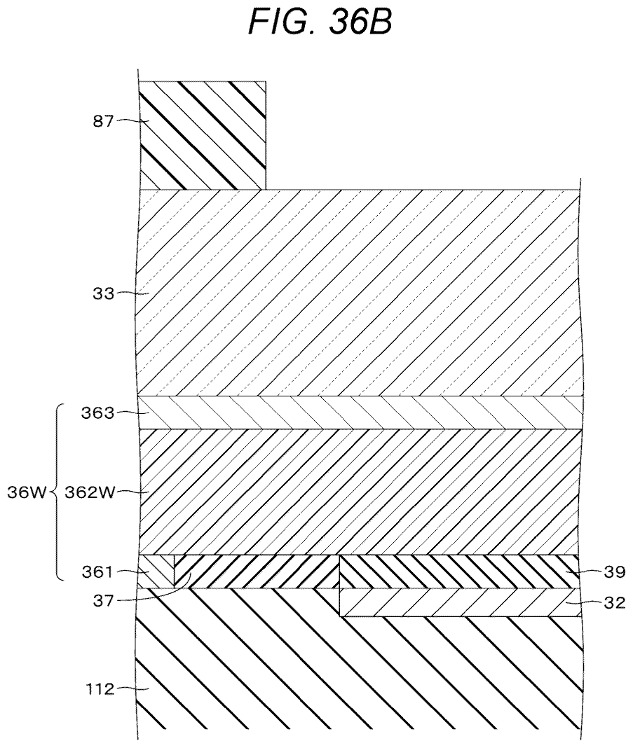

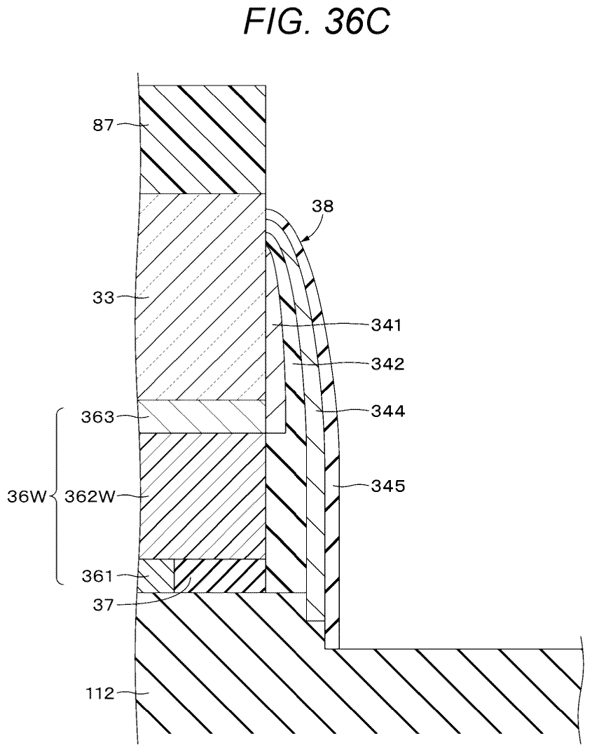

The display device 106 configured as described above may be manufactured as follows, for example. As illustrated in FIGS. 36A and 36B, the metal layer 32 and an insulating layer 39 are sequentially formed on the first surface of the drive substrate 11 between the adjacent light-emitting elements 36W. At this time, the metal layer 32 and the insulating layer 39 may be formed such that the insulating layer 39 is approximately the same height as the first electrode 361. The insulating layer 39 may include, for example, aluminum oxide (AlOₓ). Next, as illustrated in FIGS. 36A and 36B, the OLED layer 362W, the second electrode 363, and the protective layer 33 are sequentially stacked on the first surfaces of the plurality of first electrodes 311, the first surface of the insulating layer 39, and the first surfaces of the plurality of insulating layers 37, and then the island-shaped resist layer 87 is formed at a position corresponding to each subpixel 10. Next, the protective layer 33, the second electrode 363, the OLED layer 362W, the insulating layer 39, and the metal layer 32 are sequentially processed through the resist layer 87 using, for example, dry etching to deposit residues on the side surface of the protective layer 33, the side surface of the second electrode 363, the side surface of the OLED layer 362W, and the side surface of the insulating layer 37. As a result, as illustrated in FIG. 36C, the plurality of light-emitting elements 36W is formed on the first surface of the drive substrate 11. Furthermore, the first side surface protective layer 341, the second side surface protective layer 342, the fourth side surface protective layer 344, and the fifth side surface protective layer 345 are sequentially formed on the side surface of the light-emitting element 36W.

In the above-described example of the manufacturing method, the example where the insulating layer 37 and the insulating layer 39 are formed between the adjacent first electrodes 361 has been described, but the insulating layer 37 and the insulating layer 39 may be formed by one insulating layer.

### 7 Seventh Embodiment

### [Configuration of Display Device]

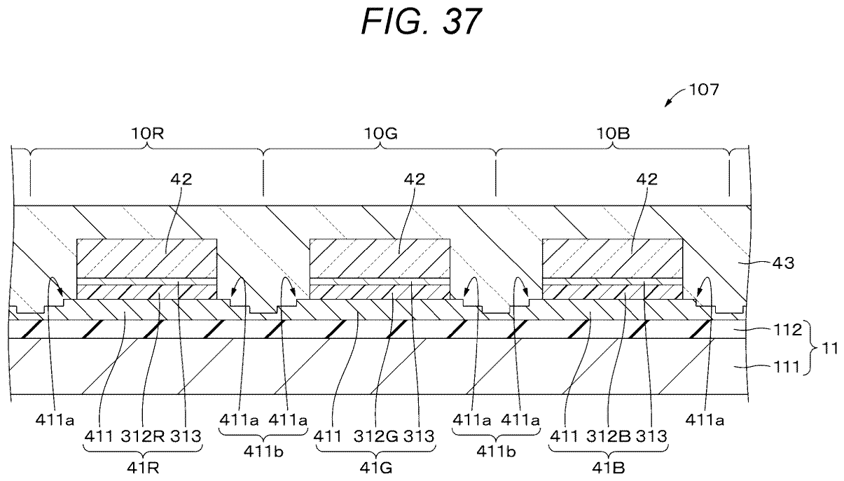

FIG. 37 is a cross-sectional view of a display device 107 according to a seventh embodiment. The display device 107 includes a drive substrate 11, a plurality of light-emitting elements 41R, a plurality of light-emitting elements 41G, a plurality of light-emitting elements 41B, a plurality of protective layers 42, and a protective layer 43. Note that, in the seventh embodiment, the same reference signs are given to parts similar to those of the fifth embodiment, and the description thereof will be omitted.

### (Light-Emitting Elements 41R, 41G, and 41B)

The light-emitting element 41R includes a first electrode 411, an OLED layer 312R, and a second electrode 313 in sequence. The light-emitting element 41G includes a first electrode 411, an OLED layer 312G, and a second electrode 313 in sequence. The light-emitting element 31B includes a first electrode 411, an OLED layer 312B, and a second electrode 313 in sequence. Note that, in the following description, the light-emitting elements 41R, 41G, and 41B may be collectively referred to as light-emitting element 41 unless otherwise distinguished.

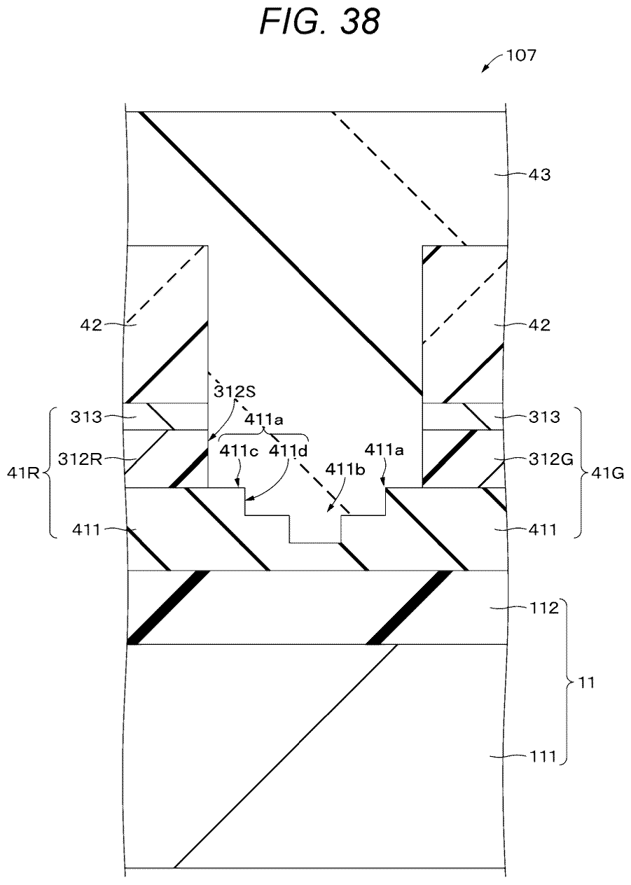

FIG. 38 is an enlarged cross-sectional view of a region between the adjacent light-emitting elements 41. The first electrode 411 is connected between the adjacent light-emitting elements 41 in the display region RE1, and is shared by the plurality of light-emitting elements 41 in the display region RE1. The second electrode 413 is an anode. The first electrode 411 has at least one step 411a in the peripheral region of each OLED layer 312. FIG. 38 illustrates an example where the first electrode 411 has two steps 411a in the peripheral region of each OLED layer 312. Since the first electrode 411 has at least one step 411a in the peripheral region of each OLED layer 312, the adhesion between the first electrode 411 and the protective layer 43 can be improved. From the viewpoint of improving the adhesion between the first electrode 411 and the protective layer 43, it is preferable to provide two or more steps 411a. The step 411a may be formed by changing the thickness of the first electrode 411.

The larger the distance from the geometric center of the light-emitting element 41, the lower the step 411a becomes. The step 411a may have a closed loop shape surrounding the light-emitting element 12 in plan view. A recess 411b may be formed by the step 411a located between the adjacent light-emitting elements 12.

The step 411a has a first surface 411c and a second surface 411d. The first surface 411c is approximately perpendicular to the thickness direction of the first electrode 411. The second surface 411d extends in a downward direction from the outer periphery of the first surface 411c. Here, the downward direction refers to a direction from the first surface 411c of the first electrode 411 toward the second surface 411d in the thickness direction of the first electrode 411. The second surface 411d may be approximately perpendicular to the first surface 411c or may be at an angle to the first surface 411c. The second surface of the OLED layer 312 and the first surface 411c of the step 411a closest to the second surface of the OLED layer 312 may be located at the same height. That is, a side surface 312S of the OLED layer 312 and the second surface 411d of the step 411a closest to the side surface 312S of the OLED layer 312 may be provided at different positions in the in-plane direction.

The first electrode 411 may be similar to the first electrode 311 in the fifth embodiment in all respects other than the above.

### (Protective Layer 42)

The protective layer 42 may be similar to the protective layer 33 in the fifth embodiment except that the protective layer 42 does not have the contact hole 161. Note that the second electrode 313 may be connected to a wiring line or the like of the drive substrate 11 via a connection member (not illustrated).

### (Protective Layer 43)

The protective layer 43 may be similar to the protective layer 16 in the fifth embodiment except that the protective layer 43 does not have the plurality of contact holes 161. The protective layer 43 is provided to fill a space between the adjacent light-emitting elements 41 and cover the plurality of protective layers 42 and the plurality of light-emitting elements 41.

### Effects

In the seventh embodiment, the first electrode 411 has at least one step 411a in the peripheral region of each OLED layer 312. This configuration allows an increase in the contact area between the first electrode 411 and the protective layer 43, which helps to improve the adhesion between the first electrode 411 and the protective layer 43. It is therefore possible to prevent delamination between the OLED layer 312R and the second electrode 313.

### Modifications

### Modification 1

In the seventh embodiment, the example where the second surface of the OLED layer 312 and the first surface 411c of the step 411a closest to the second surface of the OLED layer 312 are located at the same height has been described (see FIG. 38). However, the positional relationship between the second surface of the OLED layer 312 and the first surface 411c of the step 411a closest to the second surface of the OLED layer 312 is not limited to such an example. For example, as illustrated in FIG. 39, the height of the second surface of the OLED layer 312 (i.e., the interface between the first electrode 411 and the OLED layer 312) may be higher than the height of the first surface 411c of the step 411a closest to the second surface of the OLED layer 312. That is, the side surface 312S of the OLED layer 312 and the side surface of the recess 411b may be approximately flush with each other. In this case, the adhesion between the first electrode 411 and the protective layer 43 can be further improved.

### Modification 2

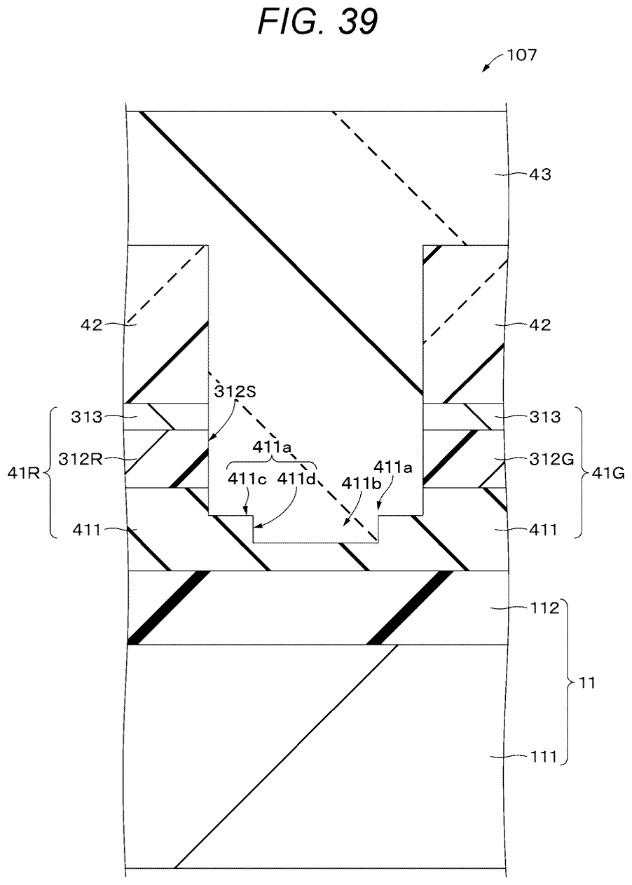

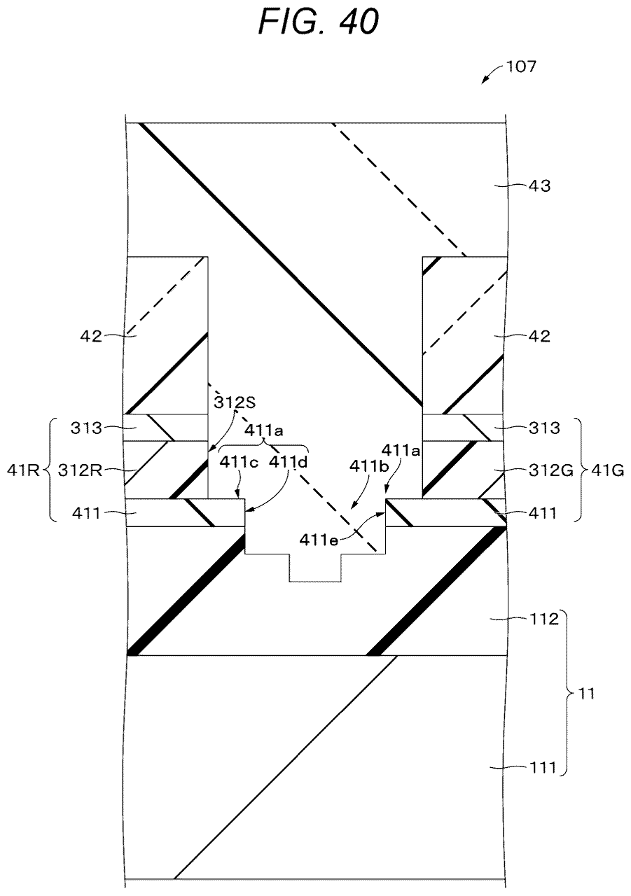

In the seventh embodiment, the example where at least one step 411a is provided only on the first electrode 411 has been described, but as illustrated in FIG. 40, at least one step 411a may be provided in both the first electrode 411 and the insulating layer 112. In this case, an opening 411e may be formed between the adjacent light-emitting elements 41. The opening 411e may have a closed loop shape surrounding the entire peripheral edge of the light-emitting element 41, or may have a segmented loop shape partially surrounding the peripheral edge of the second surface of the protective layer 13.

### Modification 3

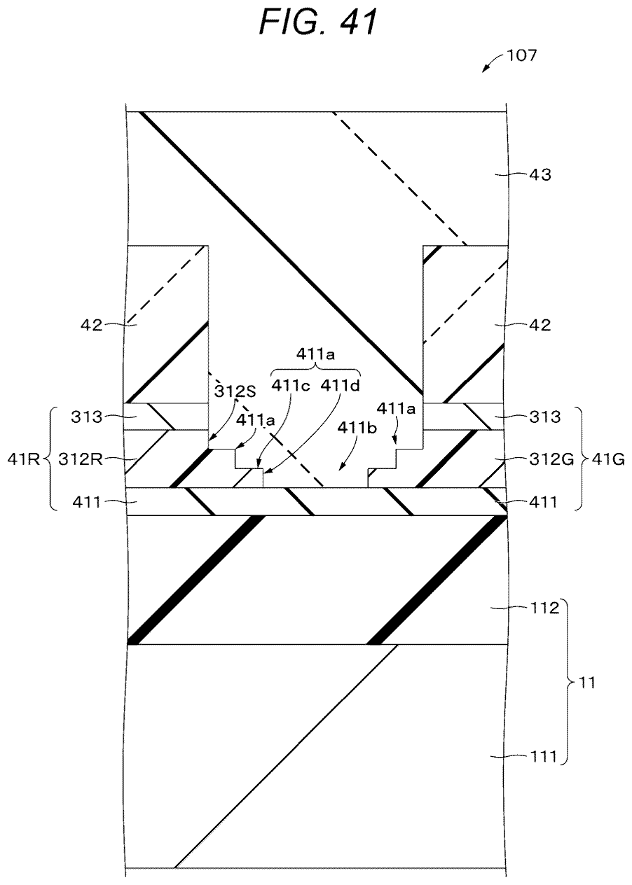

In the seventh embodiment, the example where at least one step 411a is provided on the first surface of the first electrode 411 has been described, but the location where the step 411a is provided is not limited to the first electrode 411. For example, as illustrated in FIG. 41, instead of providing at least one step 411a on the first surface of the first electrode 411, at least one step 411a may be provided on the side surface of the OLED layer 312. Alternatively, at least one step 411a may be provided on the first surface of the first electrode 411, and at least one step 411a may be provided on the side surface of the OLED layer 312.

### Modification 4

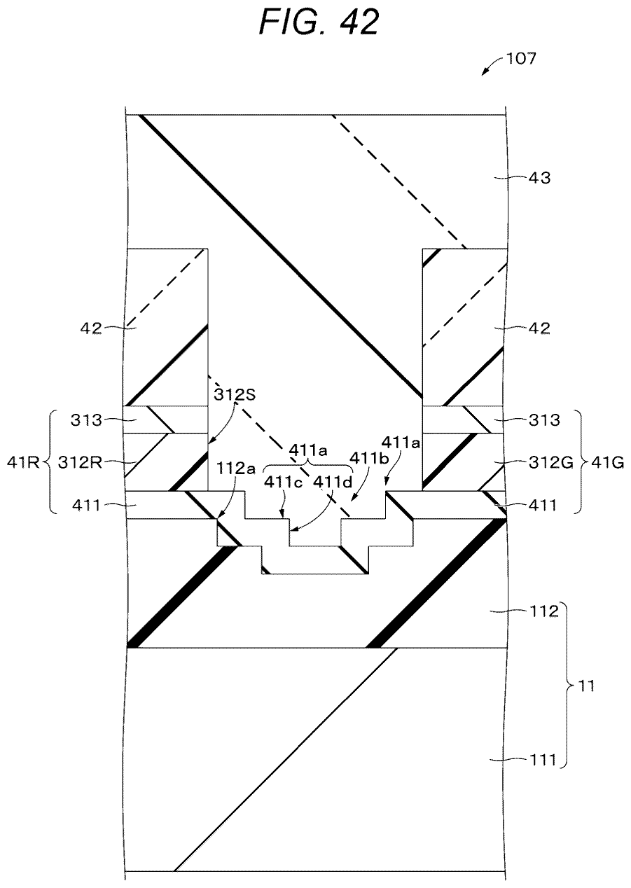

In the seventh embodiment, the example where the step 411a is formed on the first surface of the first electrode 411 by changing the thickness of the first electrode 411 has been described, but the configuration of the step 411a is not limited to such an example. For example, as illustrated in FIG. 42, a configuration where the first surface of the insulating layer 112 has at least one step 112a in the peripheral region of each light-emitting element 41, and the first electrode 411 is provided along the step 112a to form at least one step 411a on the first surface of the first electrode 411 may be employed. The insulating layer 112 is an example of the underlayer provided under the plurality of light-emitting elements 41.

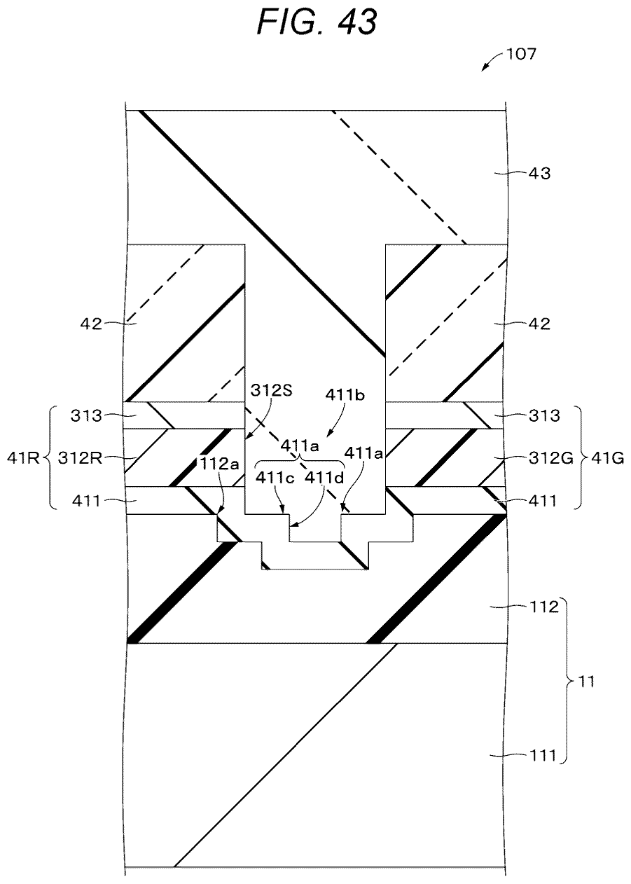

With the above-described configuration, the side surface 312S of the OLED layer 312 and the side surface of the recess 411b need not be flush with each other as illustrated in FIG. 42, or the side surface 312S of the OLED layer 312 and the side surface of the recess 411b may be flush with each other as illustrated in FIG. 43. From the viewpoint of improving the adhesion between the first electrode 411 and the protective layer 43, the side surface 312S of the OLED layer 312 and the side surface of the recess 411b are preferably flush with each other.

More specifically, as illustrated in FIG. 42, the height of the second surface of the OLED layer 312 (i.e., the interface between the first electrode 411 and the OLED layer 312) may be the same as the height of the first surface 411c of the step 411a closest to the second surface of the OLED layer 312. Alternatively, as illustrated in FIG. 43, the height of the second surface of the OLED layer 312 (i.e., the interface between the first electrode 411 and the OLED layer 312) may be higher than the height of the first surface 411c of the step 411a closest to the second surface of the OLED layer 312.

### 8 Eighth Embodiment

### [Overview]

The inventors have considered the following method for manufacturing a display device. First, a plurality of first electrodes is formed on the first surface of a drive substrate, and then an OLED layer, a second electrode, and a protective layer are sequentially stacked over the plurality of first electrodes to form a laminate. Next, the laminate is separated using, for example, photolithography and dry etching to form a plurality of light-emitting elements on the first surface of the drive substrate.

As described above, it is possible to suppress, by employing the structure where the OLED layer is separated for each light-emitting element, the carrier leakage between pixels and improve the luminous efficiency. However, in a case where the laminate is separated by single processing as described above, all the layers constituting the laminate are separated, so that there is a possibility that delamination occurs between the OLED layer and the second electrode due to film stress. In a case where delamination occurs, the drive voltage of the light-emitting element may increase. This is as described in the overview and the like in the third embodiment.

In the eighth embodiment, when the laminate is separated, dividing the laminate in a plurality of steps while ensuring the laminate is not completely separated can prevent the occurrence of delamination between the OLED layer and the second electrode due to film stress.

### [Configuration of Display Device]

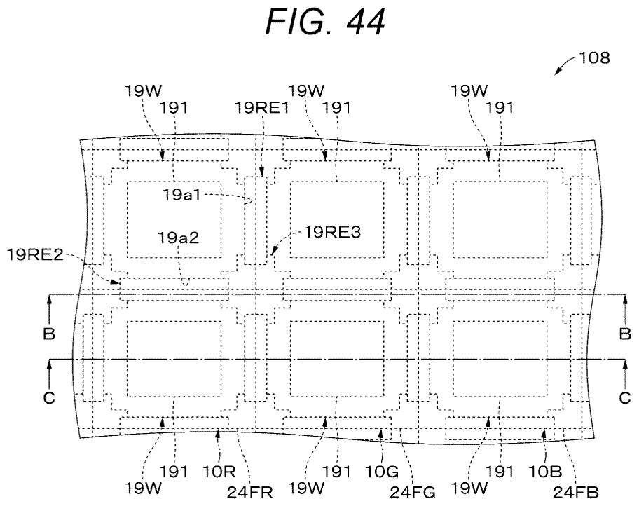

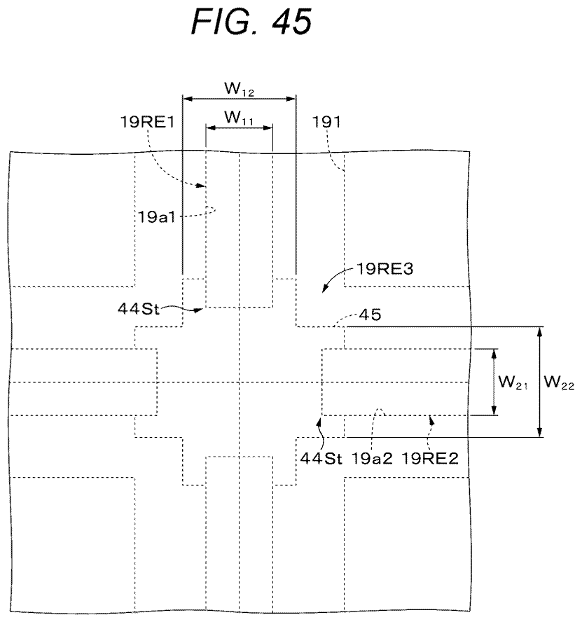

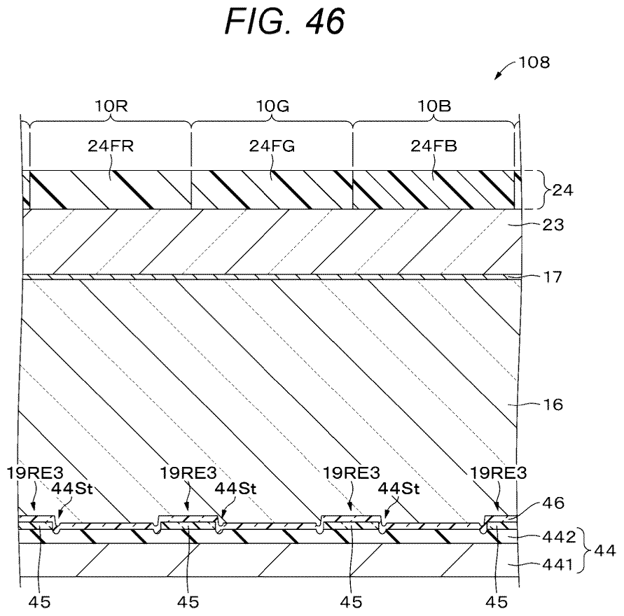

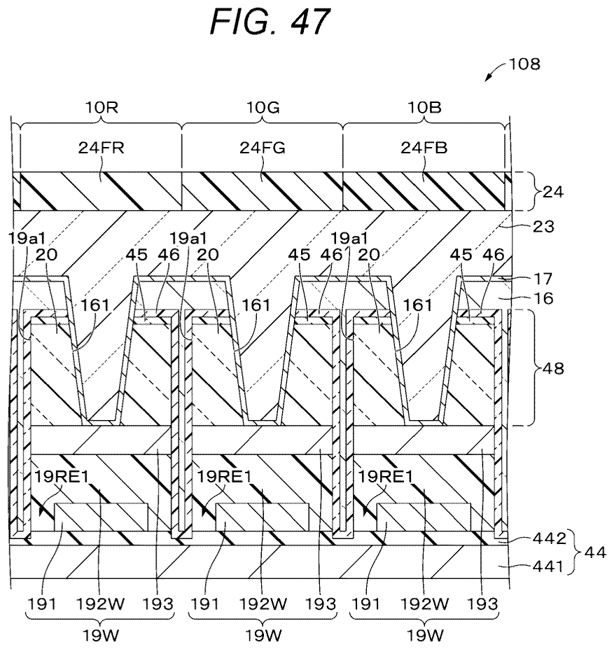

FIG. 44 is an enlarged plan view of a part of a display region RE1 of a display device 108 according to the eighth embodiment. FIG. 45 is an enlarged plan view of a part of FIG. 44. FIG. 46 is a cross-sectional view taken along line B-B in FIG. 44. FIG. 47 is a cross-sectional view taken along line C-C in FIG. 44. The display device 108 includes a drive substrate 44, a plurality of light-emitting elements 19W, a plurality of protective layers (first protective layers) 20, a protective layer (second protective layer) 45, a protective layer (third protective layer) 46, a protective layer (fourth protective layer) 16, a common electrode 17, a protective layer (fifth protective layer) 23, and a color filter 24. Note that, in the eighth embodiment, the same reference signs are given to parts similar to those of the third embodiment, and the description thereof will be omitted.

Herein, one of the two directions orthogonal to each other on the display surface of the display device 108 is referred to as first direction, and the other direction is referred to as second direction. On the display surface of the display device 108, a direction between the first direction and the second direction is referred to as third direction. The first direction and the second direction may be a horizontal direction and a vertical direction of the display surface of the display device 108, respectively.

Herein, a region between the first electrodes 191 in the first direction, that is, a region between the light-emitting elements 19W in the first direction is referred to as first region 19RE1. A region between the first electrodes 191 in the second direction, that is, a region between the light-emitting elements 19W in the second direction is referred to as second region 19RE2. A region between the first electrodes 191 in the third direction, that is, a region between the light-emitting elements 19W in the first direction is referred to as third region 19RE3. The first region 19RE1 has an elongated shape extending in the second direction. The second region 19RE2 has an elongated shape extending in the first direction.

The plurality of light-emitting elements 19W is arranged in the first direction and the second direction. The plurality of light-emitting elements 19W may be two-dimensionally arranged in a stripe array or the like. The first region 19RE1 and the third region 19RE3 are alternately provided in the second direction. The second region 19RE2 and the third region 19RE3 are alternately provided in the first direction.

A groove 19al is provided in the first region 19RE1. That is, the groove 19al is provided between the light-emitting elements 19W adjacent in the first direction. The groove 19al extends in the second direction. A groove 19a2 is provided in the second region 19RE2. That is, the groove 19a2 is provided between the light-emitting elements 19W adjacent in the second direction. The groove 19a2 extends in the second direction. The groove 19al and the groove 19a2 intersect in the third region 19RE3.

The light-emitting elements 19W adjacent in the first direction are separated by two or more different separation widths of the groove 19al. More specifically, for example, the light-emitting elements 19W adjacent in the first direction are separated by at least a first separation width W11 and a second separation width W12. The second separation width W12 may be a separation width at both the ends of the first region 19RE1, and the first separation width W11 may be a separation width between both the ends of the first region 19RE1. The width W12 of the groove 19al may be wider or narrower than the width W11 of the groove 19al. FIGS. 44 and 45 illustrate the former example. The protective layer 20 provided on the light-emitting element 19W is also separated by two or more different separation widths of the groove 19al in a similar manner as the light-emitting element 19W.

The light-emitting elements 19W adjacent in the second direction are separated by two or more different separation widths of the groove 19a2. More specifically, for example, the light-emitting elements 19W adjacent in the second direction are separated by at least a third separation width W21 and a fourth separation width W22. The third separation width W21 may be a separation width at both the ends of the second region 19RE2, and the fourth separation width W22 may be a separation width between both the ends of the second region 19RE2. The width W22 of the groove 19a2 may be wider or narrower than the width W21 of the groove 19a2. FIGS. 44 and 45 illustrate the former example. The protective layer 20 provided on the light-emitting element 19W is also separated by two or more different separation widths of the groove 19a2 in a similar manner as the light-emitting element 19W.

### (Drive Substrate 44)

The drive substrate 44 has a plurality of steps 44St in the third region 19RE3 of the first surface of the drive substrate 44. The drive substrate 44 includes a substrate 441 and an insulating layer 442. The insulating layer 442 as an underlayer is provided under the plurality of light-emitting elements 19W. The insulating layer 442 has the plurality of steps 44St on the first surface on which the plurality of light-emitting elements 19W is provided. The plurality of steps 44St may be provided at both the ends of the first region 19RE1 and at both the ends of the second region 19RE2. The steps 44St may be formed by two rounds of simultaneous etching. The drive substrate 44, the substrate 441, and the insulating layer 442 may be similar to the drive substrate 11, the substrate 111, and the insulating layer 112 in the first embodiment in all respects other than the above.

### (Protective Layer 45)

The protective layer 45 is provided on the first surfaces of the plurality of protective layers 20. The protective layer 45 on each protective layer 20 is connected in a specified direction. More specifically, the protective layer 45 on each protective layer 20 is connected between the light-emitting elements 19W in the third direction between the first direction and the second direction. On the other hand, the protective layer 45 on each protective layer 20 is separated between the light-emitting elements 19W in the first direction and is separated between the light-emitting elements 19W in the second direction. The protective layer 45 is provided along each intersection of the groove 19a1 and the groove 19a2 to cover a part of the side surface of each light-emitting element 19W and cover a part of the side surface of each protective layer 20.

The protective layer 45 may have characteristics similar to those of the protective layer 13 in the first embodiment. As the material of the protective layer 45, an inorganic material similar to that of the protective layer 13 in the first embodiment can be exemplified.

### (Protective Layer 46)

The protective layer 46 covers the plurality of light-emitting elements 19W provided with the protective layer 45. The protective layer 46 is provided along the groove 19al and the groove 19a2. The protective layer 46 is connected between the light-emitting elements 19W in the first direction, between the light-emitting elements 19W in the second direction, and between the light-emitting elements 19W in the third direction.

The protective layer 46 may have characteristics similar to those of the protective layer 13 in the first embodiment. As the material of the protective layer 46, an inorganic material similar to that of the protective layer 13 in the first embodiment can be exemplified.

The materials of the protective layer 45 and the protective layer 46 may be different or the same. Here, the difference in the materials of the protective layer 45 and the protective layer 46 may refer to the components of the materials constituting the protective layers 45 and the protective layer 46 being different, or the components of the materials constituting the protective layer 45 and the protective layer 46 being the same but with varying content ratios. In the eighth embodiment, the example where the protective layer 45 and the protective layer 46 are provided will be described, but the protective layer 45 and the protective layer 46 may be integrated into a single layer.

### (Protective Layer 48)

The protective layer 48 may include the protective layer 20, the protective layer 45, and the protective layer 46. The thickness of the protective layer 48 located between the light-emitting elements 19W in the first direction and the thickness of the protective layer 48 located between the light-emitting elements 19W in the second direction may be different from the thickness of the protective layer 48 located between the light-emitting elements 19W in the third direction.

The number of the protective layers 48 located between the light-emitting elements 19W in the first direction and the number of the protective layers 48 located between the light-emitting elements 19W in the second direction may be different from the number of the protective layers 48 located between the light-emitting elements 19W in the third direction. In the eighth embodiment, the example where the protective layer 20, the protective layer 45, and the protective layer 46 are provided will be described, but the protective layer 20, the protective layer 45, and the protective layer 46 may be integrated into a single layer.

### [Method for Manufacturing Display Device]

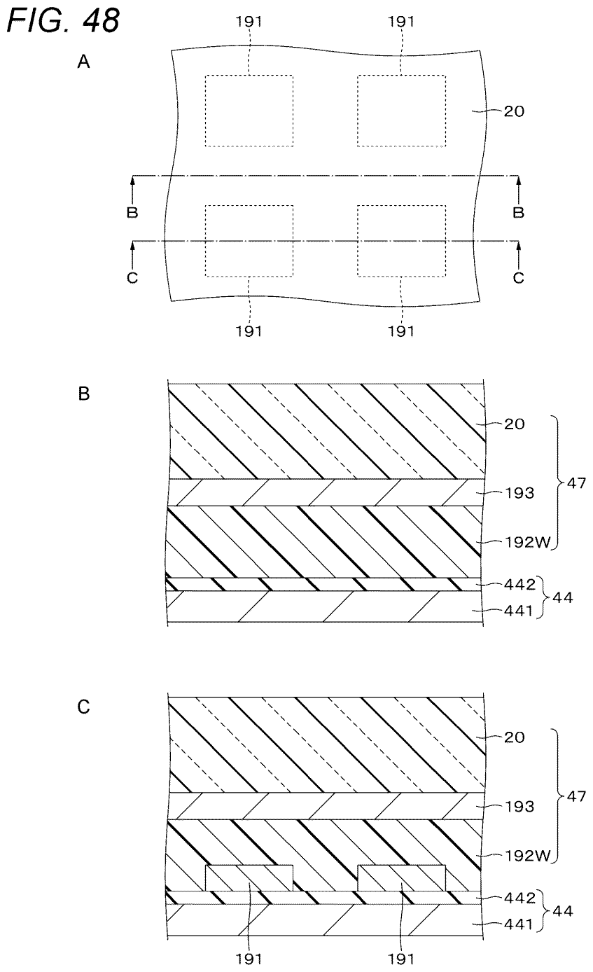

Hereinafter, an example of the method for manufacturing the display device 108 according to the eighth embodiment will be described with reference to FIGS. 48A to 52C.

First, a metal layer is formed on the first surface of the drive substrate 44 using, for example, a sputtering method, and is then patterned using, for example, photolithography and dry etching. As a result, the plurality of first electrodes 311 is formed on the first surface of the drive substrate 44. Next, as illustrated in FIGS. 48A, 48B, and 48C, the OLED layer 192W, the second electrode 193, and the protective layer 20 are sequentially stacked on the first surfaces of the plurality of first electrodes 191 to cover the plurality of first electrodes 191 using, for example, a sputtering method, a vapor deposition method, a CVD method, and the like. Hereinafter, the laminate including the OLED layer 192W, the second electrode 193, and the protective layer 20 is referred to as laminate 47.

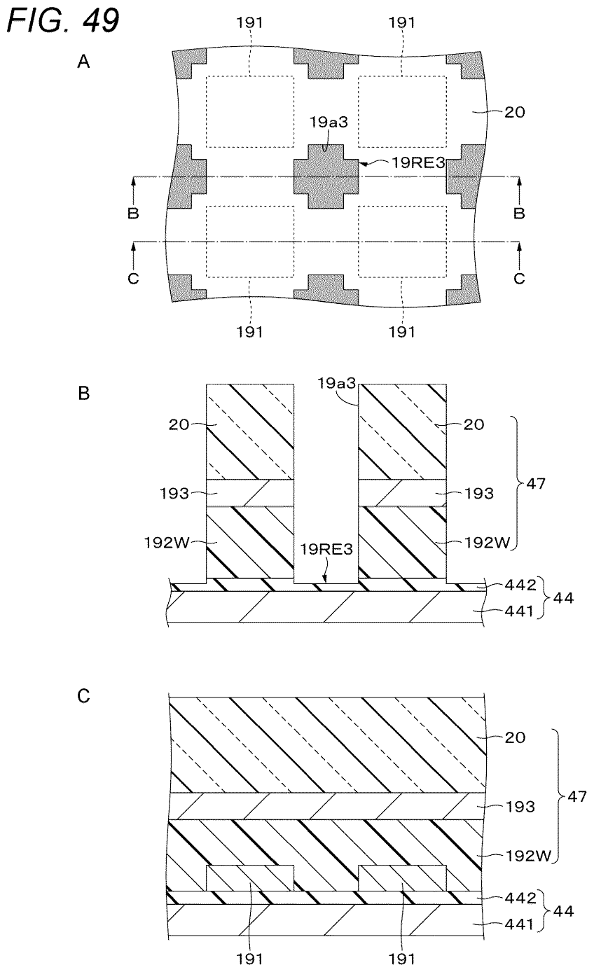

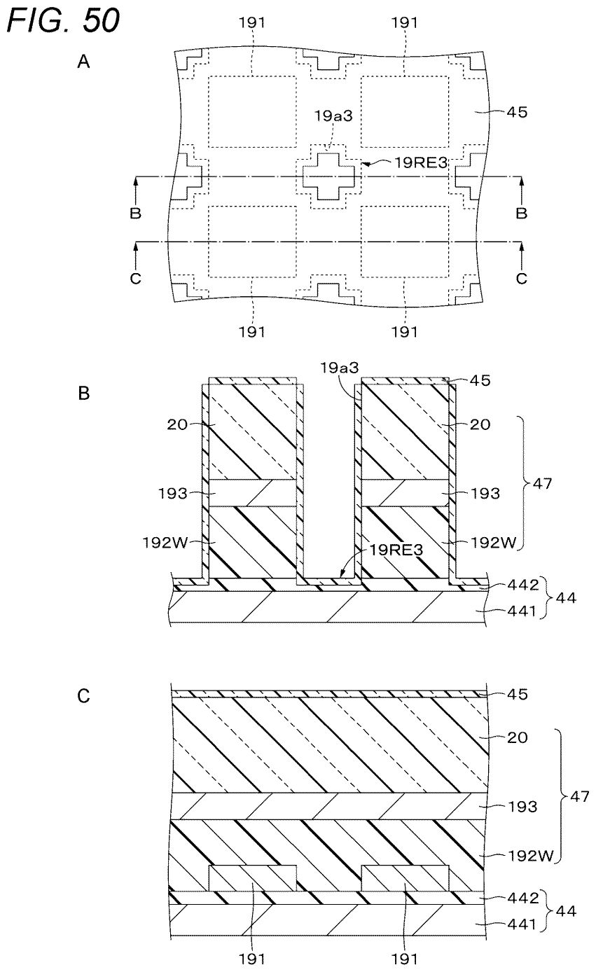

Next, as illustrated in FIGS. 49A, 49B, and 49C, each third region 19RE3 of the laminate 47 is processed using, for example, photolithography and dry etching until the first surface of the drive substrate 44 is exposed. As a result, a recess 19a3 is formed in each third region 19RE3 of the laminate 47. A region shaded in gray in FIG. 49A represents a region where the first surface of the drive substrate 44 is exposed in this process. Hereinafter, the processing of the laminate 47 in this process is referred to as first processing of the laminate 47. Next, as illustrated in FIGS. 50A, 50B, and 50C, the protective layer 45 is formed, along the plurality of recesses 19a3, on the first surface of the protective layer 20 and in the plurality of recesses 19a3 using, for example, a CVD method.

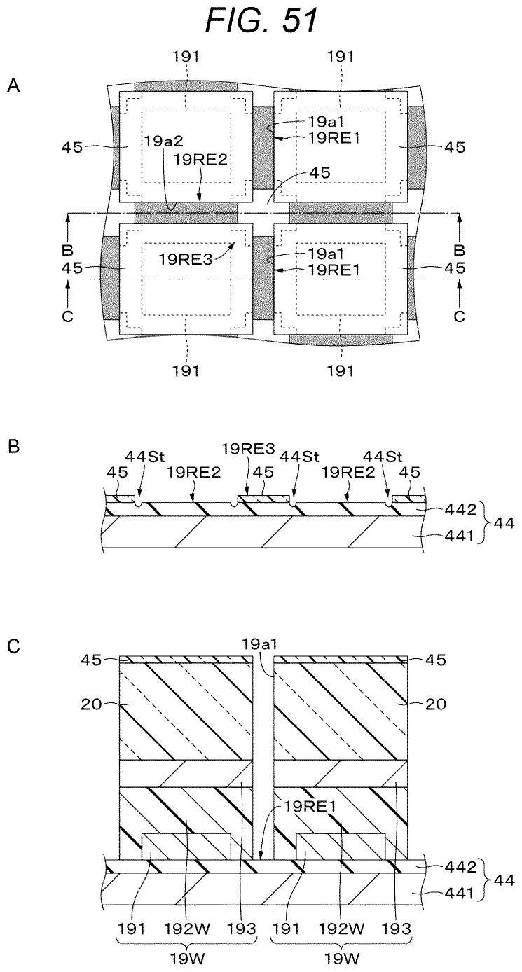

Next, as illustrated in FIGS. 51A, 51B, and 51C, the first region 19RE1 and second region 19RE2 of the laminate 47 in which the protective layer 45 is formed are processed using, for example, photolithography and dry etching until the first surface of the drive substrate 44 is exposed. As a result, the groove 19a1 is formed in the first region 19RE1 of the laminate 47, and the groove 19a2 is formed in the second region 19RE2 of the laminate 47. Therefore, the laminate 47 is separated for each subpixel 10, and the plurality of light-emitting elements 19W is formed on the first surface of the drive substrate 44. Hereinafter, the processing of the laminate 47 in this process is referred to as second processing of the laminate 47. A region shaded in gray in FIG. 51A represents a region where the first surface of the drive substrate 44 is exposed in this process.

In the process of performing the second processing of the laminate 47, the protective layer 45 formed on the first surface of the laminate 47 is separated in the first region 19RE1 and the second region 19RE2, but remains connected in the third region 19RE3. Furthermore, the third region 19RE3 of the first surface of the drive substrate 44 has a portion processed twice by the first processing of the laminate 47 and the second processing of the laminate 47. As illustrated in FIG. 51B, the step 44St is formed in this portion.

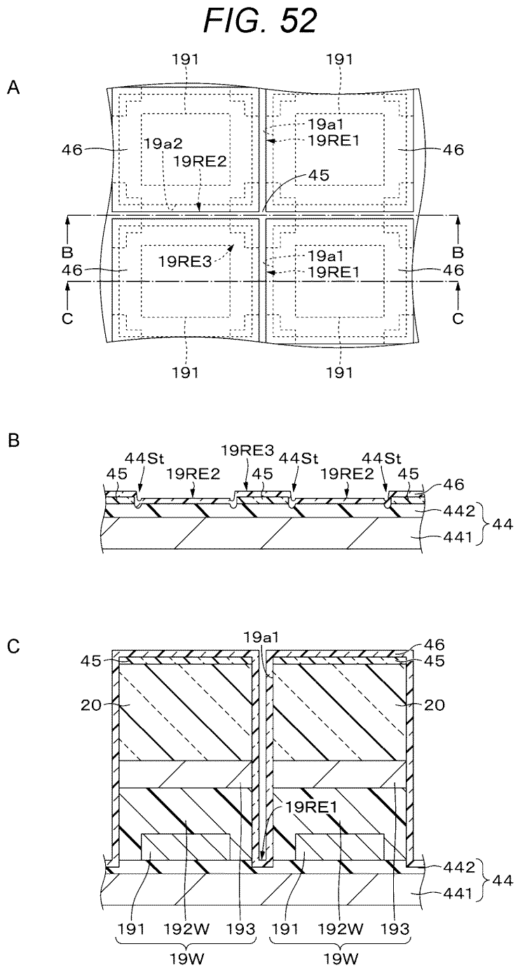

Next, as illustrated in FIGS. 52A, 52B, and 52C, the protective layer 46 is formed, along the groove 19a1 and the groove 19a2, on the first surface of the protective layer 45 and in the groove 19al and the groove 19a2, using, for example, a CVD method.

Next, the process from the formation of the protective layer 16 to the formation of the color filter 24 is performed in a similar manner as the method for manufacturing the display device 103 according to the third embodiment. Through the above-described processes, the display device 108 is obtained.

### Effects

In the display device 108 according to the eighth embodiment, the protective layer 45 is provided on the first surfaces of the plurality of protective layers 20, and the protective layer 45 on each protective layer 20 is connected between the light-emitting elements 19W in the third direction between the first direction and the second direction. With this configuration, the protective layer 45 partially covers the side surface of each light-emitting element 19W at each intersection of the grooves 19a1 and 19a2. It is therefore possible to prevent the occurrence of delamination between the peripheral edge portion of the OLED layer 192W and the peripheral edge portion of the second electrode 193. It is therefore possible to prevent an increase in the drive voltage of the light-emitting element 19W. Furthermore, it is possible to increase the luminous efficiency. The protective layer 46 covers the plurality of light-emitting elements 19W provided with the protective layer 45 along the grooves 19a1 and 19a2. This configuration can further prevent the occurrence of delamination between the peripheral edge portion of the OLED layer 192W and the peripheral edge portion of the second electrode 193.

In the display device 108 according to the eighth embodiment, as described above, the occurrence of delamination between the peripheral edge portions of the OLED layer 192W, the second electrode 193, and the like can be prevented, so that the range of film options for the OLED layer 192W, the second electrode 193, and the like can be expanded.

In the method for manufacturing the display device 108 according to the eighth embodiment, when the laminate 47 is separated, dividing the laminate 47 in a plurality of steps while ensuring the laminate 47 is not completely separated can prevent the occurrence of delamination between the OLED layer 192W and the second electrode 193 due to film stress.

Furthermore, it is possible to prevent, by forming the protective layer 45 covering the side surface of each light-emitting element 19W and the side surface of each protective layer 20, the occurrence of film delamination when the light-emitting element 19W is finally separated.

In the method for manufacturing the display device 108 according to the eighth embodiment, in the process of performing the first processing of the laminate 47, the third region 19RE3 of the laminate 47 is processed to form the recess 19a3. At this time, the laminate 47 is separated in the third region 19RE3, but is connected in the first region 19RE1 and the second region 19RE2, so that the laminate 47 is not completely separated. Therefore, in the process of performing the first processing of the laminate 47, the impact of film stress of the protective layer 20 on the interface between the OLED layer 192W and the second electrode 193 can be reduced. Therefore, in the process of performing the first processing of the laminate 47, delamination is unlikely to occur between the OLED layer 192W and the second electrode 193. After the process of performing the first processing of the laminate 47, the first surface of the laminate 47, the side surface of the recess 19a3, and the like are covered by the protective layer 45. With this configuration, it is possible to implement a measure to prevent delamination between the OLED layer 192W and the second electrode 193.

After the formation of the protective layer 45, in the process of performing the second processing of the laminate 47, the groove 19al and the groove 19a2 are formed by processing the middle of the first region 19RE1 and the middle of the second region 19RE2. At this time, the protective layer 45 is separated together with the laminate 47 in the first region 19RE1 and the second region 19RE2, but is connected in the third region 19RE3, so that the laminate 47 on which the protective layer 45 is formed is not completely separated. Furthermore, the side surface of the recess 19a3 of the third region 19RE3 is covered by the protective layer 45. It is therefore possible to reduce, even in the process of performing the second processing of the laminate 47, the impact of film stress of the protective layer 20 on the interface between the OLED layer 192W and the second electrode 193. Thus, even in the process of performing the second processing of the laminate 47, delamination is unlikely to occur between the OLED layer 192W and the second electrode 193.

After the process of performing the second processing of the laminate 47, the first surface of the laminate 47, the side surfaces of the grooves 19a1 and 19a2, and the like are covered by the protective layer 46. This configuration can prevent delamination between the OLED layer 192W and the second electrode 193.

### 9 Ninth Embodiment

### [Configuration of Display Device]

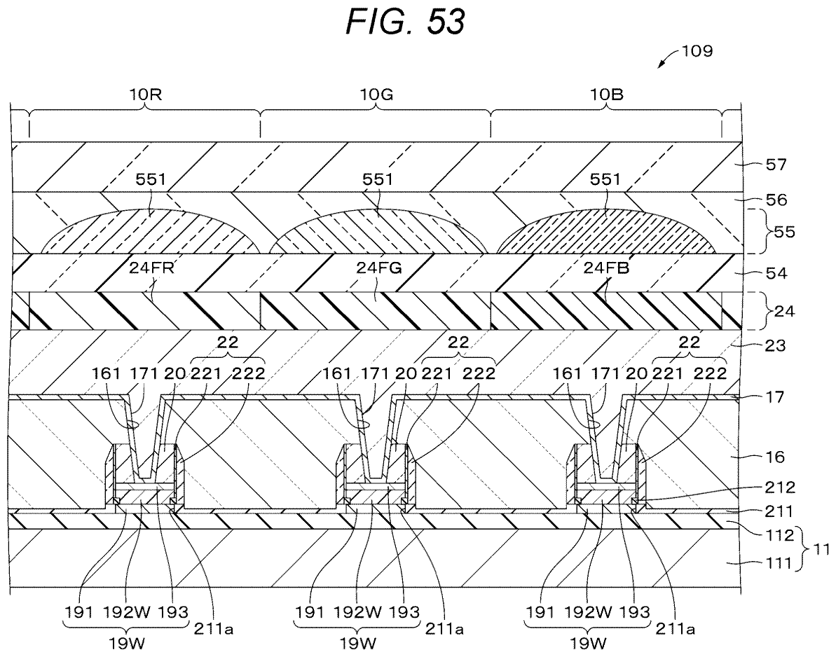

FIG. 53 is a cross-sectional view of a display device 109 according to a ninth embodiment. The display device 109 is different from the display device 103 according to the third embodiment (see FIG. 14) in that the display device 109 further includes a planarization layer 54 and a lens array 55. The display device 109 may further include a protective layer 56 and a cover layer 57, as necessary.

### (Planarization Layer 54)

The planarization layer 54 covers the color filter 24 to form a flat surface on the first surface of the color filter 24. The planarization layer 54 includes, for example, an inorganic material or polymer resin. As the inorganic material, an inorganic material similar to that of the protective layer 13 in the first embodiment can be exemplified. As the polymer resin, a polymer resin similar to that of the protective layer 13 in the first embodiment can be exemplified.

### (Lens Array 55)

The lens array 55 is provided on the first surface of the planarization layer 54. The lens array 55 includes a plurality of lenses 551. Each lens 551 can focus light emitted upward from the corresponding light-emitting element 19W in the forward direction. The plurality of lenses 551 is called an on chip microlens (OCL), and is two-dimensionally arranged on the first surface of the planarization layer 54 in a prescribed arrangement pattern.

A single lens 551 may be provided above each light-emitting elements 19W, or two or more lenses 551 may be provided above each light-emitting element 19W. FIG. 53 illustrates an example where a single lens 551 is provided above each light-emitting element 19W. The lens 551 may have a curved surface from which the light incident from the corresponding light-emitting element 19W is emitted. The curved surface may be a convex curved surface curved in a direction away from the light-emitting element 19W or a concave curved surface curved in a direction toward the light-emitting element 19W. Examples of the curved surface include, but are not limited to, an approximately parabolic shape, an approximately hemispherical shape, and an approximately semielliptical shape.

The lens 551 includes, for example, an inorganic material or polymer resin transparent to the visible light. The inorganic material includes, for example, silicon oxide (SiOₓ). The polymer resin includes, for example, ultraviolet curable resin.

### (Protective Layer 56)

The protective layer 56 covers the lens array 55. The protective layer 56 is different in refractive index from the lens array 55. The refractive index of the protective layer 56 may be higher or lower than the refractive index of the lens array 55. In a case where the lens 551 has a convex curved surface on the emission surface side, the protective layer 56 is preferably lower in refractive index than the lens array 55 from the viewpoint of increasing the front luminance. In a case where the lens 551 has a concave curved surface on the emission surface side, the protective layer 56 is preferably higher in refractive index than the lens array 55 from the viewpoint of increasing the front luminance.

### (Cover Layer 57)

The cover layer 57 is provided on the first surface of the protective layer 56. The cover layer 57 seals each member such as the plurality of light-emitting elements 12W provided on the first surface on the drive substrate 11. The cover layer 57 is transparent to light emitted from the light-emitting element 19W. The cover layer 57 is preferably transparent to the visible light. The cover layer 57 is, for example, a glass substrate.

### Effects

In the ninth embodiment, the lens array 55 is provided above the plurality of light-emitting elements 19W. This configuration allows the lens array 55 to focus light emitted upward from each light-emitting element 19W in the forward direction. It is therefore possible to increase the front luminance of the display device 109.

### [Modifications]

In the ninth embodiment, the example where the display device 103 according to the third embodiment further includes the planarization layer 54 and the lens array 55 has been described, but the display devices 101, 102, and 104 to 108 according to the first, second, and fourth to eighth embodiments may further include the planarization layer 54 and the lens array 55. A display device 109A according to a tenth embodiment to be described later may further include the planarization layer 54 and the lens array 55.

In a case where the above-described configuration is employed, the protective layer 56 and the cover layer 57 may be further provided. In a case where the above-described configuration is employed, among the display devices 101, 102, and 104 to 108 according to the first, second, and fourth to eighth embodiments, a display device not provided with the color filter 24 may further include the color filter 24.

### 10 Tenth Embodiment

### [Configuration of Display Device]

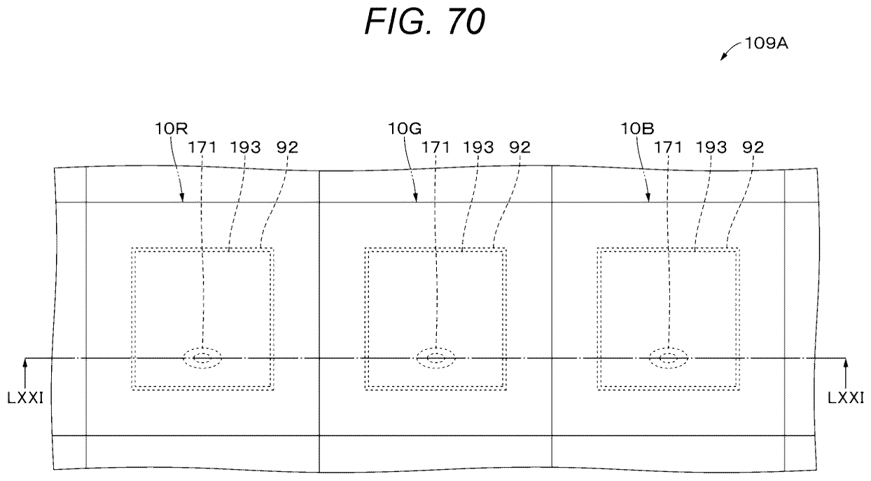

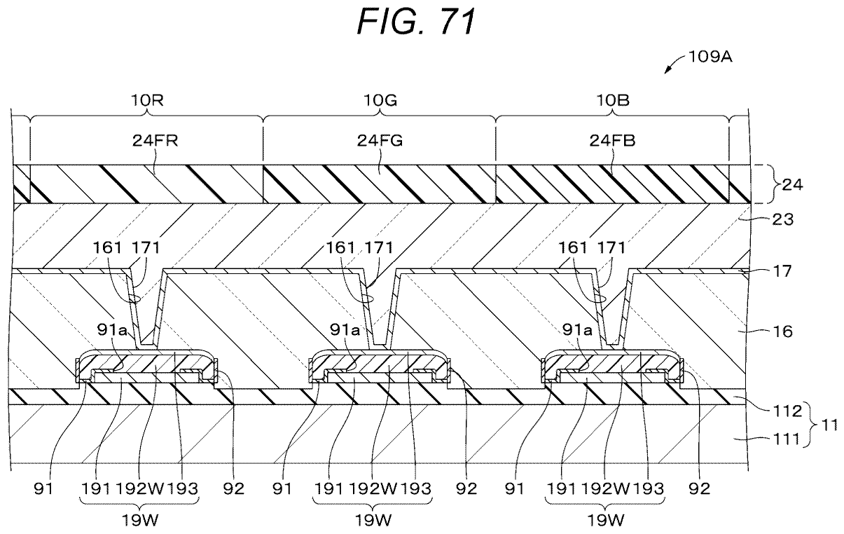

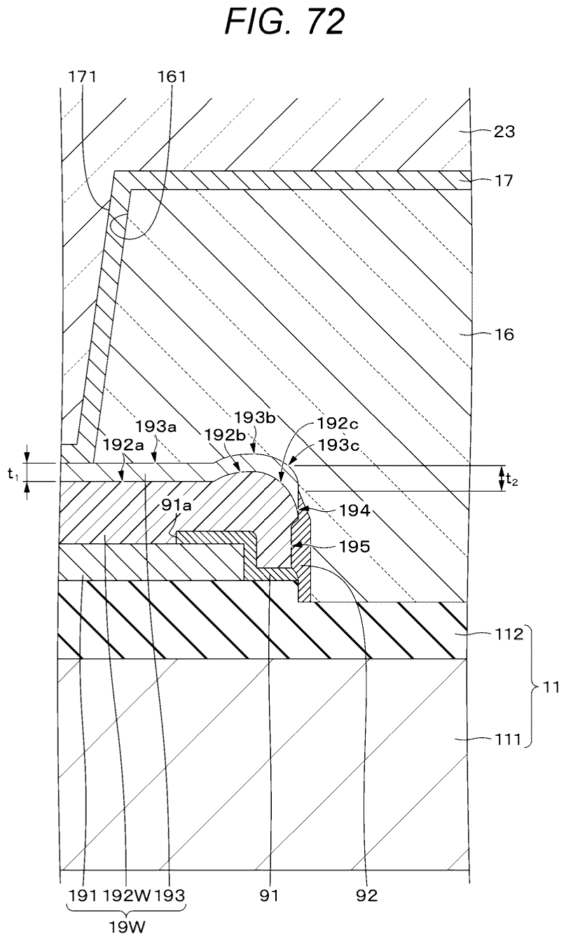

FIG. 70 is an enlarged plan view of a part of a display region RE1 of the display device 109A according to the tenth embodiment. FIG. 71 is a cross-sectional view taken along line LXXI-LXXI in FIG. 70. FIG. 72 is an enlarged cross-sectional view of a part of a light-emitting element 19W. The display device 109A includes a drive substrate 11, a plurality of the light-emitting elements 19W, an insulating layer 91, a side surface protective layer 92, a protective layer 16, a common electrode 17, a protective layer 23, and a color filter 24. Note that, in the tenth embodiment, the same reference signs are given to parts identical or corresponding to those of the third embodiment.

### (Insulating Layer 91)

The insulating layer 91 covers the peripheral edge portion of the first surface of the first electrode 191, the side surface (end surface) of the first electrode 191, and the area around the first electrode 191. The insulating layer 91 is provided individually for each of the plurality of light-emitting elements 12 in the display region RE1. That is, the insulating layer 91 is divided between the light-emitting elements 19W adjacent in the in-plane direction in the display region RE1. The insulating layer 91 has a plurality of openings 91a. Each of the plurality of openings 91a is provided for a corresponding one of the light-emitting elements 19W. More specifically, each of the plurality of openings 91a is provided on the first surface (the surface adjacent to the OLED layer 192W) of the first electrode 191. The first electrode 191 and the OLED layer 192W are in contact with each other via the opening 91a.

### (Light-Emitting Element 19W)

As illustrated in FIG. 72, the light-emitting element 19W, more specifically, the second electrode 193, has a flat portion 193a and a convex portion 193b on the first surface. The convex portion 193b protrudes relative to the flat portion 193a. The convex portion 193b is provided along the outer periphery of the flat portion 193a and has a closed loop shape surrounding the flat portion 193a in plan view. The convex portion 193b has an inclined portion 193c along the peripheral edge of the first surface of the light-emitting element 19W. The inclined portion 193c is provided adjacent to the side surface of the light-emitting element 19W. The inclined portion 193c extends outward and downward from the peripheral edge of the first surface of the light-emitting element 19W.

The light-emitting element 19W has an eaves-like overhanging portion 194 that is a uniformly overhanging upper end of the side surface (end of the side surface on the first surface side (upper surface side)). More specifically, the light-emitting element 19W has a recess 195 on the side surface of the OLED layer 192W, and the recess 195 is a side-etched portion and is provided along the entire side surface of the light-emitting element 19W. Since the light-emitting element 19W has the overhanging portion 194, in the process of dividing the OLED layer 192W and the second electrode 193 by etching, residues deposited in the recess 195 as a result of the etching are shaded by the overhanging portion 194, which reduces the incidence of ions on the residues and makes the residues less prone to etching. It is therefore possible to increase the thickness of the side surface protective layer 92, which helps to prevent delamination between the OLED layer 192W and the second electrode 193.

A thickness t₂ of the second electrode 193 at the inclined portion 193c is greater than a thickness t₁ of the second electrode 193 at the flat portion 193a. This configuration suppresses, in the process of dividing the OLED layer 192W and the second electrode 193 by etching, a retraction of the peripheral edge portion of the second electrode 193 to make the side surface of the light-emitting element 19W prone to side etching, which makes it easier to form the overhanging portion 194 on the side surface of the light-emitting element 19W. Here, the thicknesses t₁ and t₂ of the second electrode 193 each represent a thickness in a direction perpendicular to the flat portion 193a.

The OLED layer 192W has a flat portion 192a and a convex portion 192b on the first surface. The flat portion 192a is provided above the first electrode 191 and is surrounded by the convex portion 192b in plan view. The flat portion 192a is parallel to the first surface of the first electrode 191. The flat portion 192a is formed corresponding to the first surface of the first electrode 191 exposed from the opening 91a of the insulating layer 91.

The convex portion 192b protrudes relative to the flat portion 192a. The convex portion 192b is provided along the outer periphery of the flat portion 193a and has a closed loop shape surrounding the flat portion 192a in plan view. The convex portion 192b is formed corresponding to a step formed by the side surface of the opening 91a of the insulating layer 91 and a step formed by the side surface of the first electrode 191. The convex portion 192b may be formed following both the steps.

The convex portion 192b has an inclined portion 192c along the peripheral edge of the first surface of the OLED layer 192W. The inclined portion 192c is provided adjacent to the side surface of the OLED layer 192W. The inclined portion 192c extends outward and downward from the peripheral edge of the first surface of the OLED layer 192W. The cross-sectional shape of the inclined portion 192c may be, but is not limited to, a convex curved shape or an approximately linear shape, for example. Here, the cross-sectional shape of the inclined portion 192c refers to a cross-sectional shape of the inclined portion 192c obtained by cutting the display device 109A to include the central axis of the light-emitting element 19W. The inclined portion 192c is formed corresponding to the step formed by the side surface of the first electrode 191. The inclined portion 192c may be formed following the step.

The second electrode 193 follows the shape of the first surface of the OLED layer 192W, that is, the flat portion 192a and the convex portion 192b on the first surface of the OLED layer 192W. With this configuration, the flat portion 193a and the convex portion 193b are formed on the first surface of the second electrode 193 (that is, the first surface of the light-emitting element 19W). Since the flat portion 193a and the convex portion 193b of the second electrode 193 are formed following the flat portion 192a and the convex portion 192b of the OLED layer 192W, the shapes, positional relationship, and the like of the flat portion 193a and the convex portion 193b are similar to the shapes, positional relationship, and the like of the flat portion 192a and the convex portion 192b. Therefore, the description of the shapes, positional relationship, and the like of the flat portion 193a and the convex portion 193b will be omitted.

The second electrode 193 preferably includes an etch-resistant material. Specifically, the second electrode 193 is preferably lower in etching rate (etching speed) than the OLED layer 192W. This configuration makes, in the process of dividing the OLED layer 192W and the second electrode 193 by etching, the OLED layer 192W prone to side etching, which makes it easier to form the overhanging portion 194 on the side surface of the light-emitting element 19W.

### (Side Surface Protective Layer 92)

The side surface protective layer 92 covers at least the boundary between the side surface of the OLED layer 192W and the side surface of the second electrode 193. This configuration can reduce the impact of film stress of the protective layer 13 on the interface between the OLED layer 192W and the second electrode 193. More specifically, the side surface protective layer 92 covers the side surface of the second electrode 193, the side surface of the OLED layer 192W, and the side surface of the insulating layer 91. In the tenth embodiment, an example where the side surface protective layer 92 covers the side surface of the insulating layer 91 will be described, but the side surface protective layer 92 need not cover the side surface of the insulating layer 91.

The side surface protective layer 92 may have a closed loop shape or a segmented loop shape in plan view. The lower end (one end adjacent to the drive substrate 11) of the side surface protective layer 92 is lower than the second surface of the first electrode 191 and is located on the first surface of the insulating layer 91. However, the position of the lower end of the side surface protective layer 92 is not limited to such an example. For example, the lower end of the side surface protective layer 92 may be approximately the same in height as the second surface of the first electrode 191 and be located on the first surface of the insulating layer 91, or may be higher than the second surface of the first electrode 191 and be located on the first surface of the insulating layer 91.

The upper end of the side surface protective layer 92 (the other end remote from the drive substrate 11) is provided at approximately the same position as the peripheral edge of the first surface of the light-emitting element 19W or at a position lower than the peripheral edge of the first surface of the light-emitting element 19W.

The side surface protective layer 92 can protect the side surface of the light-emitting element 19W. For example, the side surface protective layer 92 may be capable of suppressing moisture ingress into the light-emitting element 19W from an external environment to suppress deterioration of the light-emitting element 19W. The side surface protective layer 92 is transparent to white light emitted from the light-emitting element 19W. The side surface protective layer 92 is preferably transparent to the visible light. The side surface protective layer 92 preferably has insulating properties.

The side surface protective layer 92 includes, for example, residues deposited on the side surface of the light-emitting element 19W as a result of etching of the second electrode 193, the OLED layer 192W, and the insulating layer 91. More specifically, the side surface protective layer 92 includes, for example, the constituent materials of the second electrode 193, the constituent materials of the OLED layer 192W, and the constituent materials of the insulating layer 91.

The deposited residues and constituent materials of the side surface protective layer 92 are not limited to the above-described examples. For example, the side surface protective layer 92 includes, for example, residues deposited on the side surface of the light-emitting element 19W as a result of etching of the second electrode 193, the OLED layer 192W, the insulating layer 91, and the insulating layer 112. More specifically, the side surface protective layer 92 includes, for example, the constituent materials of the second electrode 193, the constituent materials of the OLED layer 192W, and the constituent materials of the insulating layer 91, and the constituent materials of the insulating layer 112.

In a case where the lower end of the side surface protective layer 92 is provided on the first surface of the insulating layer 91, the side surface protective layer 92 may include, for example, residues deposited on the side surface of the light-emitting element 19W as a result of etching of the second electrode 193 and the OLED layer 192W. More specifically, the side surface protective layer 92 includes, for example, the constituent materials of the second electrode 193 and the constituent materials of the OLED layer 192W.

The constituent materials of the second electrode 193 included in the side surface protective layer 92 may include some or all of the constituent materials of the second electrode 193. The constituent materials of the OLED layer 192W included in the side surface protective layer 92 may include some or all of the constituent materials of the OLED layer 192W. The constituent materials of the insulating layer 91 included in the side surface protective layer 92 may include some or all of the constituent materials of the insulating layer 91. The constituent materials of the insulating layer 112 included in the side surface protective layer 92 may include some or all of the constituent materials of the insulating layer 112.

### [Method for Manufacturing Display Device]

### First Example

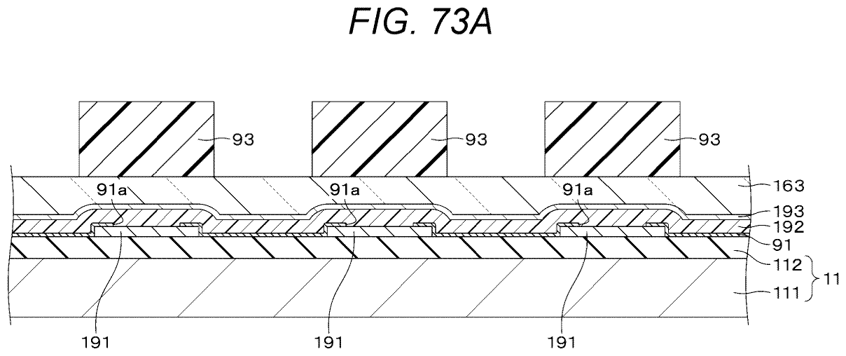

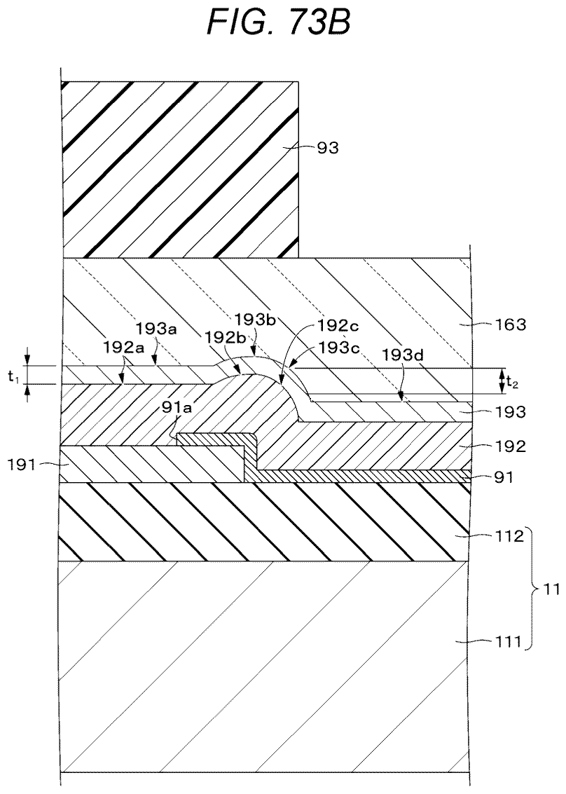

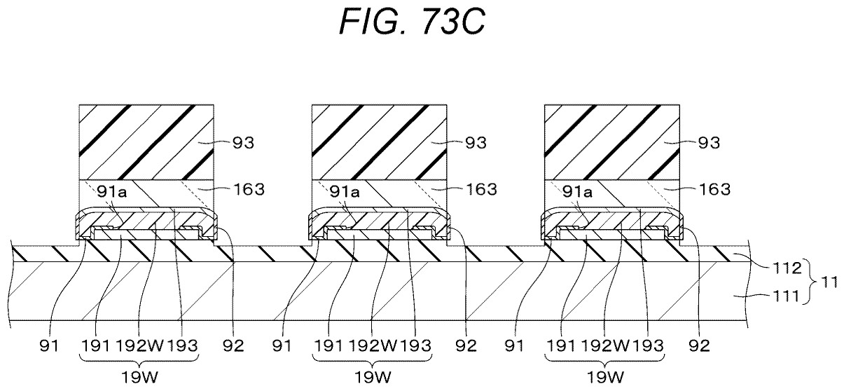

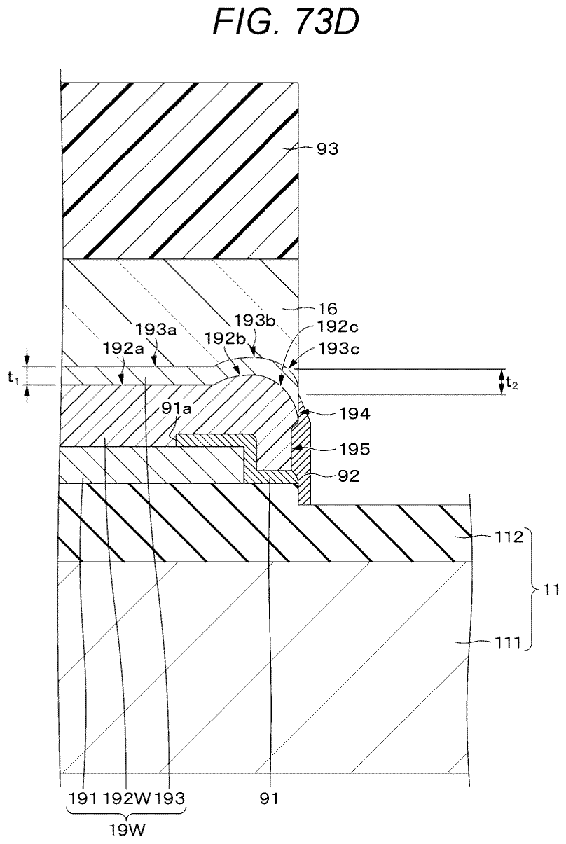

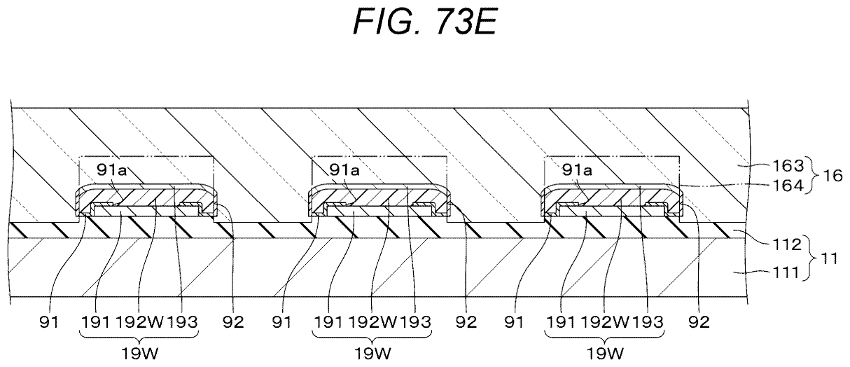

Hereinafter, a first example of the method for manufacturing the display device 109A according to the tenth embodiment will be described with reference to FIGS. 73A to 73E.

First, a metal layer (for example, an aluminum layer having a thickness of about 200 nm) is formed on the first surface of the drive substrate 11 using, for example, a sputtering method, and then the metal layer is patterned using, for example, photolithography and dry etching. As a result, the plurality of first electrodes 191 is formed on the first surface of the drive substrate 11.

Next, the insulating layer 91 (for example, a silicon oxide layer having a thickness of about 200 nm) is formed on the first surface of the drive substrate 11 using, for example, a CVD method to cover the plurality of first electrodes 191. Next, the plurality of openings 91a is formed in the insulating layer 91 using, for example, photolithography and dry etching. As a result, the first surface of each first electrode 191 is exposed through the corresponding opening 91a.

Next, the OLED layer 192W is formed on the first surfaces of the plurality of first electrodes 191 and the first surface of the insulating layer 91 using, for example, a vapor deposition method. At this time, the flat portion 192a of the first surface of the OLED layer 192W is formed corresponding to the first surface of the first electrode 191 exposed through the opening 91a of the insulating layer 91, and the convex portion 192b of the first surface of the OLED layer 192W is formed corresponding to the step formed by the side surface of the opening 91a of the insulating layer 91 and the step formed by the side surface of the first electrode 191.

Next, the second electrode 193 (for example, an IZO layer having a thickness of about 60 nm) is formed on the first surface of the OLED layer 192W using, for example, a sputtering method. At this time, the second electrode 193 is formed following the shape of the first surface of the OLED layer 192W, that is, the flat portion 192a and the convex portion 192b on the first surface of the OLED layer 192W. As a result, the flat portion 193a and the convex portion 193b are formed on the first surface of the second electrode 193. Furthermore, the thickness t₂ of the second electrode 193 at the inclined portion 193c becomes greater than the thickness t₁ of the second electrode 193 at the flat portion 193a.

Next, a first protective layer 163 (for example, a silicon nitride layer having a thickness of about 1 μm) is formed on the first surface of the second electrode 193 using, for example, a plasma CVD (PCVD) method. Next, as illustrated in FIG. 73A, an island-shaped resist layer 93 serving as a mask is formed at a position corresponding to each subpixel 10 using, for example, photolithography. At this time, as illustrated in FIG. 73B, the formation position of the island-shaped resist layer 93 is adjusted such that the edge of the island-shaped resist layer 93 is positioned above the inclined portion 193c.

Next, the first protective layer 163, the second electrode 193, and the OLED layer 192W, and the insulating layer 91 are sequentially processed through the resist layer 93 using, for example, dry etching. As a result, as illustrated in FIG. 73C, the plurality of light-emitting elements 19W is formed on the first surface of the drive substrate 11. During etching, as illustrated in FIG. 73D, the side surface of the light-emitting element 19W is side-etched to form the recess (side-etched portion) 195 thereon, and the constituent materials of the second electrode 193, the OLED layer 192W, and the insulating layer 91 are sputtered by ions and deposited on the side surface of the light-emitting element 19W to fill the recess 195.

The eaves-like overhanging portion 194 on the upper end of the side surface of the light-emitting element 19W is formed by the formation of the recess 195, and the residues deposited on the side surface of the light-emitting element 19W are shaded by the overhanging portion 194, which reduces the incidence of ions on the residues and makes the residues less prone to etching. It is therefore possible to increase the thickness of the side surface protective layer 92, which helps to prevent delamination between the OLED layer 192W and the second electrode 193.

As described above, since the formation position of the island-shaped resist layer 93 is adjusted such that the edge of the island-shaped resist layer 93 is positioned above the inclined portion 193c (see FIG. 73B), the second electrode 193 can be divided at the inclined portion 193c by etching. Since the thickness t₂ of the second electrode 193 at the inclined portion 193c is greater than the thickness t₁ of the second electrode 193 at the flat portion 193a (see FIG. 73D), the retraction of the peripheral edge portion of the second electrode 193 is suppressed to make the side surface of the light-emitting element 19W prone to side etching. Therefore, the recess 195 is easily formed on the side surface of the light-emitting element 19W. That is, the eaves-like overhanging portion 194 is easily formed in a uniform manner on the upper end of the side surface of the light-emitting element 19W.

Next, the resist layer 93 serving as a mask is removed from the first surface of the first protective layer 163 using, for example, ashing. Next, as illustrated in FIG. 73E, a second protective layer 164 (for example, a silicon nitride layer) is formed to cover each light-emitting element 19W provided with the first protective layer 163 using, for example, a PCVD method. As a result, the plurality of light-emitting elements 19W is covered by the protective layer 16 including the first protective layer 163 and the second protective layer 164. Thereafter, the first surface of the protective layer 16 may be polished for planarization using, for example, chemical mechanical polishing (CMP), as necessary.

Next, the protective layer 16 is processed using, for example, photolithography and dry etching to form the contact hole 161 on each light-emitting element 19W. Next, the common electrode 17 (for example, an IZO layer) is formed on the first surface of the protective layer 16 and in the contact hole 161 using, for example, a vapor deposition or sputtering method. Next, the protective layer 23 is formed on the first surface of the common electrode 17 using, for example, a PCVD method.

Next, a plurality of green filter portions 24FG, a plurality of red filter portions 24FR, and a plurality of blue filter portions 24FB are formed on the first surface of the protective layer 23 using, for example, photolithography. As a result, the color filter 24 is formed on the first surface of the protective layer 23. Through the above-described processes, the display device 109A is obtained.

### Second Example

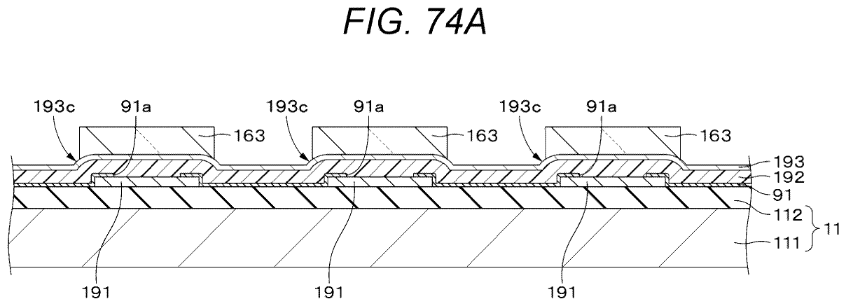

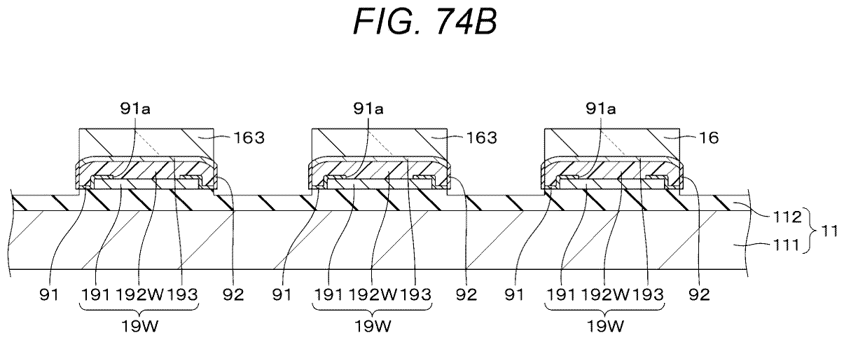

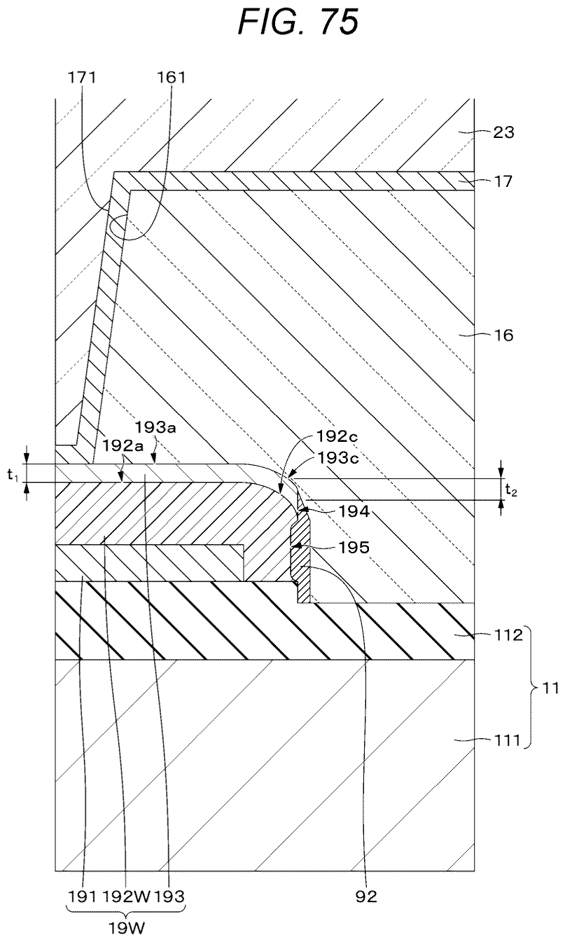

Hereinafter, a second example of the method for manufacturing the display device 109A according to the tenth embodiment will be described with reference to FIGS. 74A and 74B.

First, the process from the formation of the first electrode 191 to the formation of the resist layer 93 is performed in a similar manner as the first example of the method for manufacturing the display device 109A according to the third embodiment.

Next, the first protective layer 163 is processed through the resist layer 93 using, for example, dry etching, and then the resist layer 93 serving as a mask is removed from the first surface of the first protective layer 163 using, for example, ashing. As a result, as illustrated in FIG. 74A, an island-shaped first protective layer 163 is formed at a position corresponding to each subpixel 10. The formation position of the island-shaped resist layer 93 is adjusted such that the edge of the island-shaped first protective layer 163 is formed on the inclined portion 193c by etching.

Next, the second electrode 193, the OLED layer 192W, and the insulating layer 91 are sequentially processed using, for example, dry etching with the island-shaped first protective layer 163 serving as a mask. As a result, as illustrated in FIG. 74B, the plurality of light-emitting elements 19W is formed on the first surface of the drive substrate 11. Next, the process from the formation of the second protective layer 164 to the formation of the color filter 24 is performed in a similar manner as the first example of the method for manufacturing the display device 109A according to the third embodiment. Through the above-described processes, the display device 109A is obtained.

### Effects

In the display device 109A according to the tenth embodiment, the OLED layer 192W has the inclined portion 192c at the peripheral edge portion of the first surface adjacent to the second electrode 193, and the thickness t₂ of the second electrode 193 at the inclined portion 192c is greater than the thickness t₁ of the second electrode 193 at the flat portion 192a. This configuration suppresses, in the process of dividing the OLED layer 192W and the second electrode 193 by etching, the retraction of the peripheral edge portion of the second electrode 193 to make the side surface of the light-emitting element 19W prone to side etching, which makes it easier to form the overhanging portion 194 on the side surface of the light-emitting element 19W. When the overhanging portion 194 is formed on the side surface of the light-emitting element 19W, residues deposited on the side surface of the light-emitting element 19W are shaded by the overhanging portion 194 in the process of dividing the OLED layer 192W and the second electrode 193 by etching, which reduces the incidence of ions on the residues and makes the residues less prone to etching. It is therefore possible to increase the thickness of the side surface protective layer 92, which helps to prevent delamination between the OLED layer 192W and the second electrode 193. It is thus possible to prevent an increase in the drive voltage of the light-emitting element 19W.

In the first example and the second example of the method for manufacturing the display device 109A according to the tenth embodiment, the second electrode 193 is not divided at the flat portion 193a or the flat portion 193d (see FIG. 73B), but is divided at the inclined portion 193c. The thickness t₂ of the second electrode 193 at the inclined portion 193c is greater than the thickness t₁ of the second electrode 193 at the flat portion 193a and the flat portion 193d. Therefore, in a case where the second electrode 193 is divided at the inclined portion 193c, the retraction of the peripheral edge portion of the second electrode 193 is suppressed, and the side surface of the light-emitting element 19W becomes prone to side etching, as compared with a case where the second electrode 193 is divided at the flat portion 193a or the flat portion 193d. That is, the retraction of the OLED layer 192W in the in-plane direction becomes larger than that of the second electrode 193, and the amount of side etching increases accordingly. As a result, the eaves-like overhanging portion 194 is easily formed on the upper end of the side surface of the light-emitting element 19W. When the overhanging portion 194 is easily formed as described above, the side surface protective layer 92 tends to be formed thicker on the side surface of the light-emitting element 19W, which helps to reduce the impact of film stress of the protective layer 13 on the interface between the OLED layer 192W and the second electrode 193. It is therefore possible to prevent delamination between the OLED layer 192W and the second electrode 193. It is thus possible to prevent an increase in the drive voltage of the light-emitting element 19W.

### Modifications

### Modification 1

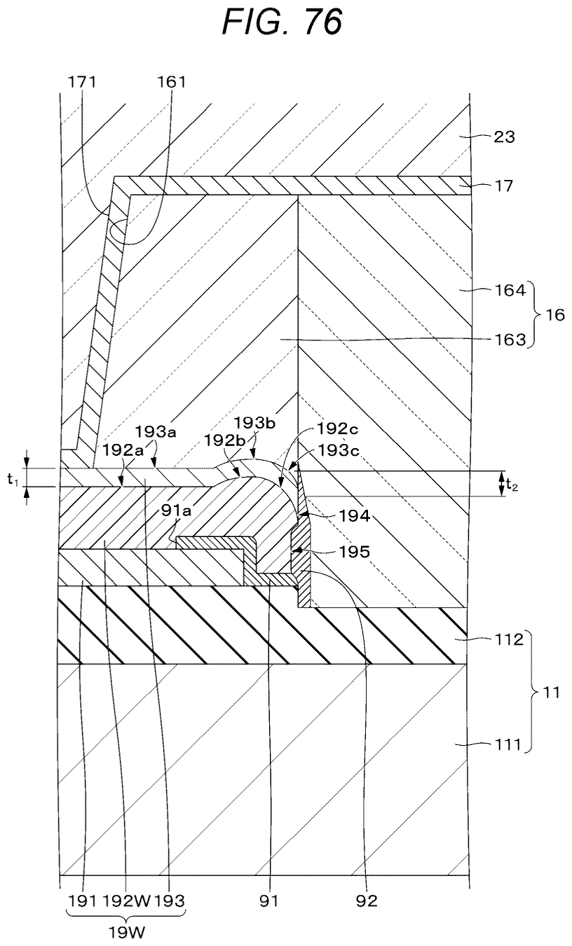

In the tenth embodiment, the example where the display device 109A includes the insulating layer 91 covering the peripheral edge portion of the first surface of the first electrode 191, the side surface of the first electrode 191, and the area around the first electrode 191 has been described (see FIG. 72). The insulating layer 91, however, is not an essential component, and the display device 109A need not necessarily include the insulating layer 91 as illustrated in FIG. 75. In this case, the OLED layer 192W may have the flat portion 192a and the inclined portion 192c on the first surface, and the second electrode 193 may have the flat portion 193a and the inclined portion 193c following the flat portion 192a and the inclined portion 192c, respectively, on the first surface. However, the shapes of the first surface of the OLED layer 192W and the first surface of the second electrode 193 are not limited to such examples, and as in the tenth embodiment, the OLED layer 192W may have the flat portion 192a and the convex portion 192b on the first surface, and the second electrode 193 may have the flat portion 193a and the convex portion 193b following the flat portion 192a and the convex portion 192b, respectively, on the first surface.

### Modification 2

In the tenth embodiment, the example where the upper end of the side surface protective layer 92 is provided at approximately the same position as the peripheral edge of the first surface of the light-emitting element 19W or at a position lower than the peripheral edge of the first surface of the light-emitting element 19W has been described. However, the position of the upper end of the side surface protective layer 92 is not limited to such an example, and may be provided at a position higher than the peripheral edge of the first surface of the light-emitting element 19W, for example, as illustrated in FIG. 76. In this case, the upper end portion of the side surface protective layer 92 may cover the lower end portion of the side surface of the first protective layer 163 provided on the first surface of the light-emitting element 19W.

### Modification 3

In the tenth embodiment, the example where the display device 109A includes the plurality of light-emitting elements 19W capable of emitting white light and the color filter 24, and a color image can be displayed by the combination of the light-emitting elements 19W and the color filter 24 has been described, but the colorization method of the display device 109A is not limited to such an example. For example, the display device 109A may include a plurality of light-emitting elements capable of emitting red light, a plurality of light-emitting elements capable of emitting green light, and a plurality of light-emitting elements capable of emitting blue light, instead of the plurality of light-emitting elements 19W. In this case, the color filter 24 may or may not be provided.

Examples of the light-emitting element capable of emitting light of each color include: (1) a light-emitting element including a light-emitting layer capable of emitting light of a predetermined color (red light, green light, or blue light); (2) a light-emitting element including a light-emitting layer capable of emitting white light, the light-emitting element being capable of enhancing light of a predetermined wavelength (red light, green light, or blue light) contained in the white light emitted by the light-emitting layer through resonation with a resonator structure; and (3) a light-emitting element including a light-emitting layer capable of emitting light of a predetermined color (red light, green light, or blue light), the light-emitting element being capable of enhancing light of a predetermined wavelength contained in the light of the predetermined color emitted by the light-emitting layer through resonation with a resonator structure.

### 10 Modifications

### Modification 1

In the third to tenth embodiments, the example where the side surface of the second electrode and the side surface of the protective layer provided on the second electrode are approximately flush with each other has been described, but the positional relationship between the side surface of the second electrode and the side surface of the protective layer provided on the second electrode is not limited to such an example. For example, in the third to ninth embodiments, the side surface of the protective layer provided on the second electrode may be located inside the side surface of the second electrode 123 in the in-plane direction as in the first or second embodiment. In this case, the effect of preventing delamination between the OLED layer and the second electrode can be further enhanced.

### Modification 2

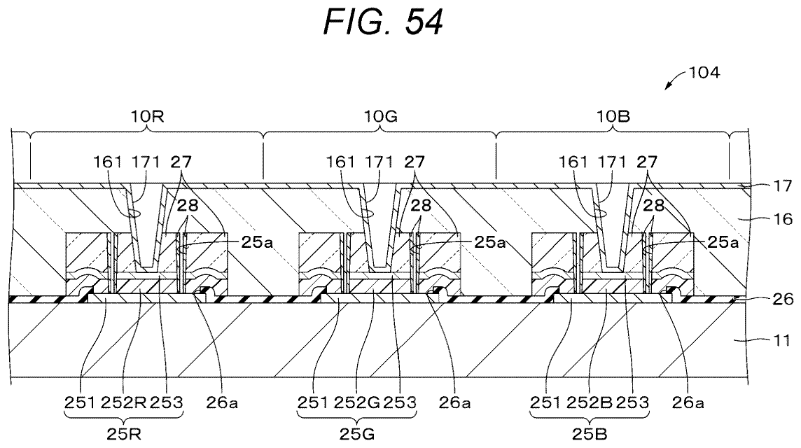

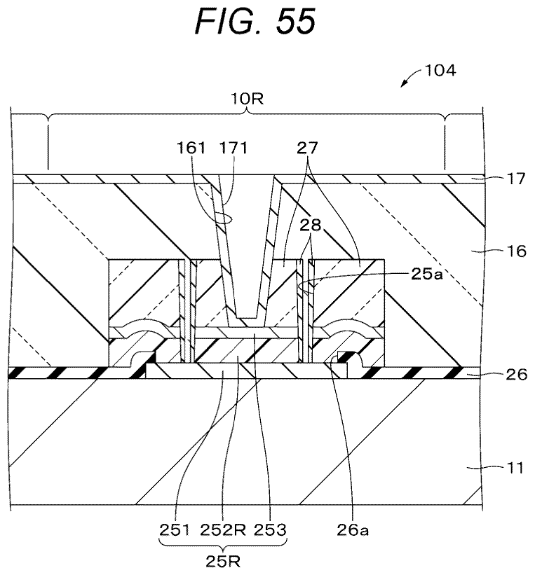

In the third embodiment, the example where the laminate including the OLED layer 252, the second electrode 253, and the protective layer 27 is provided on the first electrode 251 has been described (see FIG. 18). As illustrated in FIGS. 54 and 55, the laminate may be divided into two regions in the in-plane direction by a groove 25a. The groove 25a has a closed loop shape in plan view. A portion of the first surface of the second electrode 123 located inside the groove 25a is connected to the contact portion 171 of the common electrode 17. That is, the portion located inside the groove 25a serves as a light-emitting portion, and a portion located outside the groove 25a serves as a non-light-emitting portion.

In Modification 2, the side surface protective layer 28 may be provided on the side surface of the groove 25a instead of the side surface of the light-emitting element 25, or may be provided on both the side surface of the light-emitting element 25 and the side surface of the groove 25a. As illustrated in FIGS. 54 and 55, the side surface protective layer 28 may be provided on both the inner side surface and the outer side surface of the groove 25a, or may be provided only on the inner side surface of the groove 25a. Here, the inner side surface of the groove 25a refers to a side surface remote from the side surface of the light-emitting element 25 of the set of side surfaces defining the groove 25a, and the outer side surface of the groove 25a refers to a side surface adjacent to the side surface of the light-emitting element 25 of the set of side surfaces defining the groove 25a.

The example where the groove 25a is provided in the laminate in the third embodiment has been described above, but the groove may be provided in the laminate in the first, second, and fourth to ninth embodiments. In this case, the side surface protective layer may be provided on the side surface of the groove. In a case where the groove is provided in the laminate in the first and second embodiments, the inner side surface of the groove may have the same configuration as the side surface of the laminate in the first and second embodiments. That is, on the inner side surface of the groove, the side surface of the protective layer 13 may be located inside the side surface of the second electrode 123 in the in-plane direction.

### Modification 3

In the seventh embodiment, the display device 107 may include a plurality of side surface protective layers, and each side surface protective layer may cover the side surface of the light-emitting element 41G. The side surface protective layer may be any one of the side surface protective layers in the first to sixth and eighth embodiments. In this case, the effect of preventing delamination between the OLED layer 312R and the second electrode 313 can be further enhanced.

### Modification 4

In the first embodiment, the example where the side surface of the protective layer 13 is located inside the side surface of the second electrode 123 in the in-plane direction has been described, but the side surface of the protective layer 13 and the side surface of the second electrode 123 may be approximately flush with each other.

### Modification 5

In the first to ninth embodiments and the tenth embodiment, the example where the first electrode is an anode and the second electrode is a cathode has been described, but the first electrode may be a cathode, and the second electrode may be an anode.

### Other Modifications

Although the first to ninth embodiments and the tenth embodiment of the present disclosure and modifications thereof have been specifically described above, the present disclosure is not limited to the above-described first to ninth embodiments, tenth embodiment, and modifications thereof, and various modifications based on the technical idea of the present disclosure can be made.

For example, the configurations, methods, processes, shapes, materials, numerical values, and the like mentioned in the above-described first to ninth embodiments, tenth embodiment, and modifications thereof are merely examples, and different configurations, methods, processes, shapes, materials, numerical values, and the like may be used as necessary.

The configurations, methods, processes, shapes, materials, numerical values, and the like of the above-described first to ninth embodiments, tenth embodiment, and modifications thereof can be combined with each other without departing from the gist of the present disclosure.

The materials exemplified in the above-described first to ninth embodiments, tenth embodiment, and modifications thereof can be used alone or in combination of two or more unless otherwise specified.

The present disclosure may also employ the following configurations (1-1) to (1-20). Note that the following configurations (1-1) to (1-20) correspond to the first to eighth embodiments.

(1)

A light-emitting device including:
a plurality of light-emitting elements each including a first electrode, an organic-containing layer including an organic light-emitting layer, and a second electrode, the light-emitting elements being arranged two-dimensionally;
a protective layer provided on each of the light-emitting elements and separated between the light-emitting elements adjacent to each other; and
a side surface protective layer covering a side surface of each of the organic-containing layers, a side surface of each of the second electrodes, and a side surface of each of the protective layers, in which
the side surface of the protective layer is located inside the side surface of the second electrode.
   (2)

The light-emitting device according to (1), in which
the protective layer includes silicon nitride.
   (3)

The light-emitting device according to (1), in which
the protective layer includes a first protective layer and a second protective layer in sequence, and
the second protective layer is lower in etching rate than the first protective layer.
   (4)

The light-emitting device according to (1), in which
the protective layer includes a first protective layer and a second protective layer in sequence, and
the second protective layer includes a monolayer.
   (5)

The light-emitting device according to (1), in which
the protective layer includes a first protective layer and a second protective layer in sequence, the first protective layer including silicon nitride, the second protective layer including aluminum oxide.
   (6)

The light-emitting device according to (1), in which
the protective layer includes a first protective layer and a second protective layer in sequence, and
a side surface of the second protective layer is located outside a side surface of the first protective layer.
   (7)

The light-emitting device according to any one of (1) to (6), in which
the side surface protective layer includes a first side surface protective layer and a second side surface protective layer.
   (8)

The light-emitting device according to (7), in which
the second side surface protective layer includes at least one selected from the group consisting of zirconium oxide, tantalum oxide, and aluminum oxide.
   (9)

The light-emitting device according to (7) or (8), in which
the first side surface protective layer is lower in refractive index than the protective layer.
   (10)

The light-emitting device according to any one of (7) to (9), further including:
a first insulating layer provided between the first electrodes adjacent to each other; and
a second insulating layer provided on a peripheral edge portion of a surface of the first electrode adjacent to the organic-containing layer.
   (11)

The light-emitting device according to (10), in which
the first side surface protective layer includes a material identical to a material of the second insulating layer, and
the second side surface protective layer includes a material identical to a material of the first insulating layer.
   (12)

The light-emitting device according to any one of (1) to (6), in which
the side surface protective layer includes a monolayer.
   (13)

The light-emitting device according to any one of (1) to (6), in which
the side surface protective layer is capable of reflecting light emitted from each of the light-emitting elements.
   (14)

The light-emitting device according to (13), in which
the side surface protective layer includes
a first side surface protective layer having conductivity, a second side surface protective layer having insulating properties, and a third side surface protective layer having conductivity in sequence.
   (15)

The light-emitting device according to any one of (1) to (14), further including
a third protective layer that fills a space between the light-emitting elements adjacent to each other, in which
at least one first step is provided around each of the light-emitting elements.
   (16)

The light-emitting device according to (15), in which
each of the first steps is provided on the first electrode.
   (17)

The light-emitting device according to (16), further including
an underlayer provided under each of the light-emitting elements, in which
the underlayer includes at least one second step around each of the light-emitting elements, and
the first electrode is provided along each of the second steps.
   (18)

The light-emitting device according to (1), in which
a laminate includes each of the light-emitting elements and the protective layer,
the laminates adjacent to each other are separated by two or more different separation widths,
the protective layer includes a first protective layer and a second protective layer provided on the first protective layer,
the first protective layer is separated between the laminates adjacent to each other, and
the second protective layer is connected in a specified direction between the laminates adjacent to each other.
   (19)

The light-emitting device according to (18), further including
a third protective layer covering the plurality of laminates, in which
a groove is provided between the laminates adjacent to each other, and
the second protective layer and the third protective layer are provided along the groove.
   (20)

Electronic equipment including the light-emitting device according to claim 1.

The present disclosure may also employ the following configurations (3-1) to (3-7). Note that the following configurations (3-1) to (3-7) correspond to the third embodiment.

(3-1)

A light-emitting device including:
a plurality of light-emitting elements each including a first electrode, an organic-containing layer including an organic light-emitting layer, and a second electrode, the light-emitting elements being arranged two-dimensionally;
a protective layer provided on each of the light-emitting elements and separated between the light-emitting elements adjacent to each other; and
a side surface protective layer covering a side surface of each of the organic-containing layers, a side surface of each of the second electrodes, and a side surface of each of the protective layers, in which
the side surface protective layer includes a first side surface protective layer and a second side surface protective layer.
   (3-2)

The light-emitting device according to (3-1), in which
the second electrode includes transparent conductive oxide.
   (3-3)

The light-emitting device according to (3-1) or (3-2), in which
the second side surface protective layer includes at least one selected from the group consisting of zirconium oxide, tantalum oxide, and aluminum oxide.
   (3-4)

The light-emitting device according to any one of (3-1) to (3-3), in which the first side surface protective layer is lower in refractive index than the protective layer.

(3-5)

The light-emitting device according to any one of (3-1) to (3-4), further including:
a first insulating layer provided between the first electrodes adjacent to each other; and
a second insulating layer provided on a peripheral edge portion of a surface of the first electrode adjacent to the organic-containing layer.
   (3-6)

The light-emitting device according to (3-5), in which
the first side surface protective layer includes some or all of constituent materials of the second insulating layer, and
the second side surface protective layer includes some or all of constituent materials of the first insulating layer.
   (3-7)

A method for manufacturing a light-emitting device, the method including
forming a plurality of first electrodes two-dimensionally arranged on a drive substrate;
laminating a first insulating layer and a second insulating layer in a region between the first electrodes adjacent to each other;
laminating an organic-containing layer including an organic light-emitting layer, a second electrode, and a protective layer on the first electrodes and the second insulating layer;
removing the protective layer, the second electrode, and the organic-containing layer in the region between the first electrodes adjacent to each other; and
sequentially sputter etching the second insulating layer and the first insulating layer in the region between the first electrodes adjacent to each other to sequentially form a first side surface protective layer and a second side surface protective layer on a side surface of the organic-containing layer, a side surface of the second electrode, and a side surface of the protective layer.

The present disclosure may also employ the following configurations (4-1) and (4-2). Note that the following configurations (4-1) and (4-2) correspond to the fourth embodiment.

(4-1)

A light-emitting device including:
a plurality of light-emitting elements each including a first electrode, an organic-containing layer including an organic light-emitting layer, and a second electrode, the light-emitting elements being arranged two-dimensionally;
a protective layer provided on each of the light-emitting elements and separated between the light-emitting elements adjacent to each other; and
a side surface protective layer covering a side surface of the organic-containing layer, a side surface of the second electrode, and a side surface of the protective layer of each of the light-emitting elements, in which
the side surface protective layer includes a monolayer.
   (4-2)

The light-emitting device according to (4-1), in which
the monolayer includes an ALD layer.

The present disclosure may also employ the following configurations (5-1) to (5-6). Note that the following configurations (5-1) to (5-6) correspond to the fifth and sixth embodiments.

(5-1)

A light-emitting device including:
a plurality of light-emitting elements each including a first electrode, an organic-containing layer including an organic light-emitting layer, and a second electrode, the light-emitting elements being arranged two-dimensionally;
a protective layer provided on each of the light-emitting elements and separated between the light-emitting elements adjacent to each other; and
a side surface protective layer covering a side surface of each of the organic-containing layers, a side surface of each of the second electrodes, and a side surface of each of the protective layers, in which
the side surface protective layer is capable of reflecting light emitted from each of the light-emitting elements.
   (5-2)

The light-emitting device according to (5-1), in which
the side surface protective layer includes at least one reflective layer.
   (5-3)

The light-emitting device according to (5-1), in which
each of the light-emitting elements further includes an insulating layer, and
the insulating layer is provided on a peripheral edge portion of a surface of the first electrode adjacent to the organic-containing layer.
   (5-4)

The light-emitting device according to (5-1) or (5-3), in which
the side surface protective layer includes a first side surface protective layer having conductivity, a second side surface protective layer having insulating properties, and a third side surface protective layer having conductivity in sequence,
the first side surface protective layer is connected to the second electrode, and
the third side surface protective layer is connected to the first electrode.
   (5-5)

The light-emitting device according to (5-1) or (5-3), further including a metal layer provided under each of the light-emitting elements.

(5-6)

The light-emitting device according to (5-1) or (5-5), in which
the side surface protective layer includes the first side surface protective layer having conductivity, a second side surface protective layer having insulating properties, a third side surface protective layer capable of reflecting light emitted from the light-emitting element, and a fourth side surface protective layer capable of reflecting light emitted from the light-emitting element.
   (5-7)

A method for manufacturing a light-emitting device, the method including:
sequentially forming a metal layer, a first electrode, an insulating layer, an organic-containing layer including an organic light-emitting layer, a second electrode, and a protective layer on a drive substrate; and
sequentially etching the protective layer, the second electrode, the organic-containing layer, the insulating layer, the first electrode, and the metal layer to deposit residues on a side surface of the first electrode, a side surface of the organic-containing layer, a side surface of the second electrode, and a side surface of the protective layer.

The present disclosure may also employ the following configurations (7-1) to (7-7). Note that the following configurations (7-1) to (7-7) correspond to the seventh embodiment.

(7-1)

A light-emitting device including:
a plurality of light-emitting elements arranged two-dimensionally; and
a protective layer filling a space between the light-emitting elements adjacent to each other, in which
at least one first step is provided around each of the light-emitting elements.
   (7-2)

The light-emitting device according to (7-1), in which
each of the light-emitting elements includes a first electrode, an organic-containing layer including an organic light-emitting layer, and a second electrode in sequence.
   (7-3)

The light-emitting device according to (7-2), in which
each of the first steps is provided on the first electrode.
   (7-4)

The light-emitting device according to (7-2) or (7-3), in which
the first electrode is connected between the light-emitting elements adjacent to each other.
   (7-5)

The light-emitting device according to (7-2), in which
each of the first steps is provided on the organic-containing layer.
   (7-6)

The light-emitting device according to (7-2), further including
an underlayer provided under each of the light-emitting elements, in which
each of the first steps is provided on the first electrode and the underlayer.
   (7-7)

The light-emitting device according to (7-2), further including
an underlayer provided under each of the light-emitting elements, in which
the underlayer includes at least one second step around each of the light-emitting elements, and
the first electrode is provided along each of the second steps.

The present disclosure may also employ the following configurations (8-1) to (8-13). Note that the following configurations (8-1) to (8-13) correspond to the eighth embodiment.

(8-1)

A light-emitting device including
a plurality of laminates arranged two-dimensionally, in which
each of the laminates includes a light-emitting element, and
a protective layer provided on the light-emitting element,
the light-emitting element includes a first electrode, an OLED layer, and a second electrode, and
the laminates adjacent to each other are separated by two or more different separation widths.
   (8-2)

The light-emitting device according to (8-1), in which
the protective layer includes a first protective layer and a second protective layer provided on the first protective layer,
the first protective layer is separated between the laminates adjacent to each other, and
the second protective layer is connected in a specified direction between the laminates adjacent to each other.
   (8-3)

The light-emitting device according to (8-1), in which
each of the laminates includes a first protective layer and a second protective layer provided on the first protective layer,
the plurality of laminates is arranged in a first direction and a second direction,
the second protective layer is separated between the laminates in the first direction and is separated between the laminates in the second direction, and the second protective layer is connected between the laminates in a third direction between the first direction and the second direction.
   (8-4)

The light-emitting device according to (8-2) or (8-3), in which
the laminates adjacent in the first direction are separated by at least a first separation width and a second separation width,
the second separation width is a separation width at both ends of a region between the laminates adjacent in the first direction,
the first separation width is a separation width between both the ends,
the laminates adjacent in the second direction are separated by at least a third separation width and a fourth separation width,
the fourth separation width is a separation width at both ends of a region between the laminates adjacent in the second direction, and
the third separation width is a separation width between both the ends.
   (8-5)

The light-emitting device according to any one of (8-2) to (8-4), in which
the second protective layer covers a part of a side surface of each of the laminates.
   (8-6)

The light-emitting device according to any one of (8-2) to (8-5), in which
a groove is provided between the laminates adjacent to each other, and
the second protective layer is provided along the groove.
   (8-7)

The light-emitting device according to (8-6), further including a third protective layer covering the plurality of laminates, in which
the third protective layer is provided along the groove.
   (8-8)

The light-emitting device according to (8-7), in which
the third protective layer is connected between the laminates in a first direction, between the laminates in a second direction, and between the laminates in a third direction.
   (8-9)

The light-emitting device according to (8-7) or (8-8), in which
materials of the second protective layer and the third protective layer are different from each other.
   (8-10)

The light-emitting device according to (8-1), in which
the plurality of laminates is arranged in a first direction and a second direction, and
a thickness of the protective layer located between the laminates in the first direction and a thickness of the protective layer located between the laminates in the second direction are different from a thickness of the protective layer between the laminates in a third direction between the first direction and the second direction.
   (8-11)

The light-emitting device according to (8-1), in which
the plurality of laminates is arranged in a first direction and a second direction, and
the number of the protective layers located between the laminates in the first direction and the number of the protective layers located between the laminates in the second direction are different from the number of the protective layers between the laminates in a third direction between the first direction and the second direction.
   (8-12)

The light-emitting device according to (8-1), further including
an underlayer provided under the plurality of laminates, in which
the plurality of laminates is arranged in a first direction and a second direction, and
the underlayer has a step on a surface on which the plurality of laminates is provided, and the step is provided at both ends of a region between the laminates adjacent to each other.
   (8-13)

A method for manufacturing a light-emitting device, the method including:
forming a plurality of first electrodes arranged two-dimensionally in a first direction and a second direction;
forming a laminate by sequentially forming an OLED layer, a second electrode, and a first protective layer to cover the first electrodes;
forming a plurality of recesses in the laminate by processing a plurality of third regions of the laminate;
forming a second protective layer covering the laminate in which the plurality of recesses is formed; and
dividing the laminate by processing a plurality of first regions and a plurality of second regions of the laminate, in which
the first region is a region between the first electrodes in the first direction,
the second region is a region between the first electrodes in the second direction, and
the third region is a region between the first electrodes in a third direction between the first direction and the second direction.

The present disclosure may also employ the following configurations (9-1) to (9-4). Note that the following configurations (9-1) to (9-4) correspond to the tenth embodiment.

(9-1)

A light-emitting device including:
a plurality of light-emitting elements each including a first electrode, an organic-containing layer including an organic light-emitting layer, and a second electrode, the light-emitting elements being arranged two-dimensionally; and
a side surface protective layer provided on a side surface of each of the light-emitting elements, in which
the organic-containing layer includes a flat portion and an inclined portion on a surface adjacent to the second electrode, the inclined portion being provided adjacent to a side surface of the organic-containing layer, and
the second electrode is provided along the flat portion and the inclined portion, the second electrode located at the inclined portion being thicker than the second electrode located at the flat portion.
   (9-2)

The light-emitting device according to (9-1), in which
each of light-emitting elements includes an overhanging portion on an upper end of the side surface of the light-emitting element.
   (9-3)

The light-emitting device according to (9-1) or (9-2), in which
the side surface protective layer covers a boundary between the organic-containing layer and the second electrode.
   (9-4)

The light-emitting device according to any one of (9-1) to (9-3), further including
a protective layer provided on the plurality of light-emitting elements and separated between the light-emitting elements adjacent to each other, in which
the side surface protective layer covers both the side surface of each of the light-emitting elements and a side surface of the protective layer.
   (9-5)

A method for manufacturing a light-emitting device, the method including:
forming a plurality of first electrodes arranged two-dimensionally;
forming an organic-containing layer including an organic light-emitting layer, the organic-containing layer including, on a surface, a plurality of first inclined portions corresponding to edges of the plurality of first electrodes;
forming a plurality of second inclined portions corresponding to the plurality of first inclined portions on a surface of a second electrode by forming the second electrode on the organic-containing layer along a surface shape of the organic-containing layer; and
dividing the second electrode and the organic-containing layer at a position of each of the second inclined portions.

### 10 Relationship Among Normal Lines Passing Through Centers of Light-Emitting Unit, Lens Member, and Wavelength Selection Unit

Hereinafter, a relationship among a normal line LN passing through a center of a light-emitting unit, a normal line LN′ passing through a center of a lens member, and a normal line LN″ passing through a center of a wavelength selection unit will be described. Here, the light-emitting unit is, for example, the light-emitting element 18W in the ninth embodiment. The lens member is, for example, the lens 551 of the lens array 55 in the ninth embodiment. The wavelength selection unit is, for example, the filter portion 24F in the ninth embodiment. Here, an example where the following configuration is applied to the display device 109 according to the ninth embodiment will be described, but the following configuration may be applied to the display devices 101, 102, 104 to 108, and 109A according to the modifications of the ninth embodiment.

Note that the size of the wavelength selection unit may be changed as appropriate in accordance with light emitted from the light-emitting unit, or, in a case where a light-absorbing unit (for example, a black matrix unit) is provided between the wavelength selection units of the adjacent light-emitting units, the size of the light-absorbing unit may be changed as appropriate in accordance with light emitted from the light-emitting unit. Furthermore, the size of the wavelength selection unit may be changed as appropriate in accordance with a distance (offset amount) do between the normal line passing through the center of the light-emitting unit and the normal line passing through the center of the wavelength selection unit. The planar shape of the wavelength selection unit may be the same as, similar to, or different from the planar shape of the lens member.

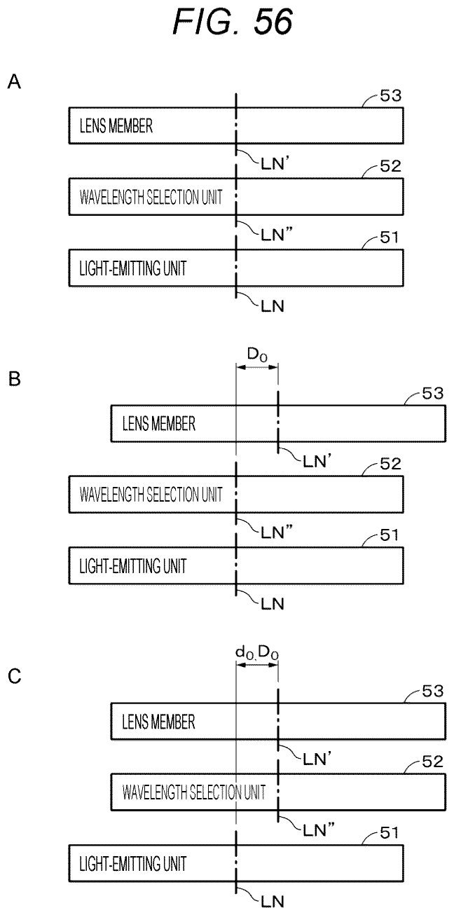

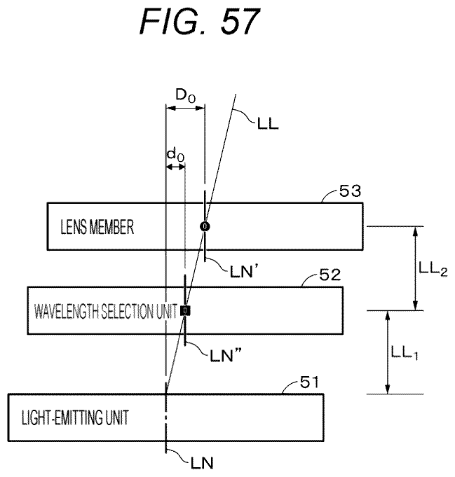

Hereinafter, with reference to FIGS. 56A, 56B, 56C, and 57, a relationship among the normal lines each passing through the center of the corresponding unit in a case where a light-emitting unit 51, a wavelength selection unit 52, and a lens member 53 are arranged in this order will be described.

As illustrated in FIG. 56A, the normal line LN passing through the center of the light-emitting unit 51, the normal line LN″ passing through the center of the wavelength selection unit 52, and the normal line LN′ passing through the center of the lens member 53 may coincide with each other. That is, D₀=0 and d₀=0 may be satisfied. Here, D₀ represents the distance (offset amount) between the normal line LN passing through the center of the light-emitting unit 51 and the normal line LN′ passing through the center of the lens member 53, and do represents the distance (offset amount) between the normal line LN passing through the center of the light-emitting unit 51 and the normal line LN″ passing through the center of the wavelength selection unit 52.

As illustrated in FIG. 56B, the normal line LN passing through the center of the light-emitting unit 51 and the normal line LN″ passing through the center of the wavelength selection unit 52 may coincide with each other, but the normal line LN passing through the center of the light-emitting unit 51 and the normal line LN″ passing through the center of the wavelength selection unit 52 need not coincide with the normal line LN′ passing through the center of the lens member 53. That is, D₀>0 and d₀=0 may be satisfied.

As illustrated in FIG. 56C, the normal line LN passing through the center of the light-emitting unit 51 need not coincide with the normal line LN″ passing through the center of the wavelength selection unit 52 and the normal line LN′ passing through the center of the lens member 53, and the normal line LN″ passing through the center of the wavelength selection unit 52 may coincide with the normal line LN′ passing through the center of the lens member 53. That is, D₀>0, d₀>0, and D₀=d₀ may be satisfied.

As illustrated in FIG. 57, the normal line LN passing through the center of the light-emitting unit 51, the normal line LN″ passing through the center of the wavelength selection unit 52, and the normal line LN′ passing through the center of the lens member 53 need not coincide with each other. That is, D₀>0, d₀>0, and D₀≠d₀ may be satisfied. Here, the center of the wavelength selection unit 52 (the position indicated by a black square in FIG. 57) is preferably located on a straight line LL connecting the center of the light-emitting unit 51 and the center of the lens member 53 (the position indicated by a black circle in FIG. 57). Specifically, assuming that the distance in the thickness direction (vertical direction in FIG. 57) between the center of the light-emitting unit 51 and the center of the wavelength selection unit 52 is denoted as LL₁, and that the distance in the thickness direction between the center of the wavelength selection unit 52 and the center of the lens member 53 is denoted as LL₂, it is preferable that

$${D}_{0} > {d}_{0} > 0$$

be satisfied, and with manufacturing variations being taken into consideration,

$${d}_{0} : {D}_{0} = {LL}_{1} : ( {LL}_{1} + {LL}_{2} )$$

be satisfied.

Here, the thickness direction indicates the thickness direction of the light-emitting unit 51, the wavelength selection unit 52, and the lens member 53.

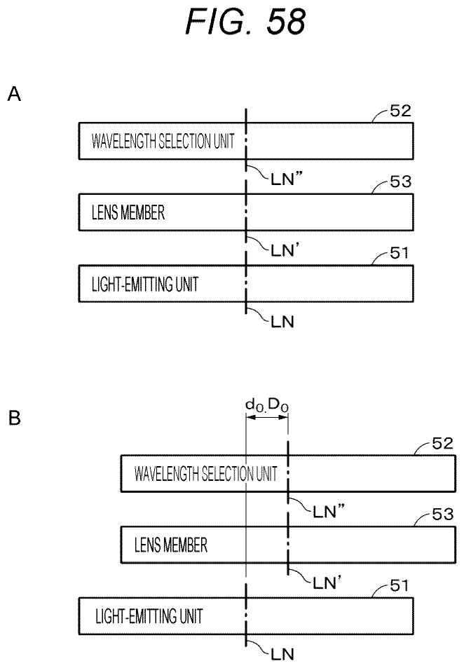

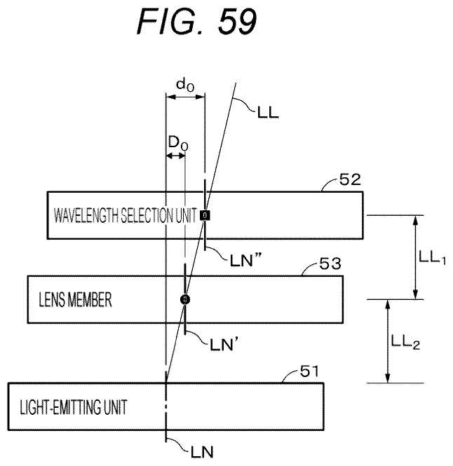

Hereinafter, with reference to FIGS. 58A, 58B, and 59, a relationship among the normal lines each passing through the center of the corresponding unit in a case where the light-emitting unit 51, the lens member 53, and the wavelength selection unit 52 are arranged in this order will be described.

As illustrated in FIG. 58A, the normal line LN passing through the center of the light-emitting unit 51, the normal line LN″ passing through the center of the wavelength selection unit 52, and the normal line LN′ passing through the center of the lens member 53 may coincide with each other. That is, D₀>0 and d₀=0 may be satisfied.

As illustrated in FIG. 58B, the normal line LN passing through the center of the light-emitting unit 51 need not coincide with the normal line LN″ passing through the center of the wavelength selection unit 52 and the normal line LN′ passing through the center of the lens member 53, and the normal line LN″ passing through the center of the wavelength selection unit 52 may coincide with the normal line LN′ passing through the center of the lens member 53. That is, D₀>0, d₀>0, and D₀=d₀ may be satisfied.

As illustrated in FIG. 59, the normal line LN passing through the center of the light-emitting unit 51, the normal line LN″ passing through the center of the wavelength selection unit 52, and the normal line LN′ passing through the center of the lens member 53 need not coincide with each other. Here, the center of the lens member 53 (the position indicated by a black circle in FIG. 59) is preferably located on a straight line LL connecting the center of the light-emitting unit 51 and the center of the wavelength selection unit 52 (the position indicated by a black square in FIG. 59). Specifically, assuming that the distance in the thickness direction (vertical direction in FIG. 59) between the center of the light-emitting unit 51 and the center of the lens member 53 is denoted as LL₂, and that the distance in the thickness direction between the center of the lens member 53 and the center of the wavelength selection unit 52 is denoted as LL₁, it is preferable that

$${d}_{0} > {D}_{0} > 0$$

be satisfied, and, with manufacturing variations being taken into consideration,

$${D}_{0} : {d}_{0} = {LL}_{2} : ( {LL}_{1} + {LL}_{2} )$$

be satisfied.

Here, the thickness direction indicates the thickness direction of the light-emitting unit 51, the wavelength selection unit 52, and the lens member 53.

### 11 Example of Resonator Structure

The pixel used in the above-described display device according to the present disclosure may have a configuration including a resonator structure that resonates light generated by the light-emitting element. Hereinafter, the resonator structure will be described with reference to the drawings. Furthermore, in the following description, the first surface of each layer may be referred to as upper surface.

### (Resonator Structure: First Example)

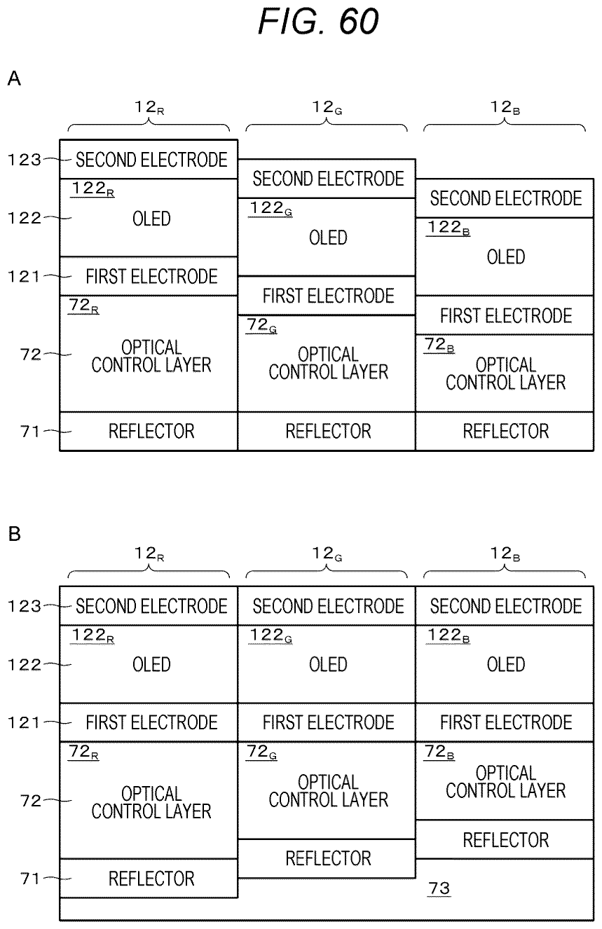

FIG. 60A is a schematic cross-sectional view for describing a first example of the resonator structure. Note that, in the following description, the light-emitting elements provided corresponding to the subpixels 10R, 10G, and 10B may be collectively referred to as light-emitting element 12 unless otherwise distinguished. The light-emitting elements provided corresponding to the subpixels 10R, 10G, and 10B may be referred to as light-emitting elements 12R, 12G, and 12B, respectively. Portions of the OLED layer 122 corresponding to the subpixels 10R, 10G, and 10B may be referred to OLED layer 122R, OLED layer 122G, and OLED layer 122B, respectively. The light-emitting element may be any one of the light-emitting elements in the first to ninth embodiments and the tenth embodiment.

In the first example, the first electrode 121 is formed with a uniform film thickness across the light-emitting elements 12. This similarly applies to the second electrode 123.

A reflector 71 is arranged below the first electrode 121 of the light-emitting element 12 with an optical control layer 72 interposed therebetween. A resonator structure that causes resonance of light generated by the OLED layer 122 is formed between the reflector 71 and the second electrode 123. In the following description, the optical control layers 72 provided corresponding to the subpixels 10R, 10G, and 10B may be referred to as optical control layers 72_{R}, 72_{G}, and 72_{B}, respectively.

The reflector 71 is formed with a uniform film thickness across the light-emitting elements 12. The film thickness of the optical control layer 72 varies in a manner that depends on a color to be displayed by the pixel. Since the optical control layers 72_{R}, 72_{G}, and 72_{B} have different film thicknesses, it is possible to set an optical distance that causes optimum resonance for a wavelength of light corresponding to the color to be displayed.

In the example illustrated in FIG. 60A, the reflectors 71 are arranged to make their respective upper surfaces flush with each other across the light-emitting elements 12_{R}, 12_{G}, and 12_{B}. As described above, since the film thickness of the optical control layer 72 varies in a manner that depends on the color to be displayed by the pixel, the position of the upper surface of the second electrode 123 varies in a manner that depends on the types of the light-emitting elements 12R, 12G, and 12B.

The reflector 71 can include a metal such as aluminum (Al), silver (Ag), or copper (Cu), or an alloy containing these as principal components, for example.

The optical control layer 72 can include an inorganic insulating material such as silicon nitride (SiNₓ), silicon oxide (SiOₓ), or silicon oxynitride (SiOₓN_{y}), or an organic resin material such as acrylic resin or polyimide resin. The optical control layer 72 may be a single layer, or may be a multilayer film including the plurality of materials. Furthermore, the number of layers may vary in a manner that depends on the type of the light-emitting element 12.

The first electrode 121 can include a transparent conductive material such as indium tin oxide (ITO), indium zinc oxide (IZO), or zinc oxide (ZnO).

The second electrode 123 needs to function as a semi-transparent reflective film. The second electrode 123 can include magnesium (Mg), silver (Ag), a magnesium-silver alloy (MgAg) containing these materials as principal components, an alloy containing an alkali metal or an alkaline earth metal, or the like.

### Resonator Structure: Second Example

FIG. 60B is a schematic cross-sectional view for describing a second example of the resonator structure.

In the second example as well, the first electrode 121 and the second electrode 123 are each formed with a uniform film thickness across the light-emitting elements 12.

In addition, in the second example as well, the reflector 71 is arranged below the first electrode 121 of the light-emitting element 12 with the optical control layer 72 interposed therebetween. A resonator structure that causes resonance of light generated by the OLED layer 122 is formed between the reflector 71 and the second electrode 123. Similarly to the first example, the reflector 71 is formed with a uniform film thickness across the light-emitting elements 12, and the film thickness of the optical control layer 72 varies in a manner that depends on the color to be displayed by the pixel.

In the first example illustrated in FIG. 60A, the reflectors 71 are arranged to make their respective upper surfaces flush with each other across the light-emitting elements 12_{R}, 12_{G}, and 12_{B}, and the position of the upper surface of the second electrode 123 varies in a manner that depends on the types of the light-emitting elements 12_{R}, 12_{G}, and 12_{B}.

On the other hand, in the second example illustrated in FIG. 60B, the second electrodes 123 are arranged to make their respective upper surfaces flush with each other across the light-emitting elements 12_{R}, 12_{G}, and 12_{B}. In order to make the upper surfaces of the second electrodes 123 flush with each other, in the light-emitting elements 12_{R}, 12_{G}, and 12_{B}, the reflectors 71 are arranged such that the positions of their respective upper surfaces vary in a manner that depends on the types of the light-emitting elements 12_{R}, 12_{G}, and 12_{B}. Therefore, the lower surfaces of the reflectors 71 (in other words, the upper surfaces of the underlayers (insulating layers) 73) form a stair shape according to the types of the light-emitting elements 12.

Materials and the like constituting the reflector 71, the optical control layer 72, the first electrode 121, and the second electrode 123 are similar to those described in the first example, and thus, the description thereof will be omitted.

### Resonator Structure: Third Example

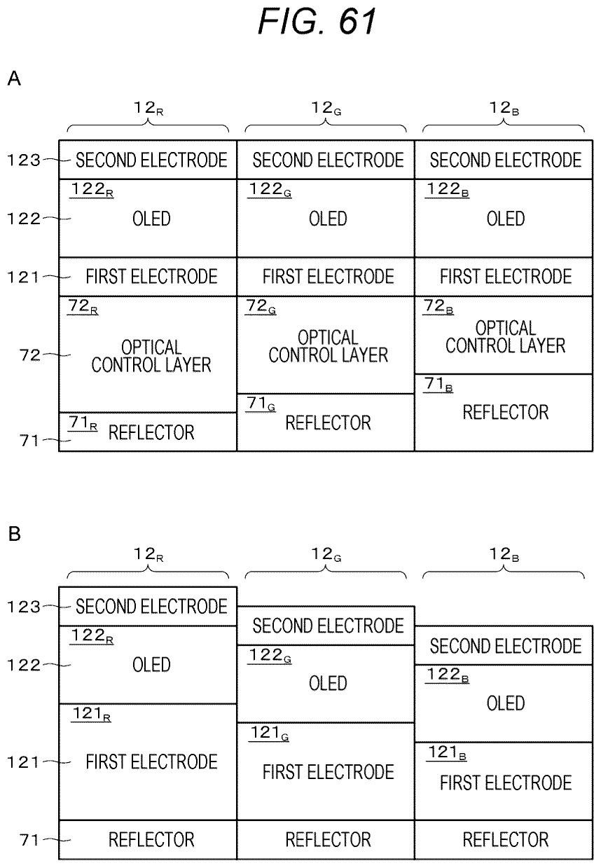

FIG. 61A is a schematic cross-sectional view for describing a third example of the resonator structure. In the following description, the reflectors 71 provided corresponding to the subpixels 10R, 10G, and 10B may be referred to as reflectors 71R, 71G, and 71B, respectively.

In the third example as well, the first electrode 121 and the second electrode 123 are each formed with a uniform film thickness across the light-emitting elements 12.

In addition, in the third example as well, the reflector 71 is arranged below the first electrode 121 of the light-emitting element 12 with the optical control layer 72 interposed therebetween. A resonator structure that causes resonance of light generated by the OLED layer 122 is formed between the reflector 71 and the second electrode 123. Similarly to the first and the second examples, the film thickness of the optical control layer 72 varies in a manner that depends on the color to be displayed by the pixel. In addition, similarly to the second example, the second electrodes 123 are arranged to make their respective upper surfaces flush with each other across the light-emitting elements 12_{R}, 12_{G}, and 12_{B}.

In the second example illustrated in FIG. 60B, to make the upper surfaces of the second electrodes 123 flush with each other, the lower surfaces of the reflectors 71 form a stair shape according to the types of the light-emitting elements 12.

On the other hand, in the third example illustrated in FIG. 61A, the film thickness of the reflector 71 is set to vary in a manner that depends on the types of the light-emitting elements 12_{R}, 12_{G}, and 12_{B}. More specifically, the film thickness is set such that the lower surfaces of the reflectors 71R, 71G, and 71B are flush with each other.

Materials and the like constituting the reflector 71, the optical control layer 72, the first electrode 121, and the second electrode 123 are similar to those described in the first example, and thus, the description thereof will be omitted.

### Resonator Structure: Fourth Example

FIG. 61B is a schematic cross-sectional view for describing a fourth example of the resonator structure. In the following description, the first electrodes 121 provided corresponding to the subpixels 10R, 10G, and 10B will be referred to as first electrodes 121R, 121G, and 121B, respectively.

In the first example illustrated in FIG. 60A, the first electrode 121 and the second electrode 123 of each light-emitting element 12 are formed with a uniform film thickness. In addition, the reflector 71 is arranged below the first electrode 121 of the light-emitting element 12 with the optical control layer 72 interposed therebetween.

On the other hand, in the fourth example illustrated in FIG. 61B, the optical control layer 72 is omitted, and the film thickness of the first electrode 121 is set to vary in a manner that depends on the types of the light-emitting elements 12_{R}, 12_{G}, and 12_{B}.

The reflector 71 is formed with a uniform film thickness across the light-emitting elements 12. The film thickness of the first electrode 121 varies in a manner that depends on the color to be displayed by the pixel. Since the first electrodes 121R, 121G, and 121B have different film thicknesses, it is possible to set an optical distance that causes optimum resonance for a wavelength of light according to the color to be displayed.

Materials and the like constituting the reflector 71, the optical control layer 72, the first electrode 121, and the second electrode 123 are similar to those described in the first example, and thus, the description thereof will be omitted.

### Resonator Structure: Fifth Example

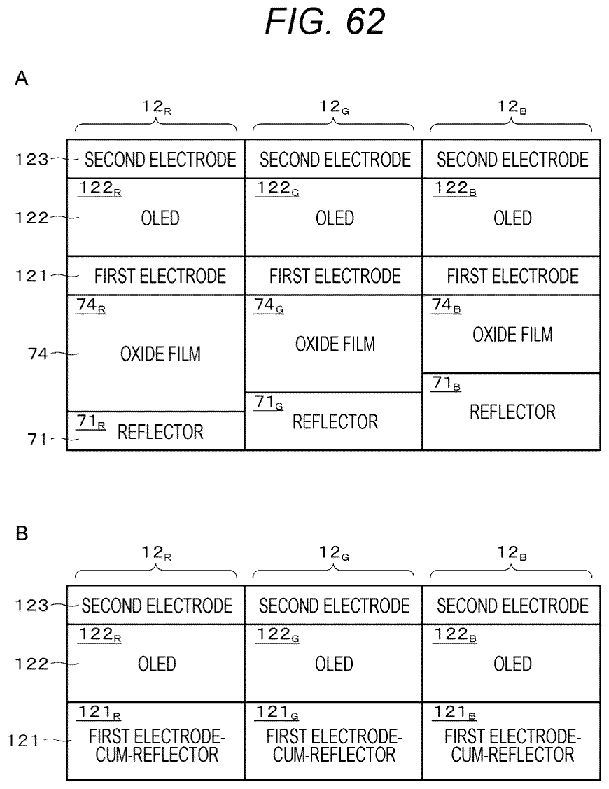

FIG. 62A is a schematic cross-sectional view for describing a fifth example of the resonator structure.

In the first example illustrated in FIG. 60A, the first electrode 121 and the second electrode 123 are each formed with a uniform film thickness across the light-emitting elements 12. In addition, the reflector 71 is arranged below the first electrode 121 of the light-emitting element 12 with the optical control layer 72 interposed therebetween.

On the other hand, in the fifth example illustrated in FIG. 62A, the optical control layer 72 is omitted, and instead, an oxide film 74 is formed on the reflector 71. The film thickness of the oxide film 74 is set to vary in a manner that depends on the types of the light-emitting elements 12_{R}, 12_{G}, and 12_{B}. In the following description, the oxide films 74 provided corresponding to the subpixels 10R, 10G, and 10B are referred to as oxide films 74R, 74G, and 74B, respectively.

The film thickness of the oxide film 74 varies in a manner that depends on the color to be displayed by the pixel. Since the oxide films 74R, 74G, and 74B have different film thicknesses, it is possible to set an optical distance that causes optimum resonance for a wavelength of light according to the color to be displayed.

The oxide film 74 is a film obtained by oxidizing the surface of the reflector 71, and includes, for example, aluminum oxide, tantalum oxide, titanium oxide, magnesium oxide, zirconium oxide, or the like. The oxide film 74 functions as an insulating film for adjusting the optical path length (optical distance) between the reflector 71 and the second electrode 123.

The oxide films 74 having film thicknesses that vary in a manner that depends on the types of the light-emitting elements 12_{R}, 12_{G}, and 12_{B} can be formed, for example, as follows.

First, an electrolytic solution is filled in a container, and a substrate on which the reflector 71 is formed is immersed in the electrolytic solution. Furthermore, an electrode is arranged to face the reflector 71.

In addition, a positive voltage is applied to the reflector 71 with reference to the electrode to anodize the reflector 71. The film thickness of the oxide film obtained as a result of the anodization is proportional to the voltage applied to the electrode. Therefore, the anodization is performed with a voltage determined according to the types of the light-emitting elements 12 applied to each of the reflectors 71R, 71G, and 71B. As a result, the oxide films 74 having different film thicknesses can be collectively formed.

Materials and the like constituting the reflector 71, the first electrode 121, and the second electrode 123 are similar to those described in the first example, and thus, the description thereof will be omitted.

### Resonator Structure: Sixth Example

FIG. 62B is a schematic cross-sectional view for describing a sixth example of the resonator structure.

In the sixth example, the light-emitting element 12 includes a stack of the first electrode 121, the OLED layer 122, and the second electrode 123. Note that, in the sixth example, the first electrode 121 is formed to function as both an electrode and a reflector. The first electrode (-cum-reflector) 121 includes a material having an optical constant selected according to the types of the light-emitting elements 12_{R}, 12_{G}, and 12_{B}. Since a phase shift caused by the first electrode (-cum-reflector) 121 varies, it is possible to set an optical distance that causes optimum resonance for a wavelength of light according to the color to be displayed.

The first electrode (-cum-reflector) 121 can include pure metal such as aluminum (Al), silver (Ag), gold (Au), or copper (Cu), or an alloy containing these as principal components. For example, the first electrode (-cum-reflector) 121R of the light-emitting element 12_{R} can include copper (Cu), and the first electrode (-cum-reflector) 121G of the light-emitting element 12_{G} and the first electrode (-cum-reflector) 121B of the light-emitting element 12_{B} can include aluminum.

Materials and the like constituting the second electrode 123 are similar to those described in the first example, and thus, the description thereof will be omitted.

### Resonator Structure: Seventh Example

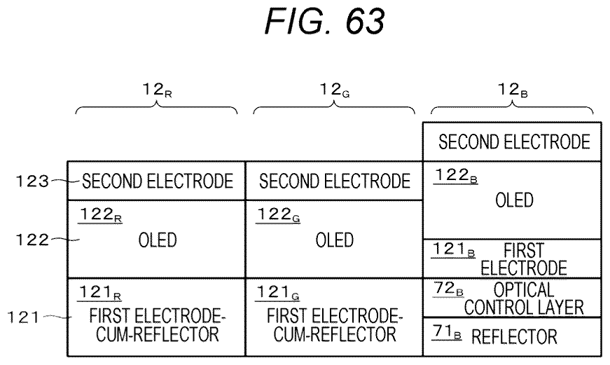

FIG. 63 is a schematic cross-sectional view for describing a seventh example of the resonator structure.

The seventh example basically has a configuration where the sixth example is applied to the light-emitting elements 12_{R} and 12_{G}, and the first example is applied to the light-emitting elements 12_{B}. With this configuration as well, it is possible to set an optical distance that causes optimum resonance for a wavelength of light according to the color to be displayed.

The first electrodes (-cum-reflectors) 121R and 121G used for the light-emitting elements 12_{R} and 12_{G} can include pure metal such as aluminum (Al), silver (Ag), gold (Au), or copper (Cu), or an alloy containing these as principal components.

Materials and the like constituting the reflector 71B, the optical control layer 72_{B}, and the first electrode 121B used for the light-emitting element 12_{B} are similar to those described in the first example, and thus, the description thereof will be omitted.

### 12 Application Examples

### (Electronic Equipment)

The display devices 101 to 109, and 109A (hereinafter, referred to as “the display device 101 and the like”) according to the first to ninth embodiments, tenth embodiment, and modifications thereof may be provided in various types of electronic equipment. The display device 101 and the like are suitable especially for an eyewear device such as a head-mounted display, an electronic viewfinder of a video camera or a single-lens reflex camera, or the like that requires high resolution and is used near the eyes in an enlarged manner.

### Specific Example 1

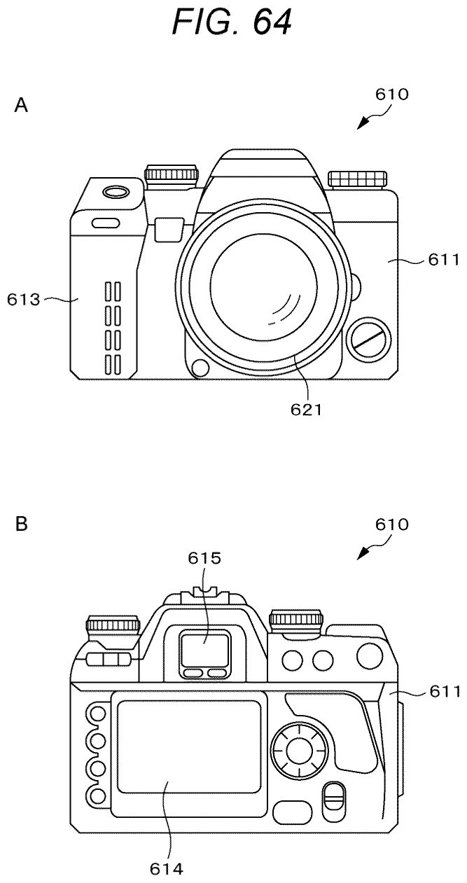

FIGS. 64A and 64B illustrate an example of an external appearance of a digital still camera 610. The digital still camera 610 is of a lens interchangeable single-lens reflex type, and includes an interchangeable imaging lens unit (interchangeable lens) 612 substantially at the center on the front surface of a camera main body (camera body) 611, and a grip portion 613 to be held by a photographer on the front left side.

A monitor 614 is provided at a position shifted to the left side from the center of the back surface of the camera main body 611. An electronic viewfinder (eyepiece window) 615 is provided above the monitor 614. By looking through the electronic viewfinder 615, the photographer can visually recognize an optical image of a subject guided from the imaging lens unit 612, and determine a picture composition. The electronic viewfinder 615 includes any one of the above-described display device 101 and the like.

### Specific Example 2

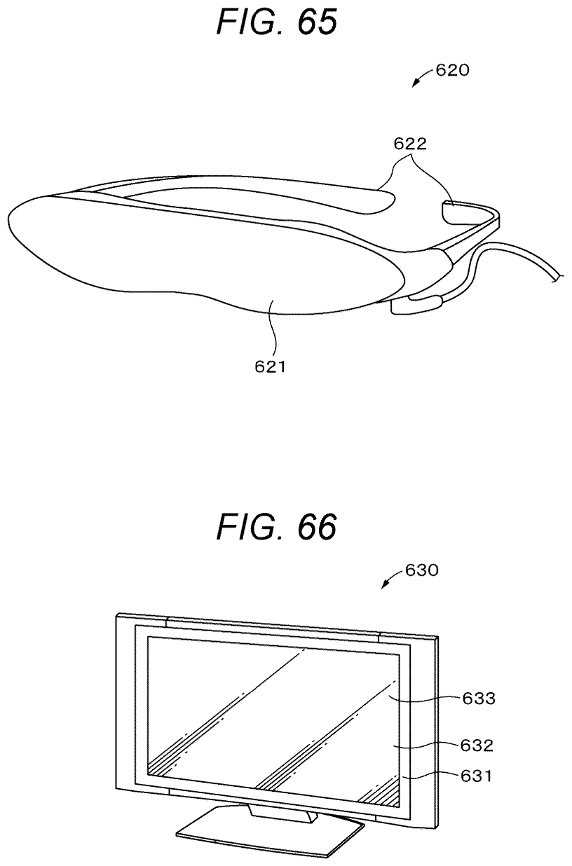

FIG. 65 illustrates an example of an external appearance of a head-mounted display 620. The head-mounted display 620 is an example of an eyewear device. The head-mounted display 620 includes, for example, ear hooking portions 622 for a user to wear the head-mounted display 620 on the head, on both sides of an eyeglass-type display unit 621. The display unit 621 includes any one of the above-described display device 101 and the like.

### Specific Example 3

FIG. 66 illustrates an example of an external appearance of a television device 630. The television device 630 includes, for example, a video display screen unit 631 including a front panel 632 and a filter glass 633, and the video display screen unit 631 includes any one of the above-described display device 101 and the like.

### Specific Example 4

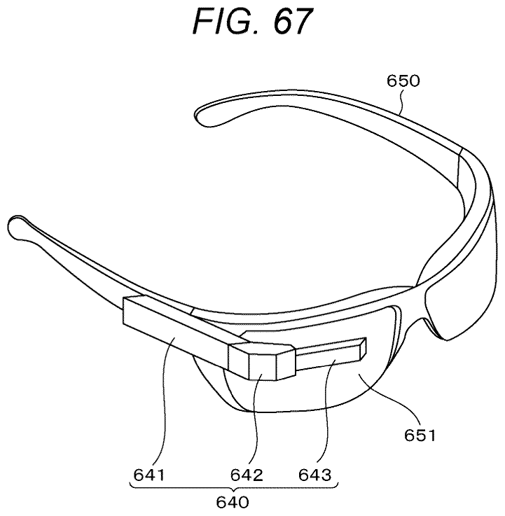

FIG. 67 illustrates an example of an external appearance of a see-through head-mounted display 640. The see-through head-mounted display 640 is an example of an eyewear device. The see-through head-mounted display 640 includes a main body 641, an arm 642, and a lens barrel 643.

The main body 641 is connected to the arm 642 and glasses 650. Specifically, an end of the main body 641 in the long side direction is coupled to the arm 642, and one side of the side surface of the main body 641 is coupled to the glasses 650 via a connecting member. Note that the main body 641 may be mounted directly on the head of the human body.

The main body 641 includes a control board for controlling the operation of the see-through head-mounted display 640, and a display unit. The arm 642 connects the main body 641 and the lens barrel 643, and supports the lens barrel 643. Specifically, the arm 642 is coupled to the end of the main body 641 and the end of the lens barrel 643 to secure the lens barrel 643. Furthermore, the arm 642 includes a signal line for communicating data related to an image provided from the main body 641 to the lens barrel 643.

The lens barrel 643 projects image light provided from the main body 641 through the arm 642 toward the eyes of the user wearing the see-through head-mounted display 640 through an eyeglass 651. In this see-through head-mounted display 640, the display unit of the main body 641 includes any one of the above-described display device 101 and the like.

### Specific Example 5

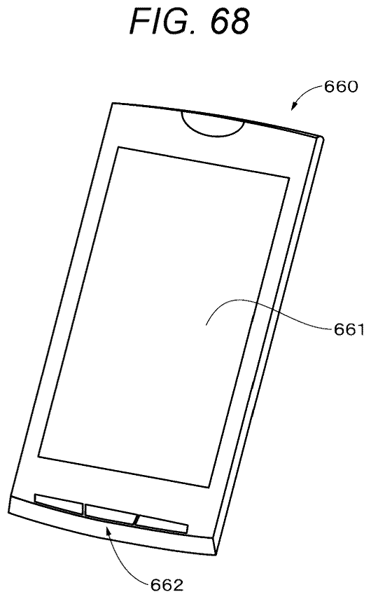

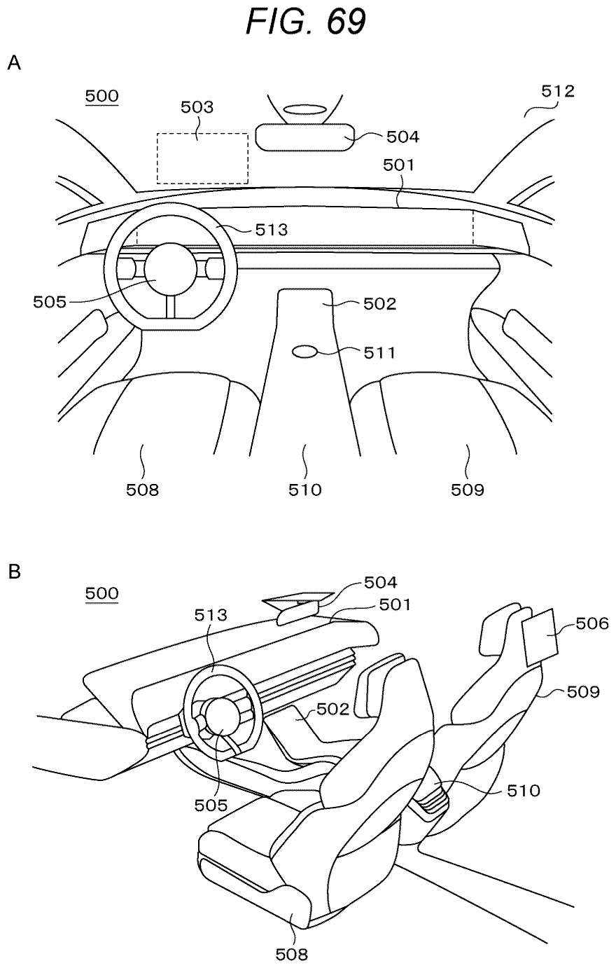

FIG. 68 illustrates an example of an external appearance of a smartphone 660. The smartphone 660 includes a display unit 661 that displays various kinds of information, an operation unit 662 including a button for receiving operation input from the user, and the like. The display unit 661 includes any one of the above-described display device 101 and the like.

### Specific Example 6

The above-described display device 101 and the like may be provided in vehicles or various displays.

FIGS. 69A and 69B are diagrams illustrating an example of an internal configuration of a vehicle 500 provided with various displays. Specifically, FIG. 69A is a diagram illustrating an example of an internal state of the vehicle 500 as viewed from the rear to the front of the vehicle 500, and FIG. 69B is a view illustrating an example of an internal state of the vehicle 500 as viewed from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes any one of the above-described display device 101 and the like. For example, all of these displays may include any one of the above-described display device 101 and the like.

The center display 501 is arranged on the dashboard at a location facing a driver's seat 508 and a passenger's seat 509. FIGS. 69A and 69B illustrate an example of the center display 501 having a horizontally elongated shape extending from the driver's seat 508 side to the passenger's seat 509 side, but the screen size and location of the center display 501 are determined as appropriate. The center display 501 can display information sensed by various sensors. As a specific example, the center display 501 can display an image captured by an image sensor, an image of a distance to an obstacle present in front of or on a side of the vehicle 500, the distance being measured by a ToF sensor, a body temperature of the occupant detected by an infrared sensor, or the like. The center display 501 can be used to display at least one of safety-related information, operation-related information, lifelogs, health-related information, authentication/identification-related information, or entertainment-related information, for example.

The safety-related information is information such as doze sensing, looking-away sensing, sensing of mischief of a child riding together, and presence or absence of wearing of a seat belt, sensing of leaving of an occupant, and is information sensed by, for example, a sensor arranged on the back surface side of the center display 501 in an overlapping manner. The operation-related information is information obtained by using the sensor to sense gestures related to the operation performed by the occupant. The sensed gestures may include operations of various types of equipment in the vehicle 500. For example, operations of air conditioning equipment, a navigation device, an audiovisual (AV) device, a lighting device, and the like are sensed. The lifelogs include lifelogs of all the occupants. For example, the lifelogs include an action record of each occupant in the vehicle. By acquiring and storing the lifelogs, it is possible to check the state of each occupant at the time of an accident. The health-related information is information obtained by estimating the health condition of the occupant on the basis of the body temperature of the occupant sensed by a sensor such as a temperature sensor. Alternatively, the face of the occupant may be imaged by using an image sensor, and the health condition of the occupant may be estimated from the imaged facial expression. Moreover, a conversation may be made with the occupant in automatic voice, and the health condition of the occupant may be estimated on the basis of the contents of a response from the occupant. The authentication/identification-related information includes information regarding a keyless entry function of performing face authentication by using a sensor, and a function of automatically adjusting a seat height and position through face identification. The entertainment-related information includes information regarding a function of detecting, by using a sensor, operation information about an AV device being used by the occupant, and a function of recognizing the face of the occupant by using the sensor and providing content suitable for the occupant through the AV device.

The console display 502 can be used, for example, to display lifelog information. The console display 502 is arranged near a shift lever 511 of a center console 510 between the driver's seat 508 and the passenger's seat 509. The console display 502 can also display information sensed by various sensors. Furthermore, the console display 502 may display an image of the surroundings of the vehicle captured with an image sensor, or may display an image of a distance to an obstacle present in the surroundings of the vehicle.

The head-up display 503 is virtually displayed behind a windshield 512 in front of the driver's seat 508. The head-up display 503 can be used to display at least one of the safety-related information, the operation-related information, the lifelogs, the health-related information, the authentication/identification-related information, or the entertainment-related information, for example. Being virtually arranged in front of the driver's seat 508 in many cases, the head-up display 503 is suitable for displaying information directly related to the operations of the vehicle 500, such as the speed, the remaining amount of fuel (battery), and the like of the vehicle 500.

The digital rearview mirror 504 can not only display the rear of the vehicle 500 but can also display the state of the occupant in the rear seat, and thus, can be used to display, for example, lifelog information obtained by a sensor arranged on the back surface side of the digital rearview mirror 504 in an overlapping manner.

The steering wheel display 505 is arranged near the center of a steering wheel 513 of the vehicle 500. The steering wheel display 505 can be used to display at least one of the safety-related information, the operation-related information, the lifelogs, the health-related information, the authentication/identification-related information, or the entertainment-related information, for example. In particular, being located close to the driver's hands, the steering wheel display 505 is suitable for displaying lifelog information such as the body temperature of the driver, or for displaying information regarding operations of the AV device, the air conditioning equipment, or the like.

The rear entertainment display 506 is attached to the back surface side of the driver's seat 508 or the passenger's seat 509, and is for the occupant in the rear seat to enjoy viewing/listening. The rear entertainment display 506 can be used to display at least one of the safety-related information, the operation-related information, the lifelogs, the health-related information, the authentication/identification-related information, or the entertainment-related information, for example. In particular, being located in front of the occupant in the rear seat, the rear entertainment display 506 displays information related to the occupant in the rear seat. For example, information regarding the operation of the AV device or the air conditioning equipment may be displayed, or a result of measurement of the body temperature or the like of the occupant in the rear seat with a temperature sensor may be displayed on the display.

A sensor may be arranged on the back surface side of the display device 101 and the like in an overlapping manner, so that the distance to an object present in the surroundings can be measured. Optical distance measurement methods are roughly classified into a passive type and an active type. By the method of the passive type, distance measurement is performed by receiving light from an object, without projecting light from a sensor to the object. The methods of the passive type include a lens focus method, a stereo method, a monocular vision method, and the like. By the method of the active type, distance measurement is performed by projecting light to an object, and receiving reflected light from the object with a sensor to measure the distance. The methods of the active type include an optical radar method, an active stereo method, an illuminance difference stereo method, a moire topography method, an interference method, and the like. The above-described display device 101 and the like can be used in distance measurement by any of these methods. With a sensor arranged on the back surface side of the above-described display device 101 and the like in an overlapping manner, distance measurement of the passive type or the active type described above can be performed.

### REFERENCE SIGNS LIST

10B, 10G, 10R Subpixel
11 Drive substrate
12B, 12G, 12R, 12W Light-emitting element
13 Protective layer
14 Side surface protective layer
15B, 15G, 15R Sidewall
16 Protective layer
16a Protective layer
17 Common electrode
18 Protective layer
18W Light-emitting element
19RE1 First region
19RE2 Second region
19RE3 Third region
19W Light-emitting element
19a1, 19a2 Groove
19a3 Recess
20 Protective layer
20R Light-emitting element
21 First electrode
22 Side surface protective layer
23 Protective layer
24 Color filter
24FB Blue filter portion
24FG Green filter portion
24FR Red filter portion
25B, 25G, 25R Light-emitting element
25a Groove
26 Insulating layer
26a Opening
27 Protective layer
28 Side surface protective layer
31B, 31G, 31R Light-emitting element
31La, 31Lb, 31Lc Light
32 Metal layer
32a Opening
33 Protective layer
34 Side surface protective layer
36W Light-emitting element
37 Insulating layer
38 Side surface protective layer
39 Insulating layer
41B, 41G, 41R Light-emitting element
42, 43 Protective layer
44 Drive substrate
44St Step
45, 46 Protective layer
47 Laminate
48 Protective layer
51 Light-emitting unit
52 Wavelength selection unit
53 Lens member
54 Planarization layer
55 Lens array
56 Protective layer
57 Cover layer
71 Reflector
71B, 71G, 71R, 71W Reflector
72B, 72G, 72R Optical control layer
74B, 74G, 74R Oxide film
74a Opening
81 Resist layer
82 Hard mask
83, 84, 85, 86, 87 Resist layer
91 Protective layer
92 Side surface protective layer
101, 102, 103, 104, 105, 106, 107, 108, 109, 109A Display device
101a Pad
111 Substrate
112 Insulating layer
112a Step
121B, 121G, 121R First electrode
122B, 122G, 122R OLED layer
123 Second electrode
123S Step
131 Side-etched portion
151 First sidewall
152 Second sidewall
153 Third sidewall
161 Contact hole
162 Recess
163 First protective layer
164 Second protective layer
171 Contact portion
191 First electrode
192W OLED layer
193 Second electrode
192a, 193a Flat portion
192b, 193b Convex portion
192c, 193c Inclined portion
194 Overhanging portion
195 Recess
211 First insulating layer
211a Opening
212 Second insulating layer
212a Opening
221 First side surface protective layer
222 Second side surface protective layer
251 First electrode
252B, 252G, 252R OLED layer
253 Second electrode
281 Protective layer
311 First electrode
312B, 312G, 312R OLED layer
312S Side surface
313 Second electrode
314 Insulating layer
314a Opening
315 Insulating layer
315a Opening
341 First side surface protective layer
342 Second side surface protective layer
343 Third side surface protective layer
344 Fourth side surface protective layer
345 Fifth side surface protective layer
346 Sixth side surface protective layer
361 First electrode
362W OLED layer
363 Second electrode
364 Insulating layer
364a Opening
411 First electrode
411a Step
411b Recess
411c First surface
411d Second surface
411e Opening
413 Second electrode
441 Substrate
442 Insulating layer
500 Vehicle
501 Center display
502 Console display
503 Head-up display
504 Digital rearview mirror
505 Steering wheel display
506 Rear entertainment display
508 Driver's seat
509 Passenger's seat
510 Center console
511 Shift lever
512 Windshield
513 Steering wheel
551 Lens
610 Digital still camera
611 Camera main body
612 Imaging lens unit
613 Grip portion
614 Monitor
615 Electronic viewfinder
620 Head-mounted display
621 Display unit
622 Ear hooking portion
630 Television device
631 Video display screen unit
632 Front panel
633 Filter glass
640 See-through head-mounted display
641 Main body
642 Arm
643 Lens barrel
650 Glasses
651 Eyeglass
660 Smartphone
661 Display unit
662 Operation unit
701 Display device
711W Light-emitting element
712W OLED layer
713 Insulating layer
RE1 Display region
RE2 Peripheral region

1. A light-emitting device comprising:
a plurality of light-emitting elements each including a first electrode, an organic-containing layer including an organic light-emitting layer, and a second electrode, the light-emitting elements being arranged two-dimensionally;
a protective layer provided on each of the light-emitting elements and separated between the light-emitting elements adjacent to each other; and
a side surface protective layer covering a side surface of each of the organic-containing layers, a side surface of each of the second electrodes, and a side surface of each of the protective layers, wherein
the side surface of the protective layer is located inside the side surface of the second electrode.

2. The light-emitting device according to claim 1, wherein
the protective layer includes silicon nitride.

3. The light-emitting device according to claim 1, wherein
the protective layer includes a first protective layer and a second protective layer in sequence, and
the second protective layer is lower in etching rate than the first protective layer.

4. The light-emitting device according to claim 1, wherein
the protective layer includes a first protective layer and a second protective layer in sequence, and
the second protective layer includes a monolayer.

5. The light-emitting device according to claim 1, wherein
the protective layer includes a first protective layer and a second protective layer in sequence, the first protective layer including silicon nitride, the second protective layer including aluminum oxide.

6. The light-emitting device according to claim 1, wherein
the protective layer includes a first protective layer and a second protective layer in sequence, and
a side surface of the second protective layer is located outside a side surface of the first protective layer.

7. The light-emitting device according to claim 1, wherein
the side surface protective layer includes a first side surface protective layer and a second side surface protective layer.

8. The light-emitting device according to claim 7, wherein
the second side surface protective layer includes at least one selected from the group consisting of zirconium oxide, tantalum oxide, and aluminum oxide.

9. The light-emitting device according to claim 7, wherein
the first side surface protective layer is lower in refractive index than the protective layer.

10. The light-emitting device according to claim 7, further comprising:
a first insulating layer provided between the first electrodes adjacent to each other; and
a second insulating layer provided on a peripheral edge portion of a surface of the first electrode adjacent to the organic-containing layer.

11. The light-emitting device according to claim 10, wherein
the first side surface protective layer includes a material identical to a material of the second insulating layer, and
the second side surface protective layer includes a material identical to a material of the first insulating layer.

12. The light-emitting device according to claim 1, wherein
the side surface protective layer includes a monolayer.

13. The light-emitting device according to claim 1, wherein
the side surface protective layer is capable of reflecting light emitted from each of the light-emitting elements.

14. The light-emitting device according to claim 13, wherein
the side surface protective layer includes
a first side surface protective layer having conductivity, a second side surface protective layer having insulating properties, and a third side surface protective layer having conductivity in sequence.

15. The light-emitting device according to claim 1, further comprising a third protective layer that fills a space between the light-emitting elements adjacent to each other, wherein
at least one first step is provided around each of the light-emitting elements.

16. The light-emitting device according to claim 15, wherein
each of the first steps is provided on the first electrode.

17. The light-emitting device according to claim 16, further comprising
an underlayer provided under each of the light-emitting elements, wherein
the underlayer includes at least one second step around each of the light-emitting elements, and
the first electrode is provided along each of the second steps.

18. The light-emitting device according to claim 1, wherein
a laminate includes each of the light-emitting elements and the protective layer,
the laminates adjacent to each other are separated by two or more different separation widths,
the protective layer includes a first protective layer and a second protective layer provided on the first protective layer,
the first protective layer is separated between the laminates adjacent to each other, and
the second protective layer is connected in a specified direction between the laminates adjacent to each other.

19. The light-emitting device according to claim 18, further comprising
a third protective layer covering the plurality of laminates, wherein
a groove is provided between the laminates adjacent to each other, and
the second protective layer and the third protective layer are provided along the groove.

20. A light-emitting device comprising:
a plurality of light-emitting elements each including a first electrode, an organic-containing layer including an organic light-emitting layer, and a second electrode, the light-emitting elements being arranged two-dimensionally; and
a side surface protective layer provided on a side surface of each of the light-emitting elements, wherein
the organic-containing layer includes a flat portion and an inclined portion on a surface adjacent to the second electrode, the inclined portion being provided adjacent to a side surface of the organic-containing layer, and
the second electrode is provided along the flat portion and the inclined portion, the second electrode located at the inclined portion being thicker than the second electrode located at the flat portion.

21. The light-emitting device according to claim 20, wherein
each of light-emitting elements includes an overhanging portion on an upper end of the side surface of the light-emitting element.

22. The light-emitting device according to claim 20, wherein
the side surface protective layer covers a boundary between the organic-containing layer and the second electrode.

23. The light-emitting device according to claim 20, further comprising
a protective layer provided on the plurality of light-emitting elements and separated between the light-emitting elements adjacent to each other, wherein
the side surface protective layer covers both the side surface of each of the light-emitting elements and a side surface of the protective layer.

24. Electronic equipment comprising the light-emitting device according to claim 1.
